(19) United States
(12) Patent Application Publication
(10) Pub. No.: US 2026/0026187 A1
(43) Pub. Date: Jan. 22, 2026

(54) Light-Emitting Device, Display Panel and Display Apparatus

(71) Applicant: BOE TECHNOLOGY GROUP CO., LTD., Chaoyang District, Beijing (CN)

(72) Inventors: Wenzhu Jing, Beijing (CN); Rongrong Gao, Beijing (CN); Xianwen Meng, Beijing (CN); Lei Chen, Beijing (CN); Xu Liu, Beijing (CN)

(21) Appl. No.: 18/868,607

(22) PCT Filed: Oct. 26, 2023
(86) PCT No.: PCT/CN2023/126891

§ 371 Date: Nov. 22, 2024

(51) Int. Cl. H10K 50/13; H10K 85/60

(52) U.S. Cl. CPC H10K 50/13; H10K 85/622; H10K 85/626; H10K 85/654; H10K 85/656; H10K 85/6572; H10K 85/6574; H10K 85/6576

(57) ABSTRACT

A light-emitting device includes a cathode and an anode that are opposite, and at least one light-emitting unit located between the cathode and the anode. The light-emitting unit includes: a light-emitting layer and a first-type functional layer disposed on a side of the light-emitting layer proximate to the cathode. The first-type functional layer includes a first functional layer and a second functional layer; a material of the first functional layer includes a first functional material; and a material of the second functional layer includes a second functional material. A structure of the first functional material contains a fluorene group; and a structure of the second functional material contains a fluorene group. The light-emitting device is used to display images.

### CROSS-REFERENCE TO RELATED APPLICATION

This application is the United States national phase of International Patent Application No. PCT/CN2023/126891, filed Oct. 26, 2023, the disclosure of which is hereby incorporated by reference in its entirety.

### BACKGROUND OF THE INVENTION

### Field of the Invention

The present disclosure relates to the field of display technologies, and in particular, to a light-emitting device, a display panel and a display apparatus.

### Description of Related Art

Organic light-emitting diode (OLED) display panels are widely used in display screens such as mobile phones, tablets and car displays due to full solid state, fast response speed, wide operating temperature range, and other advantages.

### SUMMARY OF THE INVENTION

In an aspect, a light-emitting device is provided. The light-emitting device includes a cathode and an anode that are opposite, and at least one light-emitting unit located between the cathode and the anode. The light-emitting unit includes a light-emitting layer and a first-type functional layer disposed on a side of the light-emitting layer proximate to the cathode. The first-type functional layer includes a first functional layer and a second functional layer. A material of the first functional layer includes a first functional material, and a material of the second functional layer includes a second functional material. A structure of the first functional material contains a fluorene group; and a structure of the second functional material contains a fluorene group.

In some embodiments, the first functional layer is closer to the cathode than the second functional layer; and the structure of the first functional material contains an azafluorene group.

In some embodiments, the first functional material is selected from any of structures represented by a general formula (I).

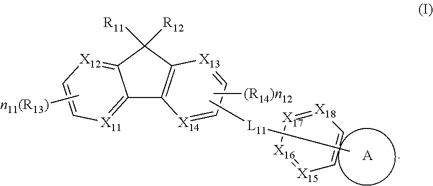

Where X₁₁, X₁₂, X₁₃, X₁₄, X₁₅, X₁₆, X₁₇ and X₁₈ are each independently selected from any of C(Rₐ) and N; any two of X₁₁, X₁₂, X₁₃, X₁₄, X₁₅, X₁₆, X₁₇ and X₁₈ are same or different; and at least one of X₁₁, X₁₂, X₁₃ or X₁₄ is N. R₁₁, R₁₂, R₁₃, R₁₄ and Rₐ are same or different. R₁₁, R₁₂, R₁₃, R₁₄ and Rₐ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₁₁, R₁₂, R₁₃, R₁₄ and Rₐ are connected with an adjacent group to form substituted or unsubstituted 3- to 30-membered ring. L₁₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups. A is selected from any of substituted or unsubstituted C6 to C12 aryl groups and substituted or unsubstituted 5- to 12-membered heteroaryl groups; n₁₁ is selected from any of 0, 1 and 2; and n₁₂ is selected from any of 0 and 1.

In some embodiments, the second functional material is selected from any of structures represented by a general formula (II).

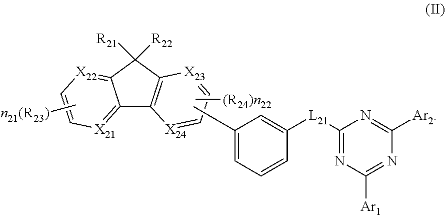

Where X₂₁, X₂₂, X₂₃ and X₂₄ are each independently selected from any of C(R_{b}) and N; and any two of X₂₁, X₂₂, X₂₃ and X₂₄ are same or different. R₂₁, R₂₂, R₂₃, R₂₄ and R_{b} are same or different; R₂₁, R₂₂, R₂₃, R₂₄ and R_{b} are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₂₁, R₂₂, R₂₃, R₂₄ and R_{b} are connected with an adjacent group to form substituted or unsubstituted 3- to 30-membered ring. L₂₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups. Ar₁ and Ar₂ are same or different; Ar₁ and Ar₂ are each independently selected from any of substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Ar₁ and Ar₂ are connected with an adjacent group to form substituted or unsubstituted 3- to 30-membered ring; n₂₁ is selected from any of 0, 1 and 2; and n₂₂ is selected from any of 0 and 1.

In some embodiments, the first functional material is selected from any of structures represented by a general formula (I-A).

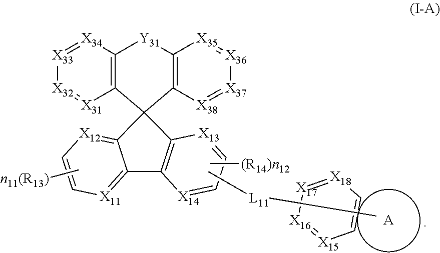

Where X₃₁, X₃₂, X₃₃, X₃₄, X₃₅, X₃₆, X₃₇ and X₃₈ are each independently selected from any of C(R_{c}) and N; and any two of X₃₁, X₃₂, X₃₃, X₃₄, X₃₅, X₃₆, X₃₇ and X₃₈ are same or different. Y₃₁ is selected from any of a direct bond, C(R_{d}Rₑ), O, S and Se. R_{c}, R_{d} and Rₑ are same or different; R_{c}, R_{d} and Rₑ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{c}, R_{d} and Rₑ are connected with an adjacent group to form substituted or unsubstituted 3- to 30-membered ring.

In some embodiments, R₁₁ is a phenyl group, and R₁₂ is a phenyl group.

In some embodiments, A is selected from any of structures represented by a general formula (A1-1), a general formula (A1-2), a general formula (A1-3) and a general formula (A1-4).

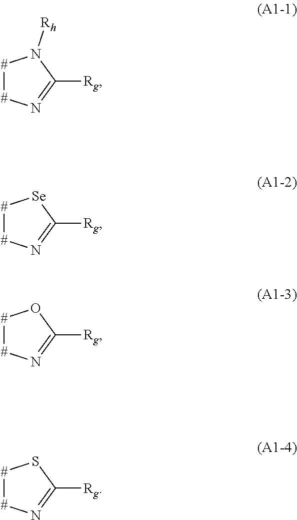

Wherein #indicates a fusion site. R_{g} and Rₕ are same or different; R_{g} and Rₕ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{g} and Rₕ are connected with an adjacent group to form substituted or unsubstituted 3- to 30-membered ring.

In some embodiments, A is selected from any of structures represented by a general formula (A2), a general formula (A3), a general formula (A4) and a general formula (A5).

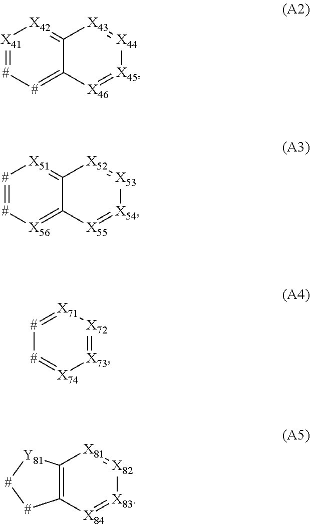

Where #indicates a fusion site.

X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are each independently selected from any of C(R_{f}) and N; and any two of X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are same or different. Y₈₁ is selected from any of C(RᵢRⱼ), N(Rₖ), O, S and Se. R_{f}, Rᵢ, Rⱼ and Rₖ are same or different; R_{f}, Rᵢ, Rⱼ and Rₖ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{f}, Rᵢ, Rⱼ and Rₖ are connected with an adjacent group to form substituted or unsubstituted 3- to 30-membered ring.

In some embodiments, A is selected from any of structures represented by the general formula (A2); and A and a six-membered ring containing X₁₅, X₁₆, X₁₇ and X₁₈ form a phenanthroline group.

In some embodiments, A is selected from any of structures represented by the general formula (A4); and A and a six-membered ring containing X₁₅, X₁₆, X₁₇ and X₁₈ form a benzodiazine group.

In some embodiments, the second functional material is selected from any of structures represented by a general formula (II-A).

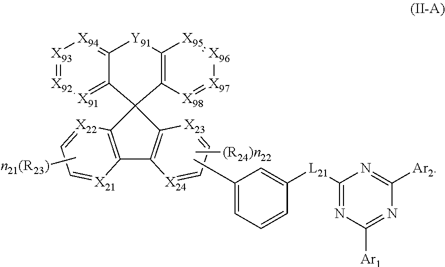

Where X₉₁, X₉₂, X₉₃, X₉₄, X₉₅, X₉₆, X₉₇ and X₉₈ are each independently selected from any of C(Rₙ) and N; and any two of X₉₁, X₉₂, X₉₃, X₉₄, X₉₅, X₉₆, X₉₇ and X₉₈ are same or different. Y₉₁ is selected from any of a direct bond, C(RₒRₚ), O, S and Se. Rₙ, Rₒ and Rₚ are same or different; Rₙ, Rₒ and Rₚ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Rₙ, Rₒ and Rₚ are connected with an adjacent group to form substituted or unsubstituted 3- to 30-membered ring.

In some embodiments, R₂₁ is a phenyl group, and R₂₂ is a phenyl group.

In some embodiments, R₂₁ is a methyl group, and R₂₂ is a methyl group.

In some embodiments, L₂₁ has a structure represented by a general formula (II-A).

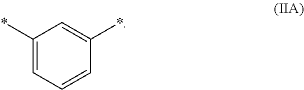

Where * indicates a connection site.

In some embodiments, X₂₁, X₂₂, X₂₃ and X₂₄ are substituted or unsubstituted carbon.

In some embodiments, the first-type functional layer further includes a third functional layer, and the third functional layer is located on a side of the first functional layer away from the second functional layer. A material of the third functional layer includes a third functional material, and the third functional material is selected from any of ytterbium and lithium fluoride.

In some embodiments, a material of the light-emitting layer includes a host material and a guest material; and the guest material is configured to emit blue light.

In some embodiments, the guest material is selected from any of a fluorescent material, a phosphorescent material and a delayed fluorescent material.

In some embodiments, the light-emitting device comprises at least two light-emitting units, and the at least two light-emitting units are stacked. The light-emitting device further includes a charge generation layer located between two adjacent light-emitting units. A material of a second functional layer of each of the light-emitting units includes the second functional material.

In another aspect, a display panel is provided. The display panel includes a plurality of light-emitting devices each as described in any of the above embodiments and a plurality of pixel driving circuits. Each pixel driving circuit in the plurality of pixel driving circuits is electrically connected to a light-emitting device, and is used to drive the light-emitting device to emit light.

In another aspect, a display apparatus is provided. The display apparatus includes the display panel as described in any of the above embodiments and a driver chip. The driver chip is used to drive the display panel to display.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of a display panel, in accordance with some embodiments;

FIG. 3 is a structural diagram of another display panel, in accordance with some embodiments;

FIG. 4 is a structural diagram of yet another display panel, in accordance with some embodiments;

FIG. 5 is a structural diagram of yet another display panel, in accordance with some embodiments;

FIG. 6 is a structural diagram of yet another display panel, in accordance with some embodiments;

FIG. 7 is a structural diagram of yet another display panel, in accordance with some embodiments;

FIG. 8 is a LUMO electron cloud distribution diagram of a first functional material, in accordance with some embodiments;

FIG. 9 is a HOMO electron cloud distribution diagram of a first functional material, in accordance with some embodiments;

FIG. 10 is an electron cloud distribution diagram of T1 holes of a first functional material, in accordance with some embodiments;

FIG. 11 is an electron cloud distribution diagram of T1 electrons of a first functional material, in accordance with some embodiments;

FIG. 12 is a LUMO electron cloud distribution diagram of a second functional material, in accordance with some embodiments;

FIG. 13 is a HOMO electron cloud distribution diagram of a second functional material, in accordance with some embodiments;

FIG. 14 is an electron cloud distribution diagram of T1 holes of a second functional material, in accordance with some embodiments; and

FIG. 15 is an electron cloud distribution diagram of T1 electrons of a second functional material, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

It will be noted that, reference numerals such as 1/2 in the drawings of the present disclosure indicates that both a component 1 and a component 2 may refer to this component, for example, a reference numeral 101/100 indicates that both a first light-emitting device 101 and a light-emitting device 100 may be represented by this component. Other similar reference numerals in the drawings also follow the above description. Other similar reference numerals in the drawings also follow the above description.

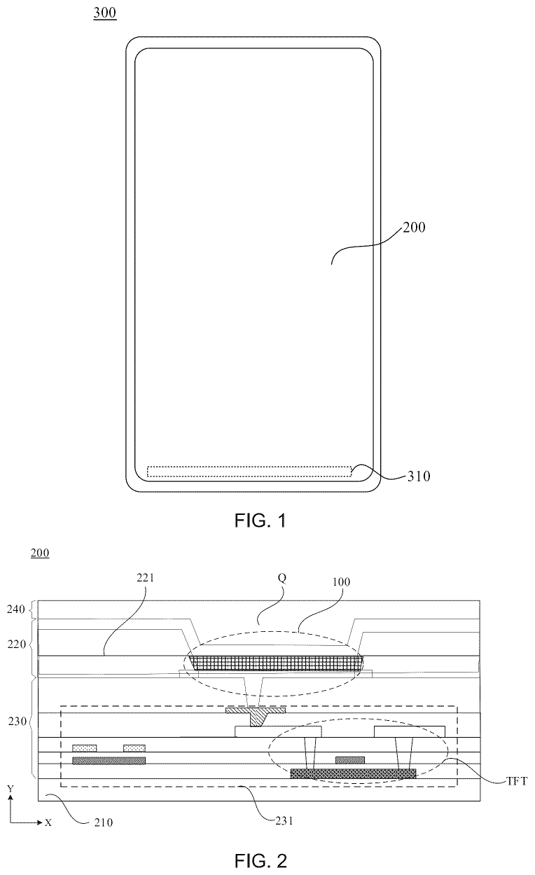

As shown in FIG. 1, some embodiments of the present disclosure provide a display apparatus 300, and the display apparatus 300 includes a display panel 200.

The display apparatus 300 may be, for example, an organic light-emitting diode (OLED) display apparatus.

For example, as shown in FIG. 1, the display apparatus 300 further includes a driver chip 310. The driver chip 310 is used to drive the display panel 200 to display.

In addition, the display apparatus 300 may further include an under-screen camera and an under-screen fingerprint recognition sensor, so that the display apparatus 300 can realize various functions such as photographing, video recording, fingerprint recognition or face recognition.

The above display apparatus 300 may be any apparatus that displays images whether in motion (such as a video) or fixed (such as a still image), and regardless of text or image. More specifically, it is expected that the display apparatus 300 in the described embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

In some embodiments, as shown in FIG. 2, the display panel 200 includes a substrate 210 and a light-emitting functional layer 220 disposed on the substrate 210. The light-emitting functional layer 220 includes a plurality of light-emitting devices 100. The plurality of light-emitting devices 100 are arranged in a first direction X, and the first direction X is parallel to a plane where the substrate 210 is located.

For example, a material of the substrate 210 may be a transparent rigid material, such as glass, to achieve a rigid substrate display; alternatively, the material of the substrate 210 may be a transparent flexible material, such as polyimide, to achieve a flexible substrate display.

In some examples, as shown in FIG. 2, the display panel 200 further includes an array layer 230 disposed between the substrate 210 and the light-emitting functional layer 220. The array layer 230 includes a plurality of pixel driving circuits 231, and the pixel driving circuit 231 includes a plurality of transistors TFT. Each pixel driving circuit 231 is electrically connected to a light-emitting device 100, and is used to drive the light-emitting device 100 to emit light.

For example, in the display panel 200, the pixel driving circuit 231 may generate a driving current. Each light-emitting device 100 may emit light under driving of the driving current generated by the corresponding pixel driving circuit 231, and lights emitted by the plurality of light-emitting devices 100 cooperate with each other to make the display panel 200 to achieve the display function.

In some examples, as shown in FIG. 2, the display panel 200 further includes an encapsulation layer 240. In this case, the array layer 230, the light-emitting functional layer 220 and the encapsulation layer 240 are stacked on the substrate 210, and the array layer 230, the light-emitting functional layer 220 and the encapsulation layer 240 are arranged in sequence in a direction away from the substrate 210.

For example, the display panel 200 is an OLED display panel 200. In this case, the encapsulation layer 240 covers the light-emitting device 100 to wrap the light-emitting device 100, thereby avoiding shortening a life of the OLED display panel 200 caused by damaging the organic material in the light-emitting device 100 by moisture and oxygen in an external environment entering the display panel 200.

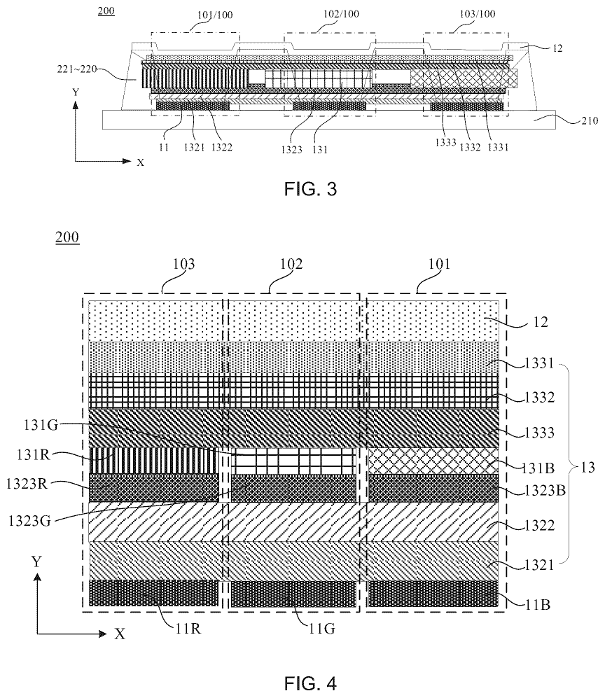

In some embodiments, as shown in FIGS. 2 and 3, the light-emitting functional layer 220 in the display panel 200 further includes a pixel defining layer 221. The pixel defining layer 221 includes a plurality of openings Q, and the plurality of light-emitting devices 100 are provided in one-to-one correspondence with the plurality of openings Q.

In some embodiments, as shown in FIGS. 3 and 4, the plurality of light-emitting devices 100 in the display panel 200 include first light-emitting devices 101, second light-emitting devices 102 and third light-emitting devices 103. Due to action of a driving voltage, the first light-emitting device 101 is configured to emit blue light, the second light-emitting device 102 is configured to emit green light, and the third light-emitting device 103 is configured to emit red light.

The provision of the plurality of light-emitting devices 100 including the first light-emitting devices 101, the second light-emitting devices 102 and the third light-emitting devices 103 may adjust brightness (grayscales) of the first light-emitting devices 101, the second light-emitting devices 102 and the third light-emitting devices 103, respectively. Combination and superposition of colors may achieve display of a plurality of colors, thereby realizing full-color display of the display panel 200.

It will be noted that FIGS. 4 to 7 are each a simplified schematic diagram obtained after other film layers in the display panel 200 except for film layers related to the light-emitting device 100 are removed.

In some embodiments, as shown in FIGS. 2 to 7, the light-emitting device 100 includes an anode 11 and a cathode 12 that are provided sequentially, and at least one light-emitting unit 13 disposed between the anode 11 and the cathode 12. The light-emitting unit 13 includes a light-emitting layer 131.

Based on the above structure, a light-emitting principle of the light-emitting device 100 is as follows. Through a circuit connected to the anode 11 and the cathode 12 (e.g., a pixel driving circuit 231), the anode 11 is used to inject holes into the light-emitting layer 131, and the cathode 12 is used to inject electrons into the light-emitting layer 131. The injected electrons and holes form excitons (i.e., electron-hole pairs) in the light-emitting layer 131, and the excitons return to a ground state through radiation transition to emit photons. It can be seen that in a light-emitting process of the light-emitting device 100, three processes of efficient charge generation, effective charge injection and rapid charge transfer are indispensable. The above charges are holes or electrons.

In some examples, as shown in FIG. 3, the anode 11 may be located on a side of the light-emitting unit 13 proximate to the substrate 210, and the cathode 12 may be located on a side of the light-emitting unit 13 away from the substrate 210. In some other examples, the anode 11 may be located on a side of the light-emitting unit 13 away from the substrate 210, and the cathode 12 may be located on a side of the light-emitting unit 13 proximate to the substrate 210.

For example, a material of the anode 11 is a transparent oxide such as indium tin oxide (ITO) or indium zinc oxide (IZO). Alternatively, the anode 11 may be a composite electrode such as ITO/Ag/ITO, Ag/IZO, CNT/ITO, or CNT/IZO, where Ag is silver and CNT is carbon nanotube.

For example, a material of the cathode 12 is silver-magnesium alloy or aluminum.

In some examples, as shown in FIGS. 3 to 5, the light-emitting device 100 includes a light-emitting unit 13. In this case, the light-emitting device 100 is a single-layer light-emitting device 100; the anode 11, the light-emitting unit 13 and the cathode 12 are stacked in a second direction Y, and the second direction Y intersects the first direction X. In some other examples, as shown in FIG. 6, the light-emitting device 100 includes a plurality of (e.g., two) stacked light-emitting units 13. In this case, the light-emitting device 100 is a stacked light-emitting device 100; the anode 11, the plurality of light-emitting units 13 and the cathode 12 are stacked in the second direction Y.

For example, as shown in FIGS. 3 to 6, the second direction Y is perpendicular to the first direction X.

In some embodiments, as shown in FIG. 6, in a case where the light-emitting device 100 includes a plurality of light-emitting units 13, the light-emitting device 100 further includes a charge generation layer 14, and the charge generation layer 14 is located between two adjacent light-emitting units 13 in the plurality of light-emitting units 13.

The plurality of light-emitting units 13 may be connected in sequence by the charge generation layer(s) 14 in a direction perpendicular to a light-emitting surface (e.g., the second direction Y). Moreover, the charge generation layer 14 not only plays a role of connecting the light-emitting units 13 in the stacked OLED light-emitting device 100, but also helps to improve a generation efficiency of charges (holes or electrons), which may generate a significant influence on properties of the light-emitting device 100.

In some examples, as shown in FIG. 6, the charge generation layer 14 includes an electron generation layer 141 and a hole generation layer 142 that are stacked. The electron generation layer 141 is closer to the anode 11 than the hole generation layer 142. The electron generation layer 141 may also be referred to as an N-type charge generation layer; and the hole generation layer 142 may also be referred to as a P-type charge generation layer.

In some embodiments, as shown in FIGS. 3 to 6, in order to improve a luminous efficiency of the light-emitting device 100, the light-emitting unit 13 further includes a hole transport functional layer 132 that is located on a side of the light-emitting layer 131 proximate to the anode 11 and in contact with the light-emitting layer 131. The hole transport functional layer 132 includes, for example, at least one of a hole injection layer 1321 (HIL), a hole transport layer 1322 (HTL) and an electron blocking layer 1323 (EBL) that are stacked. In a case where the hole transport functional layer 132 includes a hole injection layer 1321, a hole transport layer 1322 and an electron blocking layer 1323, the hole injection layer 1321, the hole transport layer 1322 and the electron blocking layer 1323 are arranged in sequence in a direction from the anode 11 to the cathode 12, and the electron blocking layer 1323 is in contact with the light-emitting layer 131.

In some embodiments, as shown in FIGS. 3 to 6, in order to improve the luminous efficiency of the light-emitting device 100, the light-emitting unit 13 further includes an electron transport functional layer 133 that is located on a side of the light-emitting layer 131 proximate to the cathode 12 and in contact with the light-emitting layer 131. The electron transport functional layer 133 includes, for example, at least one of an electron injection layer 1331 (EIL), an electron transport layer 1332 (ETL) and a hole blocking layer 1333 (HBL) that are stacked. In a case where the electron transport functional layer 133 includes an electron injection layer 1331, an electron transport layer 1332 and a hole blocking layer 1333, the electron injection layer 1331, the electron transport layer 1332 and the hole blocking layer 1333 are arranged in sequence in a direction from the cathode 12 to the anode 11, and the hole blocking layer 1333 is in contact with the light-emitting layer 131.

By providing the film layers such as the hole injection layer 1321, the hole transport layer 1322, the electron blocking layer 1323, the electron injection layer 1331, the electron transport layer 1332 and the hole blocking layer 1333, it is equivalent to providing transition steps between the anode 11 and the light-emitting layer 131 and between the cathode 12 and the light-emitting layer 131, thereby reducing a barrier height that carrier transition need to overcome and thus making the luminous efficiency rather high.

In some examples, the hole injection layer 1321 may be configured to reduce a hole injection barrier and improve a hole injection efficiency. The hole transport layer 1322 may be configured to transport holes. The electron blocking layer 1323 may be configured to transport holes, and block electrons and excitons generated in the light-emitting layer 131.

For example, a material of the hole injection layer 1321 is an inorganic oxide such as an oxide of a metal of molybdenum, titanium, vanadium, rhenium, ruthenium, chromium, zirconium, hafnium, tantalum, silver, tungsten, manganese and the like. Alternatively, the material of the hole injection layer 1321 may be a dopant of a strong electron-withdrawing compound, where the strong electron-withdrawing compound is, for example, F4TCNQ, HAT-CN, or the like. Alternatively, the material of the hole injection layer 1321 may be obtained by performing P-type doping on the material of the hole transport layer 1322.

For example, a thickness of the hole injection layer 1321 is in a range of 3 nm to 30 nm, inclusive.

For example, a material of the hole transport layer 1322 is a material with a good hole transport property, and may be an aromatic amine or carbazole material such as NPB, TPD, BAFLP and DFLDPBi.

For example, a thickness of the hole transport layer 1322 is in a range of 30 nm to 300 nm, inclusive.

For example, a material of the electron blocking layer 1323 (also referred to as a light-emitting auxiliary layer) is a material with a hole transport property, and may be an aromatic amine or carbazole material such as CBP and PCzPA.

For example, a thickness of the electron blocking layer 1323 is in a range of 5 nm to 150 nm, inclusive.

In some examples, the electron injection layer 1331 may be configured to reduce an electron injection barrier and improve an electron injection efficiency. The electron transport layer 1332 may be configured to transport electrons. The hole blocking layer 1333 may be configured to transport electrons, and block holes and excitons generated in the light-emitting layer 131.

For example, a material of the electron injection layer 1331 is an alkali metal or a metal, such as lithium fluoride (LiF), ytterbium (Yb), magnesium (Mg), or calcium (Ca). Alternatively, the material of the electron injection layer 1331 may be a compound of ytterbium (Yb), magnesium (Mg) or calcium (Ca).

For example, a thickness of the electron injection layer 1331 is in a range of 1 nm to 15 nm, inclusive.

For example, a material of the hole blocking layer 1333 is an aromatic heterocyclic compound such as an imidazole derivative, a pyrimidine derivative, an azine derivative or a compound containing a nitrogen-containing six-membered ring structure. The imidazole derivative is, for example, a benzimidazole derivative, an imidazopyridine derivative or a benzimidazolephenanthridine derivative. The azine derivative is, for example, a triazine derivative. The compound containing a nitrogen-containing six-membered ring structure is, for example, a quinoline derivative, an isoquinoline derivative or a phenanthroline derivative. Alternatively, the material of the hole blocking layer 1333 may be a compound having a heterocyclic ring with a phosphine oxide-based substituent, such as OXD-7, TAZ, p-EtTAZ, BPhen or BCP.

For example, a thickness of the hole blocking layer 1333 is in a range of 5 nm to 100 μm, inclusive.

For example, a material of the electron transport layer 1332 is an aromatic heterocyclic compound such as an imidazole derivative, a pyrimidine derivative, an azine derivative or a compound containing a nitrogen-containing six-membered ring structure. The imidazole derivative is, for example, a benzimidazole derivative, an imidazopyridine derivative or a benzimidazolephenanthridine derivative. The azine derivative is, for example, a triazine derivative. The compound containing a nitrogen-containing six-membered ring structure is, for example, a quinoline derivative, an isoquinoline derivative or a phenanthroline derivative. Alternatively, the material of the hole blocking layer 1333 may be a compound having a heterocyclic ring with a phosphine oxide-based substituent, such as OXD-7, TAZ, p-EtTAZ, BPhen or BCP.

For example, a thickness of the electron transport layer 1332 is in a range of 20 nm to 120 nm, inclusive.

In some embodiments, as shown in FIGS. 3 and 4, in a case where the plurality of light-emitting devices 100 include a first light-emitting device 101, a second light-emitting device 102 and a third light-emitting device 103, cathodes 12 of the plurality of light-emitting devices 100 may be of a whole-layer connected structure, that is, the cathodes 12 may be a common electrode shared by the plurality of light-emitting devices 100. The hole injection layers 1321 of the plurality of light-emitting devices 100 may also be of a whole-layer connected structure, that is, the hole injection layers 1321 may be a common film layer shared by the plurality of light-emitting devices 100. The hole transport layers 1322, the electron blocking layers 1323, the electron injection layers 1331, the electron transport layers 1332, the hole blocking layers 1333, the electron generation layers 141 and the hole generation layers 142 may also be common film layers shared by the plurality of light-emitting devices 100, which are not described in detail here.

For example, as shown in FIG. 3, in a case where the cathodes 12 are a common electrode shared by the plurality of light-emitting devices 100, the cathodes 12 are simultaneously formed on a side of the pixel defining layer 221 away from the substrate 210.

In some embodiments, as shown in FIG. 4, in a case where the plurality of light-emitting devices 100 include a first light-emitting device 101, a second light-emitting device 102 and a third light-emitting device 103, electron blocking layers 1323 of the first light-emitting device 101, the second light-emitting device 102 and the third light-emitting device 103 are independently provided. In this way, depending on different materials of the light-emitting layers 131, the materials of the electron blocking layers 1323 that match the properties of the materials of the light-emitting layers 131 may be selected.

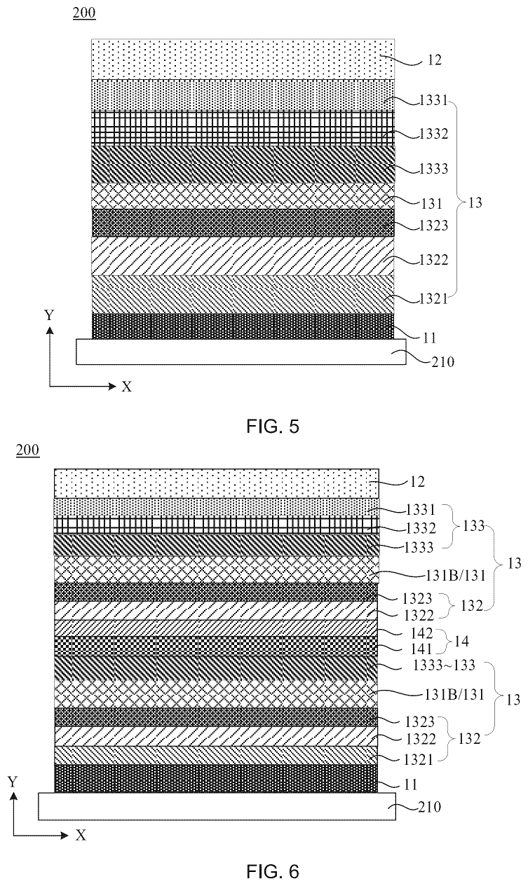

For example, in a case where the light-emitting device 100 is a single-layer light-emitting device 100, a structure of a display panel 200 including the light-emitting device 100 is shown in FIG. 5, and the light-emitting device 100 includes an anode 11, a hole injection layer 1321, a hole transport layer 1322, an electron blocking layer 1323, a light-emitting layer 131, a hole blocking layer 1333, an electron transport layer 1332, an electron injection layer 1331 and a cathode 12 that are stacked.

For example, in a case where the light-emitting device 100 is a single-layer light-emitting device 100 and the plurality of light-emitting devices 100 include a first light-emitting device 101, a second light-emitting device 102 and a third light-emitting device 103, a structure of a display panel 200 is shown in FIG. 4, and the first light-emitting device 101, the second light-emitting device 102 and the third light-emitting device 103 are arranged in the first direction X. Moreover, the cathodes 12 are a common electrode of the first light-emitting device 101, the second light-emitting device 102 and the third light-emitting device 103; and the hole injection layers 1321, the hole transport layers 1322, the hole blocking layers 1333, the electron transport layers 1332 and the electron injection layers 1331 are each a common film layer shared by the first light-emitting device 101, the second light-emitting device 102 and the third light-emitting device 103. The anodes 11 are independently provided, and are an anode 11B of the first light-emitting device 101, an anode 11G of the second light-emitting device 102 and an anode 11R of the third light-emitting device 103. The electron blocking layers 1323 are independently provided, and are an electron blocking layer 1323B of the first light-emitting device 101, an electron blocking layer 1323G of the second light-emitting device 102 and an electron blocking layer 1323R of the third light-emitting device 103. The light-emitting layers 131 are independently provided, and are a light-emitting layer 131B of the first light-emitting device 101, a light-emitting layer 131G of the second light-emitting device 102 and a light-emitting layer 131R of the third light-emitting device 103.

In some embodiments, a material of the light-emitting layer 131 includes a host material H and a guest material D.

For example, the host material H is configured to: transport holes or electrons, and/or recombine electrons and holes to form excitons and transfer exciton energy to the guest material D.

For example, the guest material D is configured to: emit photons using the exciton energy transferred from the host material H, and/or recombine electrons and holes to form excitons and emit photons.

In some examples, the guest material D is a fluorescent material that can emit light using singlet excitons. In some other examples, the guest material D is a phosphorescent material or a delayed fluorescent material that can emit light using triplet excitons.

In some examples, the host material H includes more than two materials. For example, the host material H includes a first host material and a second host material, where the first host material is a hole-type material and the second host material is an electron-type material.

For example, a thickness of the light-emitting layer 131 is in a range of 15 nm to 100 nm, inclusive.

For example, the host material H of the light-emitting layer 131 of the first light-emitting device 101 is an anthracene derivative, such as AND or MADN.

For example, the host material H of the light-emitting layer 131 of the second light-emitting device 102 is a coumarin dye, a quinacridone copper derivative, polycyclic aromatic hydrocarbon, a diamine anthracene derivative, a carbazole derivative, such as DMQA, BA-NPB or Alq3.

For example, the host material H of the light-emitting layer 131 of the third light-emitting device 103 is a DCM series material, such as DCM, DCJTB or DCJTI.

As described in the background, in the field of organic semiconductors, the OLED light-emitting device 100 has become a mainstream product due to advantages of self-luminescence, low power consumption, high resolution, large color gamut, no need for backlight, flexibility and bendability, and has been successfully applied in lighting systems, communication systems, vehicle display systems, portable electronic devices and high-definition display apparatuses 300.

With the development of the OLED light-emitting device, requirements for the efficiency, life and other properties of the OLED light-emitting device are becoming higher and higher. The efficiency and life of the light-emitting device 100 are related to the device structure and the optimal combination of organic materials in various film layers. In terms of device structure, the structure of the OLED light-emitting device has developed from an original sandwich structure to a multi-layer device structure. The multi-layer device structure is, for example, a multi-layer device structure including an anode 11, a hole transport functional layer 132, a light-emitting layer 131, an electron transport functional layer 133 and a cathode 12. As for the description of the multi-layer device structure, reference may be made to the foregoing contents, and details are not repeated here again.

Since matching of mobility and energy levels between all the functional film layers in the light-emitting device 100 and characteristics of the materials themself affect injection and transport of carriers and/or formation and quenching of excitons inside the light-emitting device 100, an interface structure of the OLED light-emitting device 100 will affect the properties (e.g., a driving voltage, a luminous efficiency and a device life) of the light-emitting device 100.

In light of this, as shown in FIGS. 5 and 6, some embodiments of the present disclosure provide a light-emitting device 100. The light-emitting unit 13 includes: a light-emitting layer 131 and a first-type functional layer disposed on a side of the light-emitting layer 131 proximate to the cathode 12. The first-type functional layer includes a first functional layer and a second functional layer. A material of the first functional layer includes a first functional material G1. A material of the second functional layer includes a second functional material G2. A structure of the first functional material G1 contains a fluorene group. A structure of the second functional material G2 contains a fluorene group.

The first-type functional layer is the above electron transport functional layer 133. The first functional layer may be one of the electron injection layer 1331, the electron transport layer 1332 and the hole blocking layer 1333, and the second functional layer may be the other of the electron injection layer 1331, the electron transport layer 1332 and the hole blocking layer 1333.

For example, the first functional layer is the electron transport layer 1332, and the first functional material G1 is the material of the electron transport layer 1332; the second functional layer is the hole blocking layer 1333, and the second functional material G2 is the material of the hole blocking layer 1333.

It can be understood that in a case where the structures of the first functional material G1 and the second functional material G2 both contain fluorene groups, the first functional material G1 and the second functional material G2 have relatively good matching, so that the first functional layer and the second functional layer have smooth transition, and a contact property between the first functional layer and the second functional layer may be improved. In this way, an interface between the first functional layer and the second functional layer may be optimized, which is beneficial to transport of electrons between the first functional layer and the second functional layer, thereby improving an electron transport effect of the light-emitting device 100. Thus, the transport of electrons may be well controlled, so that electrons and holes in the light-emitting layer 131 are relatively balanced, and a recombination probability of the excitons is increased. In this way, firstly, the yield of excitons may increase, so that an efficiency of the light-emitting device 100 may be improved; secondly, distribution of carriers may be balanced to block holes or excitons from leaking to a side of the cathode 12, so that the life of the light-emitting device 100 may be improved. In addition, in a case where the structures of the first functional material G1 and the second functional material G2 both contain fluorene groups, the first functional material G1 and the second functional material G2 may be prepared using the same fragment, thereby saving preparation time and cost.

In some embodiments, the first functional layer is closer to the cathode 12 than the second functional layer. The structure of the first functional material G1 contains an azafluorene group.

For example, the first functional layer is the electron transport layer 1332, and the first functional material G1 is the material of the electron transport layer 1332.

It can be understood that the azafluorene group refers to a group obtained by replacing at least one carbon atom in the fluorene group with a nitrogen atom. Since the nitrogen atom on the fluorene group has a certain electron-withdrawing ability, the azafluorene group has a better electron transport property than the fluorene group without nitrogen. Therefore, in a case where the structure of the first functional material G1 contains an azafluorene group, the electron transport property of the first functional material G1 may be improved, so that the first functional material G1 may have a relatively high electron mobility. As a result, the electron transport effect of the light-emitting device 100 may be improved, the recombination probability of excitons may increase, and the efficiency and life of the light-emitting device 100 may be improved.

Moreover, in a case where the second functional layer is the hole blocking layer 1333, the material of the hole blocking layer 1333 is the second functional material G2 containing a fluorene group, and the material of the electron transport layer 1332 is the first functional material G1 containing an azafluorene group. Therefore, the material of the electron transport layer 1332 has a higher electron transport property than the material of the hole blocking layer 1333. In this way, the electron transport properties of the hole blocking layer 1333 and the electron transport layer 1332 may match the electron transport requirements of the electron transport functional layer 133.

It will be noted that the first functional layer may include other materials besides the first functional material G1, and the second functional layer may include other materials besides the second functional material G2, which are not limited here. In some examples, the material of the first functional layer may further include 8-hydroxyquinoline lithium (LiQ).

It will be noted that the number and position of nitrogen in the azafluorene group in the structure of the first functional material G1 are not limited here.

For example, the first functional material G1 may be selected from the structures shown in the general formula (I) described in detail below, as shown in (G1-8), (G1-57), (G1-69), (G1-72), (G1-80), (G1-85), (G1-88), (G1-93), (G1-96), (G1-101), (G1-104), (G1-123), (G1-127), (G1-131), (G1-135), (G1-185), (G1-189) and (G1-193), the azafluorene group may be an azafluorene group containing a nitrogen atom.

For example, the first functional material G1 may be selected from the structures shown in the general formula (I) described in detail below, as shown in (G1-1) to (G1-7), (G1-10) to (G1-31), (G1-33) to (G1-48), (G1-49) to (G1-56), (G1-58) to (G1-68), (G1-70), (G1-71), (G1-73) to (G1-75), (G1-78), (G1-79), (G1-81) to (G1-84), (G1-86), (G1-87), (G1-89) to (G1-92), (G1-94), (G1-95), (G1-97) to (G1-100), (G1-102), (G1-103), (G1-105), (G1-107) to (G1-122), (G1-124) to (G1-126), (G1-128) to (G1-130), (G1-132) to (G1-134), (G1-136), (G1-137), (G1-139) to (G1-169), (G1-171) to (G1-173), (G1-175) to (G1-177), (G1-179) to (G1-181), (G1-183), (G1-184), (G1-187), (G1-188), (G1-191), (G1-192), (G1-195), (G1-196), (G1-199), (G1-203) and (G1-204), the azafluorene group may be an azafluorene group containing two nitrogen atoms. Furthermore, the relative positions of the two nitrogen atoms are not limited here.

For example, the first functional material G1 may be selected from the structures shown in the general formula (I) described in detail below, as shown in (G1-9), the azafluorene group may be an azafluorene group containing three nitrogen atoms. Furthermore, the relative positions of the three nitrogen atoms are not limited here.

For example, the first functional material G1 may be selected from the structures shown in the general formula (I) described in detail below, as shown in (G1-32), (G1-76), (G1-77), (G1-106), (G1-138), (G1-170), (G1-174), (G1-178), (G1-182), (G1-186), (G1-190) and (G1-194), the azafluorene group may be an azafluorene group containing four nitrogen atoms. Furthermore, the relative positions of the four nitrogen atoms are not limited here.

In some embodiments, the first functional material G1 is selected from any of structures represented by the following general formula (I).

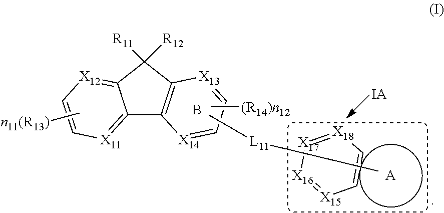

Where X₁₁, X₁₂, X₁₃, X₁₄, X₁₅, X₁₆, X₁₇ and X₁₈ are each independently selected from any of C(Rₐ) and N; any two of X₁₁, X₁₂, X₁₃, X₁₄, X₁₅, X₁₆, X₁₇ and X₁₈ are the same or different; at least one of X₁₁, X₁₂, X₁₃ or X₁₄ is N; C(Rₐ) is carbon substituted with Rₐ, and N is nitrogen.

R₁₁, R₁₂, R₁₃, R₁₄ and Rₐ are the same or different. R₁₁, R₁₂, R₁₃, R₁₄ and Rₐ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₁₁, R₁₂, R₁₃, R₁₄ and Rₐ are connected with an adjacent group to form substituted or unsubstituted 3- to 30-membered ring.

L₁₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups.

A is selected from any of substituted or unsubstituted C6 to C12 aryl groups and substituted or unsubstituted 5- to 12-membered heteroaryl groups.

n₁₁ is selected from any of 0, 1 and 2.

n₁₂ is selected from any of 0 and 1.

Regarding the structure shown in general formula (I), the following points need to be explained.

In the structure represented by the general formula (I), at least one of X₁₁, X₁₂, X₁₃ or X₁₄ is N, that is, the fluorene group contained in the structure represented by the general formula (I) is an azafluorene group.

L₁₁ may be a direct bond. In a case where L₁₁ is a direct bond, the azafluorene group and the IA portion (i.e., a fused ring group generated by condensing the A ring and the six-membered ring containing X₁₅, X₁₆, X₁₇ and X₁₈) are directly connected by a covalent bond.

L₁₁ may be selected from any of substituted or unsubstituted C3 to C30 alkylene groups, substituted or unsubstituted C6 to C30 arylene groups, and substituted or unsubstituted 5- to 30-membered heteroarylene groups. The alkylene group of Cx refers to an alkylene group having x carbon (C) atoms, where x is a positive integer, and the same applies to the following. For understanding of other groups such as the arylene group of Cx and the heteroarylene group of Cx, reference may be made to the above contents and details are not repeated here. In addition, the phenyl group refers to a general name of a group left after a hydrogen atom of one carbon atom on the benzene ring is removed; and the phenylene group refers to a general name of a group left after hydrogen atoms of two carbon atoms on the benzene ring are removed. For understandings of other groups such as the arylene group, the heteroarylene group and the alkylene group, reference may be made to the above contents, and details are not repeated here. Furthermore, a Z-membered heteroarylene group refers to a heteroarylene group having Z atoms on the ring, where Z is a positive integer, and the same applies to the following. For understanding of other groups such as a Z-membered heteroaryl group and a Cx-membered heterocyclyl group, reference may be made to the above contents, and details are not repeated here. Here, the atom on the ring refers to an atom of the ring connected by a chemical bond, for example, the atoms on the ring of the benzene ring are six carbon atoms.

In the structure represented by the general formula (I), L₁₁ is connected to the B ring of the azafluorene group, and L₁₁ is also connected to the IA portion. The connection position between L₁₁ and the B ring of the azafluorene group means that L₁₁ may be connected to any atom on the B ring that has a substitution position. The connection position between L₁₁ and the IA portion means that L₁₁ may be connected to any atom on the ring of the IA portion that has a substitution position. Here, there is no limitation on the connection position between L₁₁ and the azafluorene group and the connection position between L₁₁ and the IA portion.

In the structure represented by the general formula (I), (Rₓ)_{ny} means that the number of substituents Rₓ is ny. In a case where ny is 0, it means that the substituted positions of the carbon atoms on the corresponding six-membered ring with substituted positions are all substituted by hydrogen atoms. In a case where ny is a positive integer greater than or equal to 1, it means that ny Rₓ are connected to the corresponding six-membered ring; and the ny Rₓ may be connected to any ny carbon atoms with substitution positions in the six carbon atoms on the six-membered ring. Here, there is no limitation on the position of the carbon atom connected to Rₓ. In a case where ny is a positive integer greater than 1, the ny Rₓ may be the same or different. Here, x is any of 13 and 14, and y is any of 11 and 12.

In a case where R₁₁, R₁₂, R₁₃, R₁₄ and Rₐ are each selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, and/or L₁₁ is selected from any of substituted C3 to C30 alkylene groups, substituted C6 to C30 arylene groups, and substituted 5- to 30-membered heteroarylene groups, and/or A is selected from any of substituted C6 to C12 aryl groups and substituted 5- to 12-membered heteroaryl groups, the type and number of substituents are not limited here.

It can be understood that, the structure represented by the general formula (I) contains at least one electron-withdrawing group (e.g., the IA portion) with good planarity, which may produce a conjugation effect, so that the first functional material G1 has a wide LUMO electron cloud distribution. In this way, the lowest unoccupied molecular orbital (LUMO) energy level of the first functional material G1 may be relatively low, and the electron mobility of the first functional material G1 may be relatively high. Moreover, the structure represented by the general formula (I) contains an azafluorene group, which has a certain electron-withdrawing ability. The azafluorene group has a better electron transport property than the fluorene group without nitrogen, so that the first functional material G1 may have a relatively high electron mobility. In this way, the electron transport property of the first functional material G1 may be improved, the recombination probability of excitons may increase, and the efficiency and life of the light-emitting device 100 may be improved.

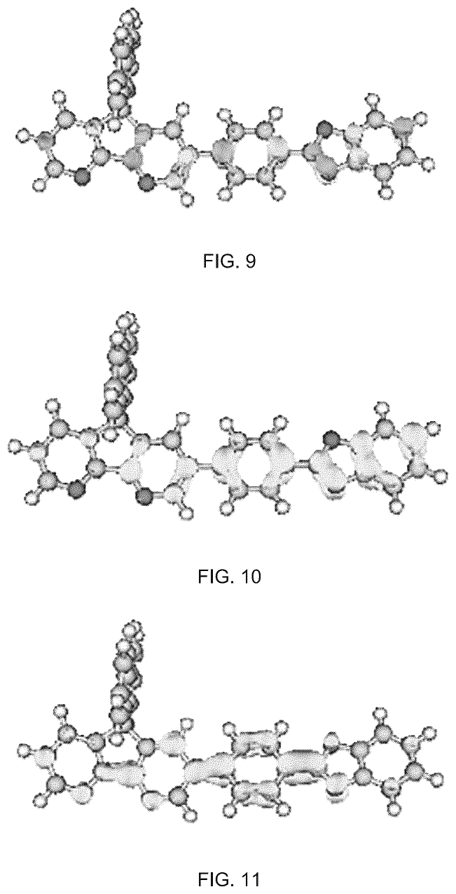

In some examples, a LUMO electron cloud distribution diagram, a HOMO electron cloud distribution diagram, an electron cloud distribution diagram of T1 holes, and an electron cloud distribution diagram of T1 electrons of the first functional material G1 (e.g., the first functional material G1 with the structural formula (G1-97) as described in detail below) are shown in FIGS. 8, 9, 10 and 11. It can be seen from FIG. 8 that, the LUMO electron cloud of the first functional material G1 is distributed at the location of the electron-withdrawing group with good planarity. Moreover, since the first functional material G1 may produce a conjugation effect, the first functional material G1 has a wide LUMO electron cloud distribution. For example, the LUMO electron cloud may also be distributed at the location of the fluorene group.

The IA portion may be conjugated with the azafluorene group, so that at least part of the LUMO electron cloud may be distributed in an area where the azafluorene group is located. In this way, the first functional material G1 may have a relatively wide LUMO electron cloud distribution, the LUMO energy level of the first functional material G1 may be reduced, and the electron mobility of the first functional material G1 may be improved.

The exemplary structures of the first functional material G1 having a structure as represented by the general formula (I) are described below.

In some examples, in a case where R₁₁ and R₁₂ are methyl groups, the structural formula of the first functional material G1 may be as shown below.

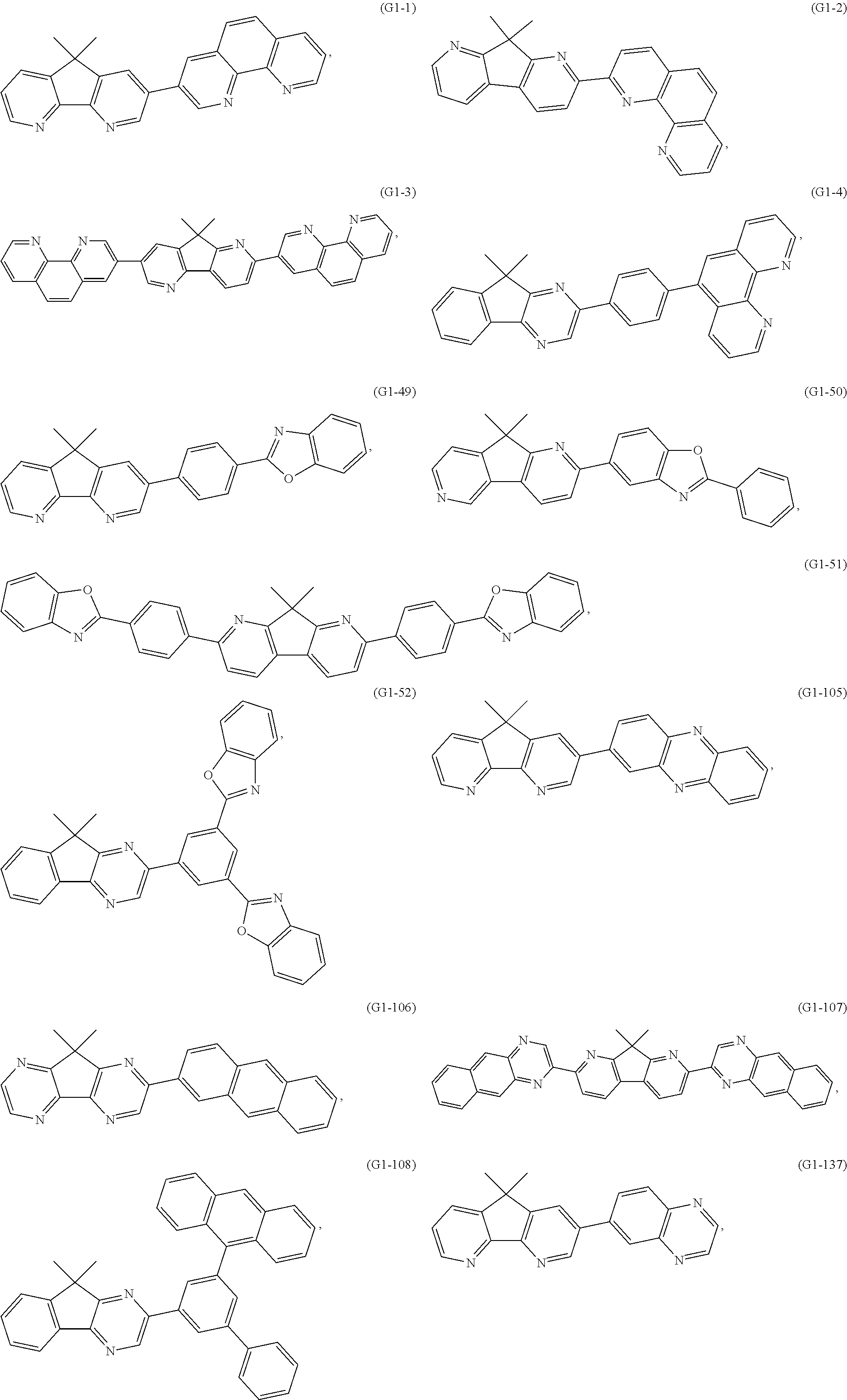

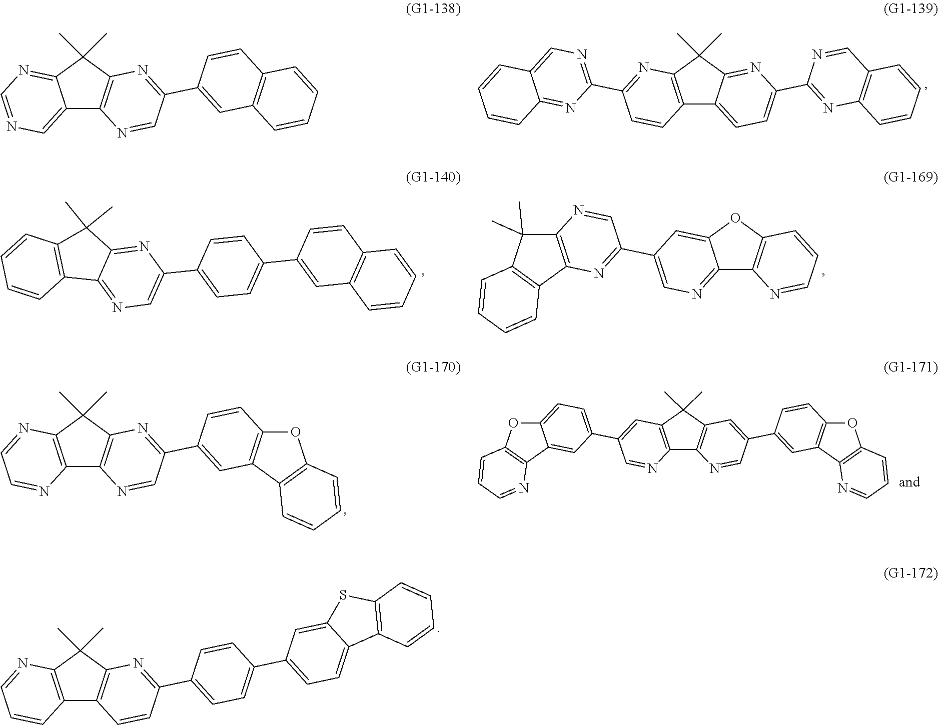

In some examples, in a case where R₁₁ and R₁₂ are connected to form a six-membered ring, the structural formula of the first functional material G1 may be as shown below.

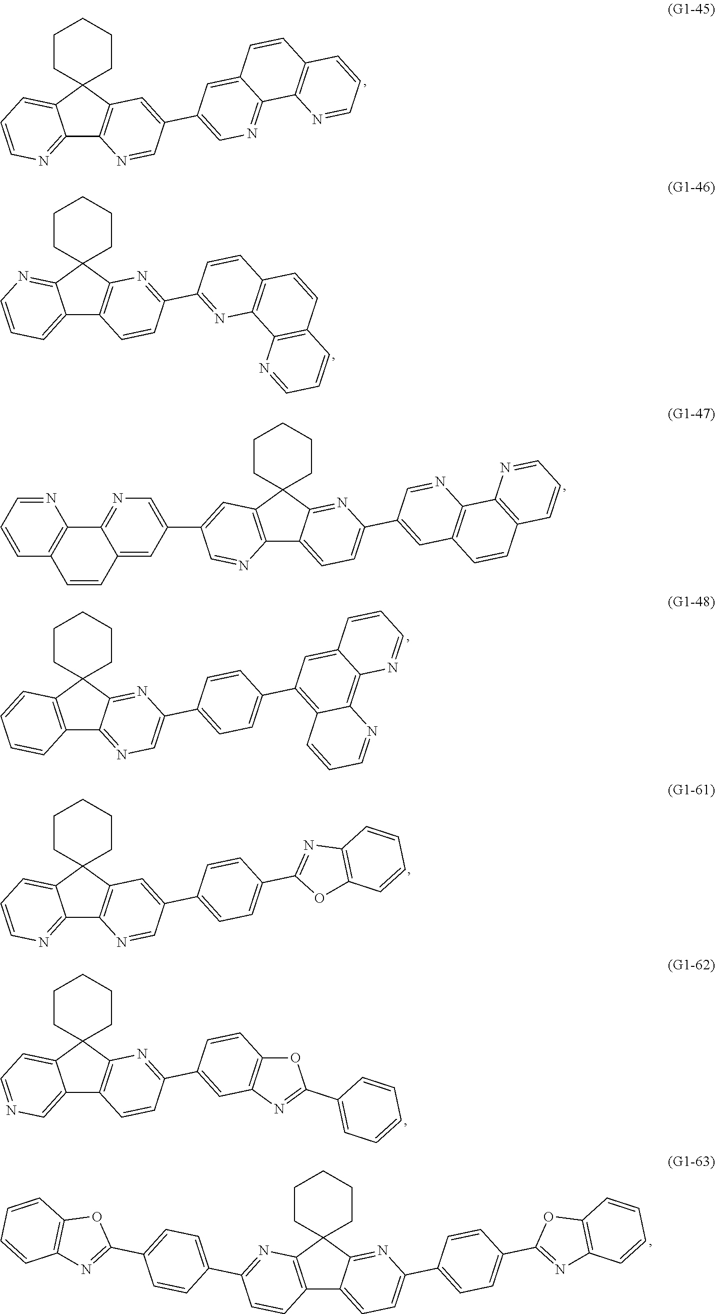

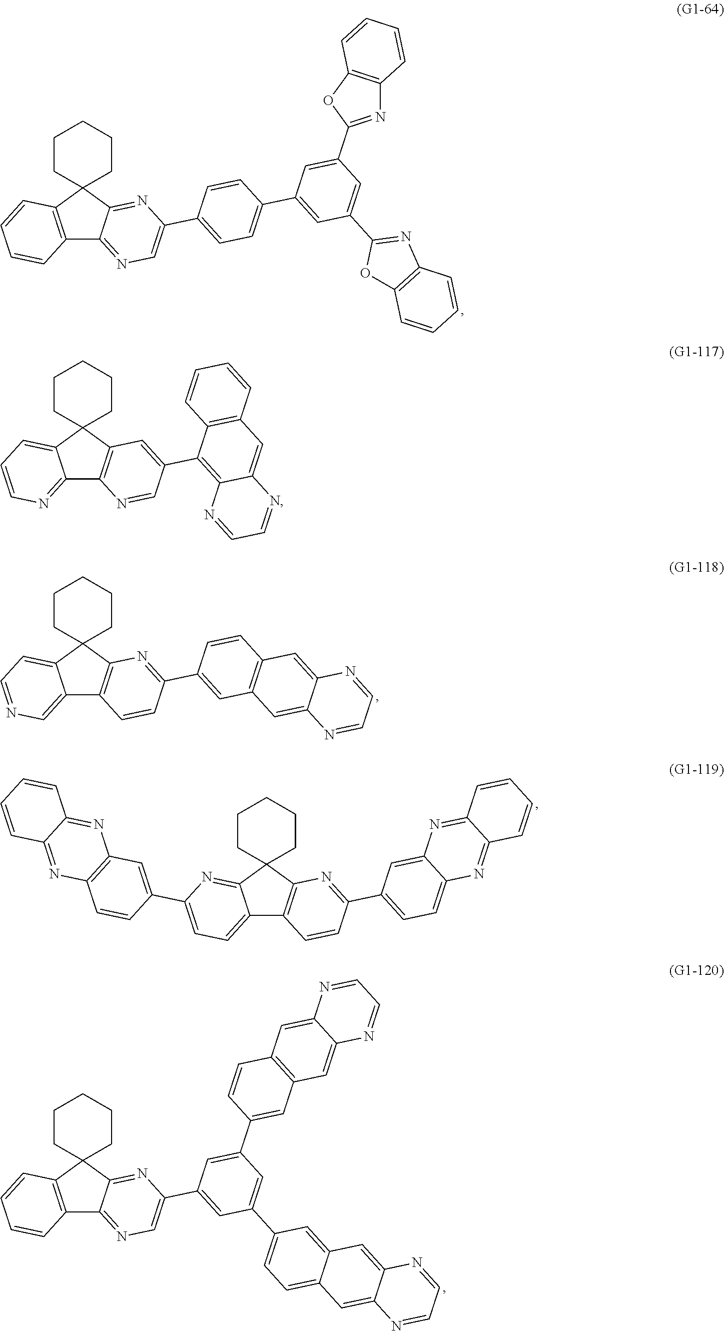 [SMILES: c1ccc2c(c1)-c1ncc(-c3ccc(-c4cc(-c5nc6ccccc6o5)cc(-c5nc6ccccc6o5)c4)cc3)nc1C21CCCCC1 ; c1cnc2c(c1)C1(CCCCC1)c1cc(-c3c4ccccc4cc4nccnc34)cnc1-2 ; c1cc2c(cn1)-c1ccc(-c3ccc4cc5nccnc5cc4c3)nc1C21CCCCC1 ; c1ccc2nc3cc(-c4ccc5c(n4)C4(CCCCC4)c4nc(-c6ccc7nc8ccccc8nc7c6)ccc4-5)ccc3nc2c1 ; c1ccc2c(c1)-c1ncc(-c3cc(-c4ccc5cc6nccnc6cc5c4)cc(-c4ccc5cc6nccnc6cc5c4)c3)nc1C21CCCCC1]

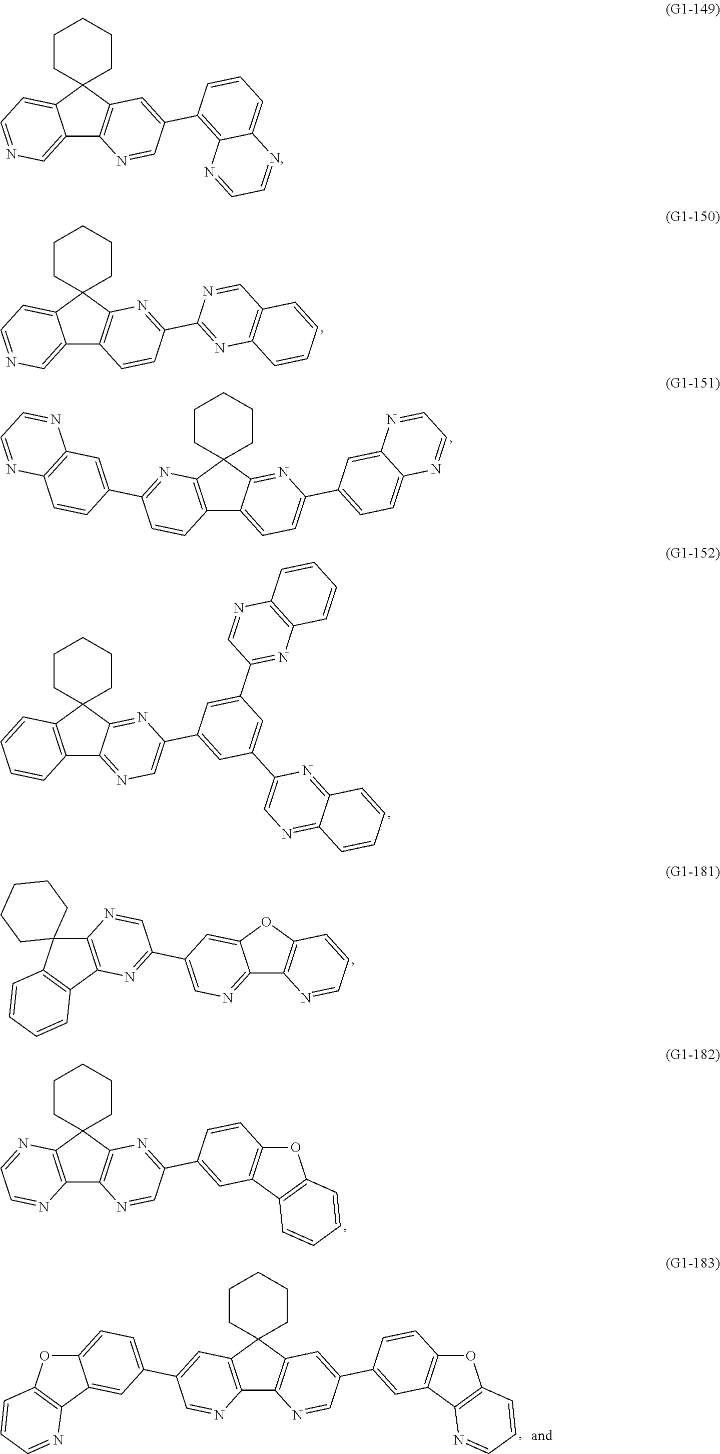

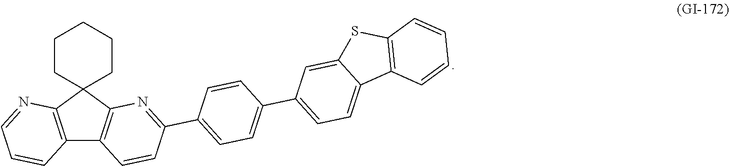 [SMILES: c1cnc2c(c1)-c1ccc(-c3ccc(-c4ccc5c(c4)sc4ccccc45)cc3)nc1C21CCCCC1]

It can be understood that in a case where R₁₁ and R₁₂ are connected to form a six-membered ring, the six-membered ring and the azafluorene group share the sp3 carbon atom to form a spirocyclic group. Since the spirocyclic group has an orthogonal stereo configuration, the stereoscopic property of the configuration of the first functional material G1 may be improved. Thus, the first functional material G1 may be prevented from crystallizing, and the first functional material G1 may have a high glass transition temperature. In this way, the film-forming property of the first functional material G1 may be improved; and the thermal stability of the first functional material G1 may be improved, so that the life of the light-emitting device 100 may increase.

It will be noted that the structural formulas listed above are examples of the structure of the first functional material G1, but not limitations on the first functional material G1. Moreover, (G1-x) in the above structural formulas is a synonym for each structural formula and is not a part of the structure of the structural formula, where x is a positive integer.

In some embodiments, the first functional material G1 is selected from any of structures represented by the following general formula (I-A).

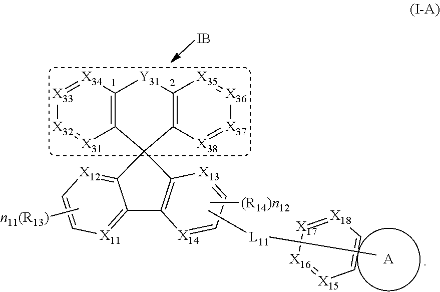

Where X₃₁, X₃₂, X₃₃, X₃₄, X₃₅, X₃₆, X₃₇ and X₃₈ are each independently selected from any of C(R_{c}) and N; and any two of X₃₁, X₃₂, X₃₃, X₃₄, X₃₅, X₃₆, X₃₇ and X₃₈ are the same or different. Here, C(R_{c}) is carbon substituted with R_{c}, and N is nitrogen.

Y₃₁ is selected from any of a direct bond, C(R_{d}Rₑ), O, S and Se. Here, C(R_{d}Rₑ) is carbon substituted with R_{d} and Rₑ, O is oxygen, S is sulfur, and Se is selenium.

R_{c}, R_{d} and Rₑ are the same or different. R_{c}, R_{d} and Rₑ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{c}, R_{d} and Rₑ are connected with an adjacent group to form substituted or unsubstituted 3- to 30-membered ring.

It will be noted that Y₃₁ may be a direct bond. In a case where Y₃₁ is a direct bond, a carbon of number 1 and a carbon of number 2 of the IB portion are directly connected by a covalent bond.

It will be noted that in a case where R_{c}, R_{d} and Rₑ are selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, or R_{c}, R_{d} and Rₑ are connected with an adjacent group to form substituted or unsubstituted 3- to 30-membered ring, the type and number of substituents are not limited here.

The description of the alkyl group of Cx, the alkenyl group of Cx and the like here may refer to the description of the alkylene group of Cx above; the description of the Z-membered heteroaryl group, the Z-membered heterocyclyl group, and the Z-membered ring here may refer to the description of the Z-membered heteroarylene group above; and details are not repeated here. The meanings of symbols in the general formula (I-A) other than those mentioned above have the same meanings as in the general formula (I).

It can be understood that in a case where R₁₁ and R₁₂ in the structure represented by the general formula (I) are connected to form the structure shown in the IB portion, the structure represented by the general formula (I) may be transformed into the structure represented by the general formula (I-A).

In a case where the first functional material G1 is selected from any of the structures represented by the general formula (I-A), the IB portion and the azafluorene group share the sp3 carbon atom to form a spirocyclic group. Since the spirocyclic group has an orthogonal stereo configuration, the stereoscopic property of the configuration of the first functional material G1 may be improved. Thus, the first functional material G1 may be prevented from crystallizing, and the first functional material G1 may have a high glass transition temperature. In this way, the film-forming property of the first functional material G1 may be improved; and the thermal stability of the first functional material G1 may be improved, so that the life of the light-emitting device 100 may increase.

The exemplary structures of the first functional material G1 having a structure as represented by the general formula (I-A) are described below.

In some examples, in a case where Y₃₁ is a direct bond, the structural formula of the first functional material G1 may be as shown below.

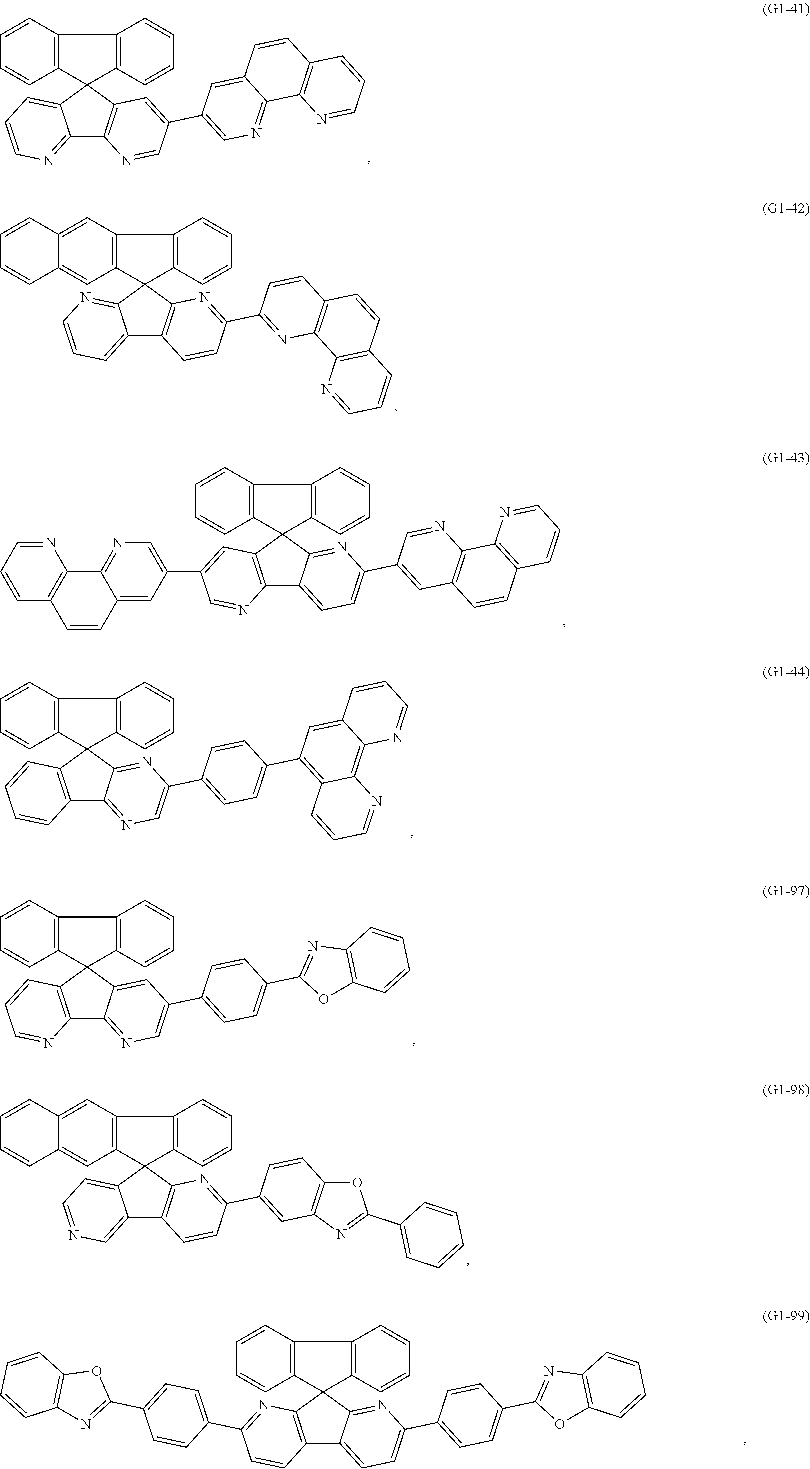

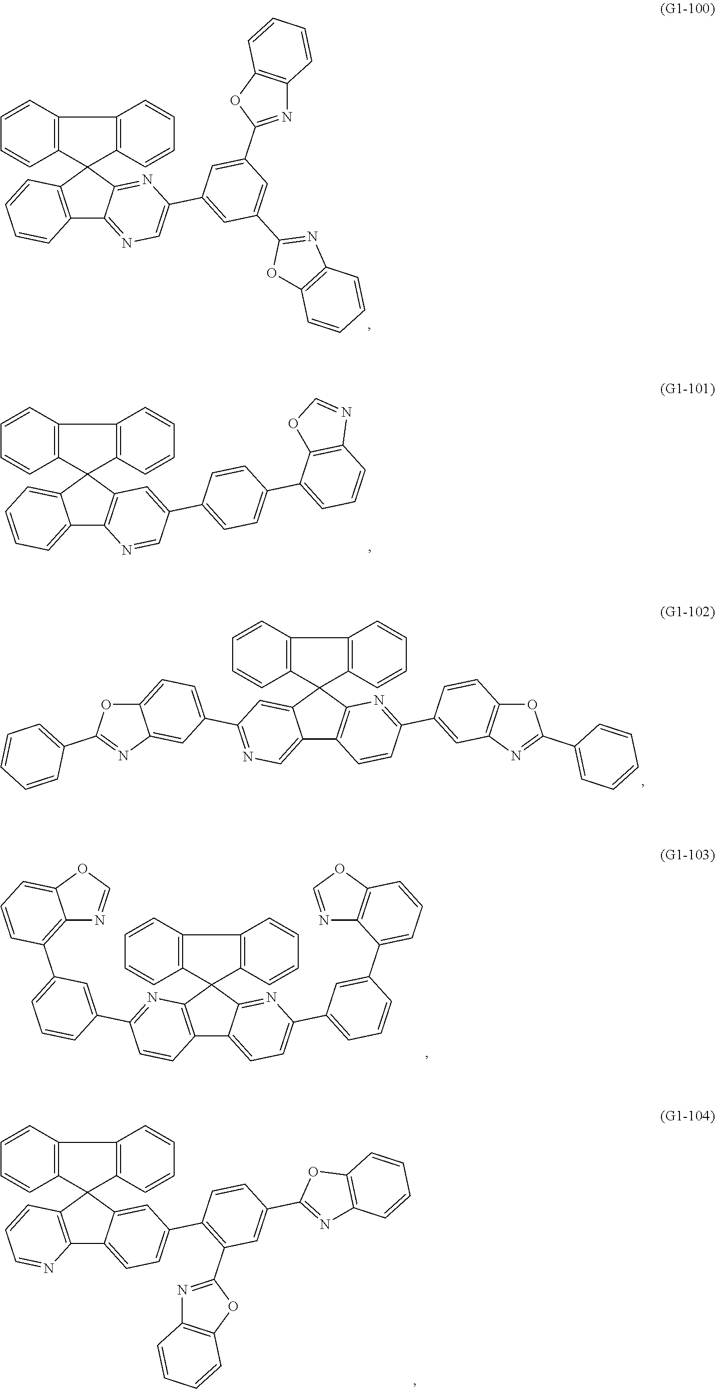 [SMILES: c1ccc2c(c1)-c1ccccc1C21c2ccccc2-c2ncc(-c3cc(-c4nc5ccccc5o4)cc(-c4nc5ccccc5o4)c3)nc21 ; c1ccc2c(c1)-c1ccccc1C21c2ccccc2-c2ncc(-c3ccc(-c4cccc5ncoc45)cc3)cc21 ; c1ccc(-c2nc3cc(-c4cc5c(cn4)-c4ccc(-c6ccc7oc(-c8ccccc8)nc7c6)nc4C54c5ccccc5-c5ccccc54)ccc3o2)cc1 ; c1cc(-c2ccc3c(n2)C2(c4ccccc4-c4ccccc42)c2nc(-c4cccc(-c5cccc6ocnc56)c4)ccc2-3)cc(-c2cccc3ocnc23)c1 ; c1ccc2c(c1)-c1ccccc1C21c2cc(-c3ccc(-c4nc5ccccc5o4)cc3-c3nc4ccccc4o3)ccc2-c2ncccc21]

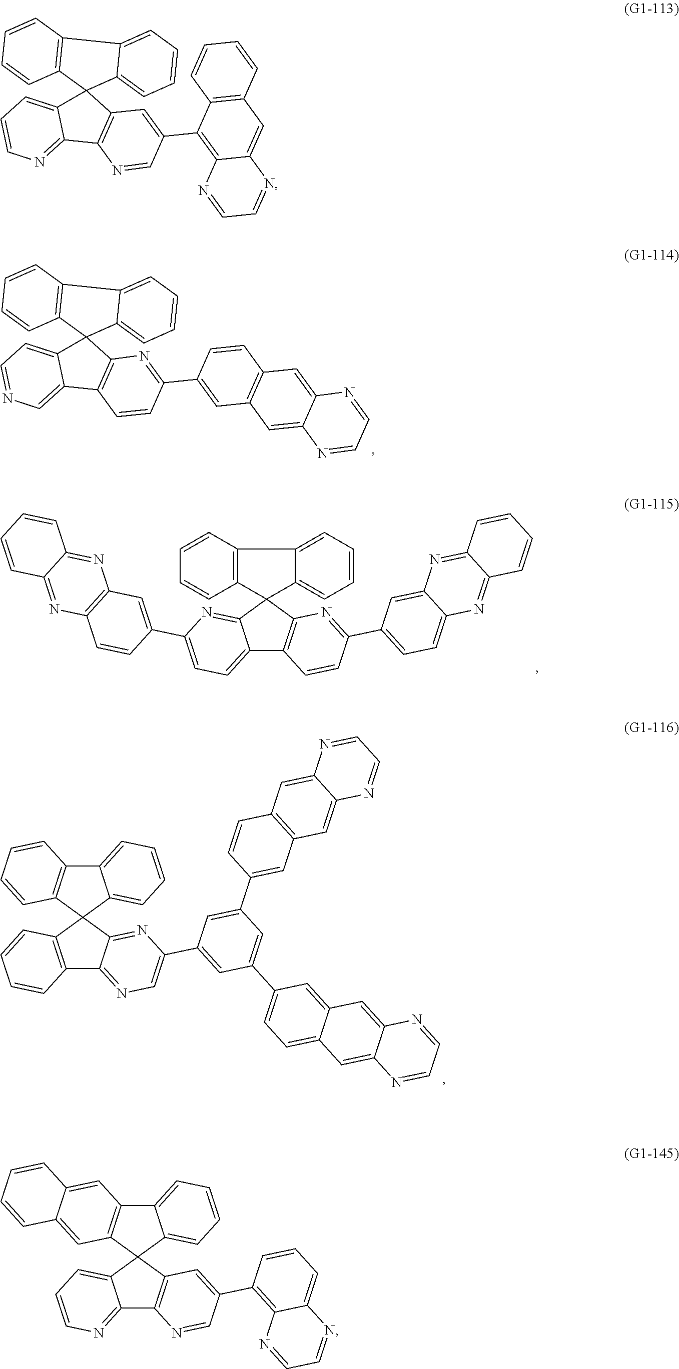 [SMILES: c1ccc2c(c1)-c1ccccc1C21c2cccnc2-c2ncc(-c3c4ccccc4cc4nccnc34)cc21 ; c1ccc2c(c1)-c1ccccc1C21c2ccncc2-c2ccc(-c3ccc4cc5nccnc5cc4c3)nc21 ; c1ccc2c(c1)-c1ccccc1C21c2nc(-c3ccc4nc5ccccc5nc4c3)ccc2-c2ccc(-c3ccc4nc5ccccc5nc4c3)nc21 ; c1ccc2c(c1)-c1ccccc1C21c2ccccc2-c2ncc(-c3cc(-c4ccc5cc6nccnc6cc5c4)cc(-c4ccc5cc6nccnc6cc5c4)c3)nc21 ; c1ccc2c(c1)-c1cc3ccccc3cc1C21c2cccnc2-c2ncc(-c3cccc4nccnc34)cc21]

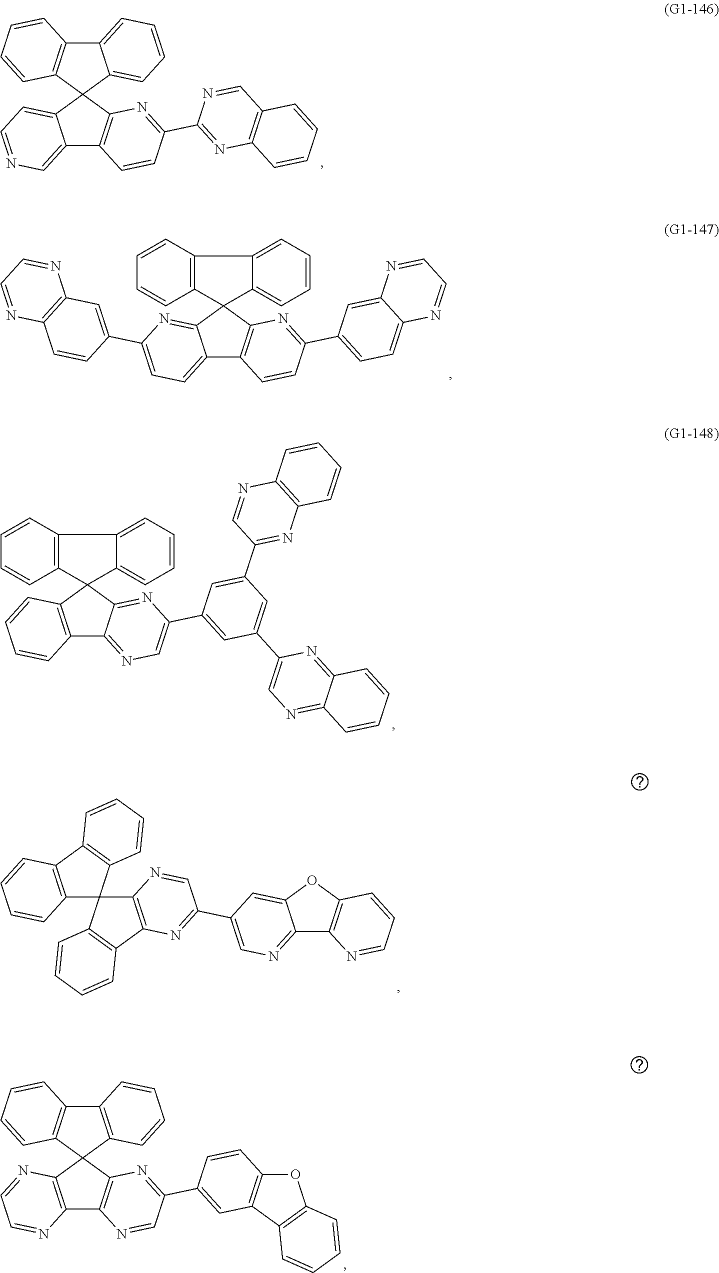 [SMILES: c1ccc2c(c1)-c1ccccc1C21c2ccncc2-c2ccc(-c3ncc4ccccc4n3)nc21 ; c1ccc2c(c1)-c1ccccc1C21c2nc(-c3ccc4nccnc4c3)ccc2-c2ccc(-c3ccc4nccnc4c3)nc21 ; c1ccc2c(c1)-c1ccccc1C21c2ccccc2-c2ncc(-c3cc(-c4cnc5ccccc5n4)cc(-c4cnc5ccccc5n4)c3)nc21 ; c1ccc2c(c1)-c1ccccc1C21c2ccccc2-c2nc(-c3cnc4c(c3)oc3cccnc34)cnc21 ; c1ccc2c(c1)-c1ccccc1C21c2nccnc2-c2ncc(-c3ccc4oc5ccccc5c4c3)nc21]

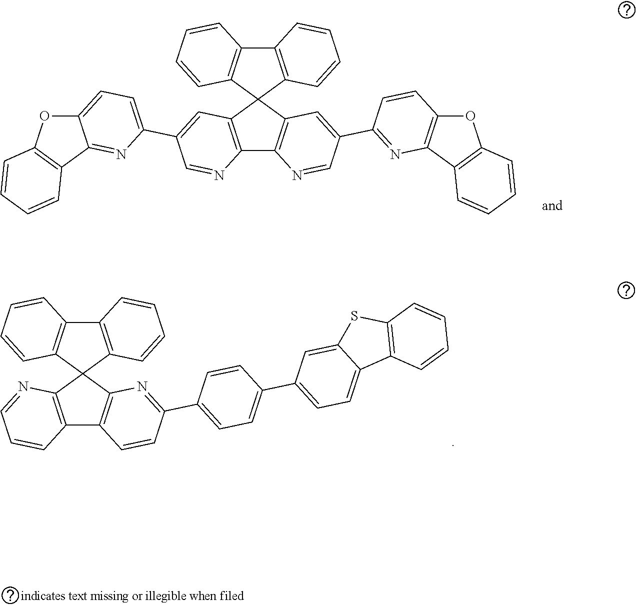 [SMILES: c1ccc2c(c1)-c1ccccc1C21c2cc(-c3ccc4oc5ccccc5c4n3)cnc2-c2ncc(-c3ccc4oc5ccccc5c4n3)cc21 ; c1ccc2c(c1)-c1ccccc1C21c2ncccc2-c2ccc(-c3ccc(-c4ccc5c(c4)sc4ccccc45)cc3)nc21]

In some examples, in a case where Y₃₁ is substituted carbon, the structural formula of the first functional material G1 may be as shown below.

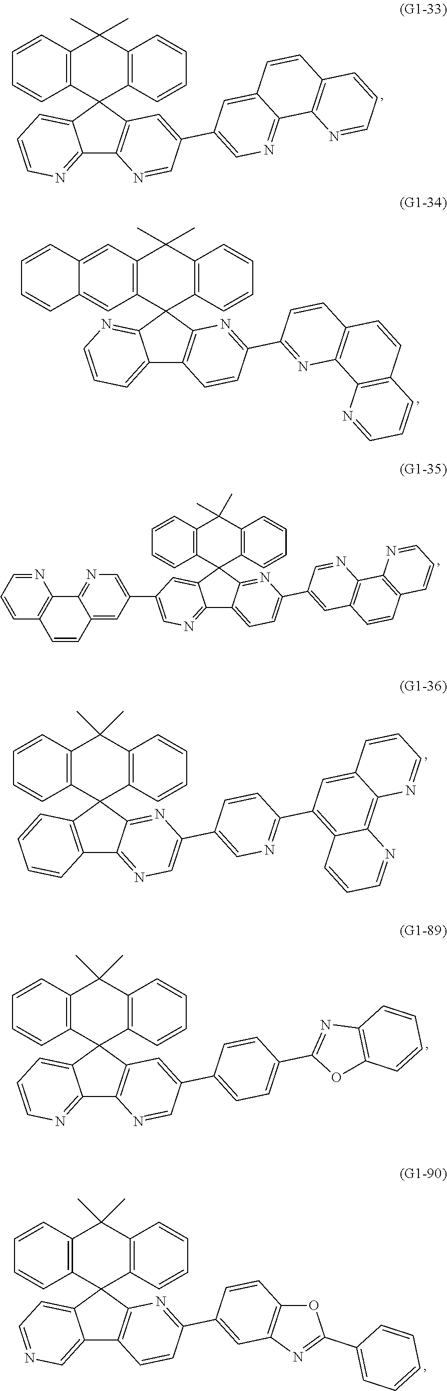 [SMILES: CC1(C)c2ccccc2C2(c3ccccc31)c1cccnc1-c1ncc(-c3cnc4c(ccc5cccnc54)c3)cc12 ; CC1(C)c2ccccc2C2(c3cc4ccccc4cc31)c1ncccc1-c1ccc(-c3ccc4ccc5cccnc5c4n3)nc12 ; CC1(C)c2ccccc2C2(c3ccccc31)c1cc(-c3cnc4c(ccc5cccnc54)c3)cnc1-c1ccc(-c3cnc4c(ccc5cccnc54)c3)nc12 ; CC1(C)c2ccccc2C2(c3ccccc3-c3ncc(-c4ccc(-c5cc6cccnc6c6ncccc56)nc4)nc32)c2ccccc21 ; CC1(C)c2ccccc2C2(c3ccccc31)c1cccnc1-c1ncc(-c3ccc(-c4nc5ccccc5o4)cc3)cc12 ; CC1(C)c2ccccc2C2(c3ccncc3-c3ccc(-c4ccc5oc(-c6ccccc6)nc5c4)nc32)c2ccccc21]

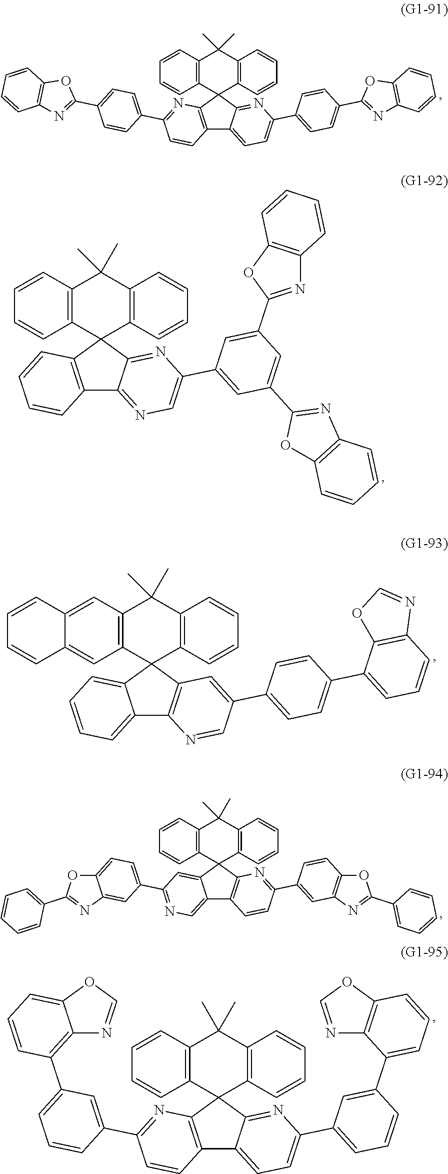 [SMILES: CC1(C)c2ccccc2C2(c3ccccc31)c1nc(-c3ccc(-c4nc5ccccc5o4)cc3)ccc1-c1ccc(-c3ccc(-c4nc5ccccc5o4)cc3)nc12 ; CC1(C)c2ccccc2C2(c3ccccc3-c3ncc(-c4cc(-c5nc6ccccc6o5)cc(-c5nc6ccccc6o5)c4)nc32)c2ccccc21 ; CC1(C)c2ccccc2C2(c3ccccc3-c3ncc(-c4ccc(-c5cccc6ncoc56)cc4)cc32)c2cc3ccccc3cc21 ; CC1(C)c2ccccc2C2(c3cc(-c4ccc5oc(-c6ccccc6)nc5c4)ncc3-c3ccc(-c4ccc5oc(-c6ccccc6)nc5c4)nc32)c2ccccc21 ; CC1(C)c2ccccc2C2(c3ccccc31)c1nc(-c3cccc(-c4cccc5ocnc45)c3)ccc1-c1ccc(-c3cccc(-c4cccc5ocnc45)c3)nc12]

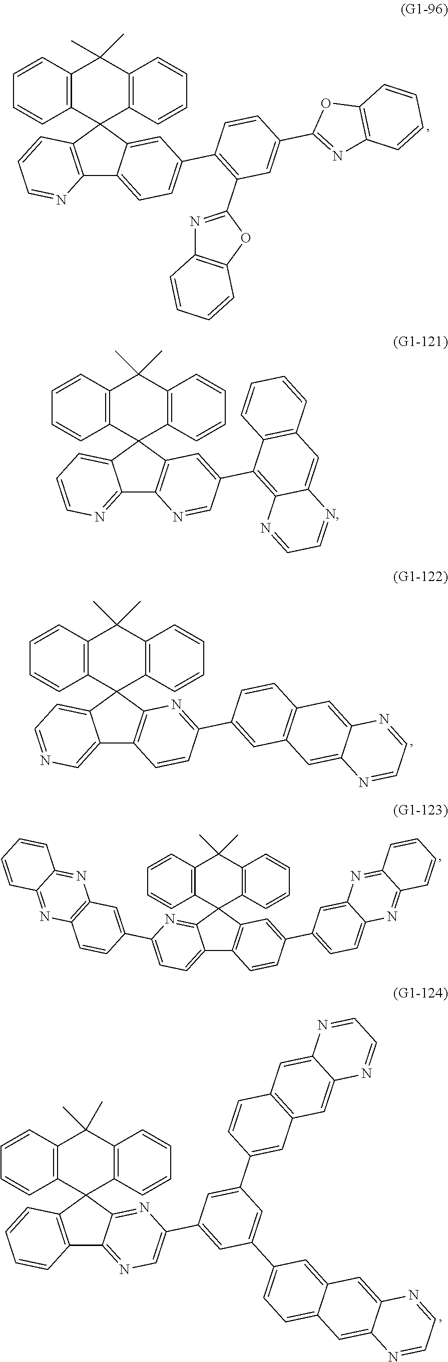

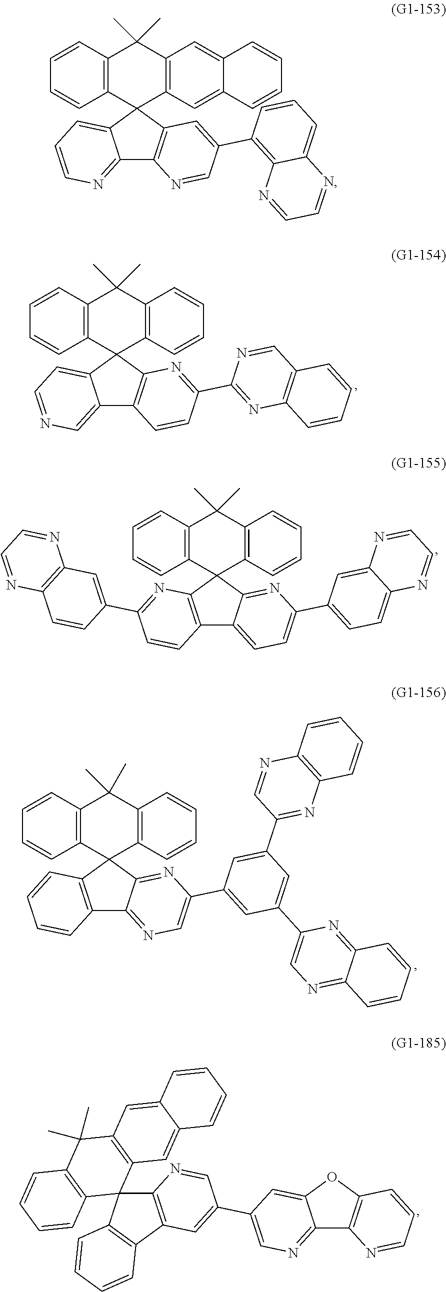 [SMILES: CC1(C)c2ccccc2C2(c3cc4ccccc4cc31)c1cccnc1-c1ncc(-c3cccc4nccnc34)cc12 ; CC1(C)c2ccccc2C2(c3ccncc3-c3ccc(-c4ncc5ccccc5n4)nc32)c2ccccc21 ; CC1(C)c2ccccc2C2(c3ccccc31)c1nc(-c3ccc4nccnc4c3)ccc1-c1ccc(-c3ccc4nccnc4c3)nc12 ; CC1(C)c2ccccc2C2(c3ccccc3-c3ncc(-c4cc(-c5cnc6ccccc6n5)cc(-c5cnc6ccccc6n5)c4)nc32)c2ccccc21 ; CC1(C)c2ccccc2C2(c3ccccc3-c3cc(-c4cnc5c(c4)oc4cccnc45)cnc32)c2cc3ccccc3cc21]

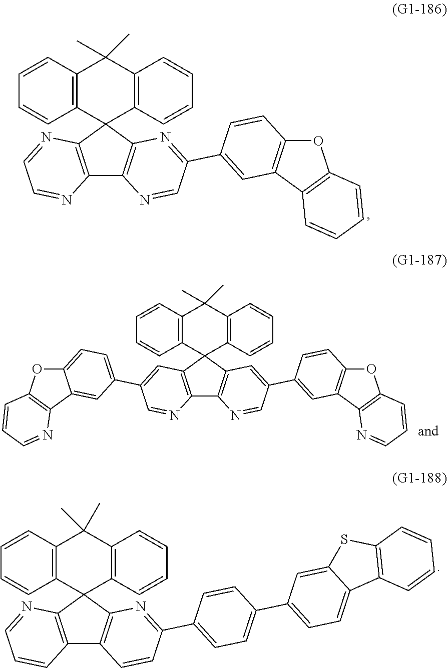 [SMILES: CC1(C)c2ccccc2C2(c3ccccc31)c1nccnc1-c1ncc(-c3ccc4oc5ccccc5c4c3)nc12 ; CC1(C)c2ccccc2C2(c3ccccc31)c1cc(-c3ccc4oc5cccnc5c4c3)cnc1-c1ncc(-c3ccc4oc5cccnc5c4c3)cc12 ; CC1(C)c2ccccc2C2(c3ccccc31)c1ncccc1-c1ccc(-c3ccc(-c4ccc5c(c4)sc4ccccc45)cc3)nc12]

In some examples, in a case where Y₃₁ is oxygen, the structural formula of the first functional material G1 may be as shown below.

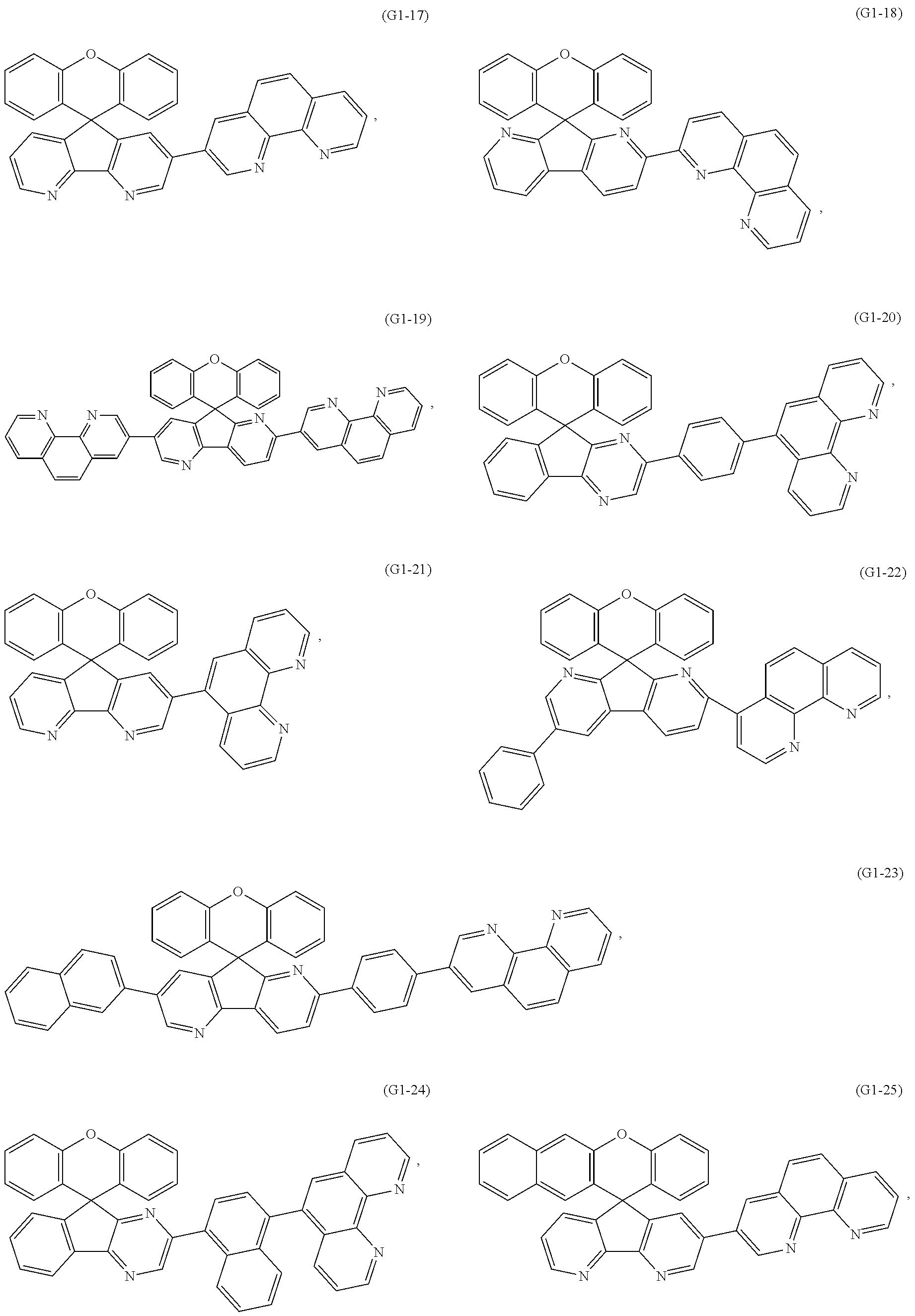

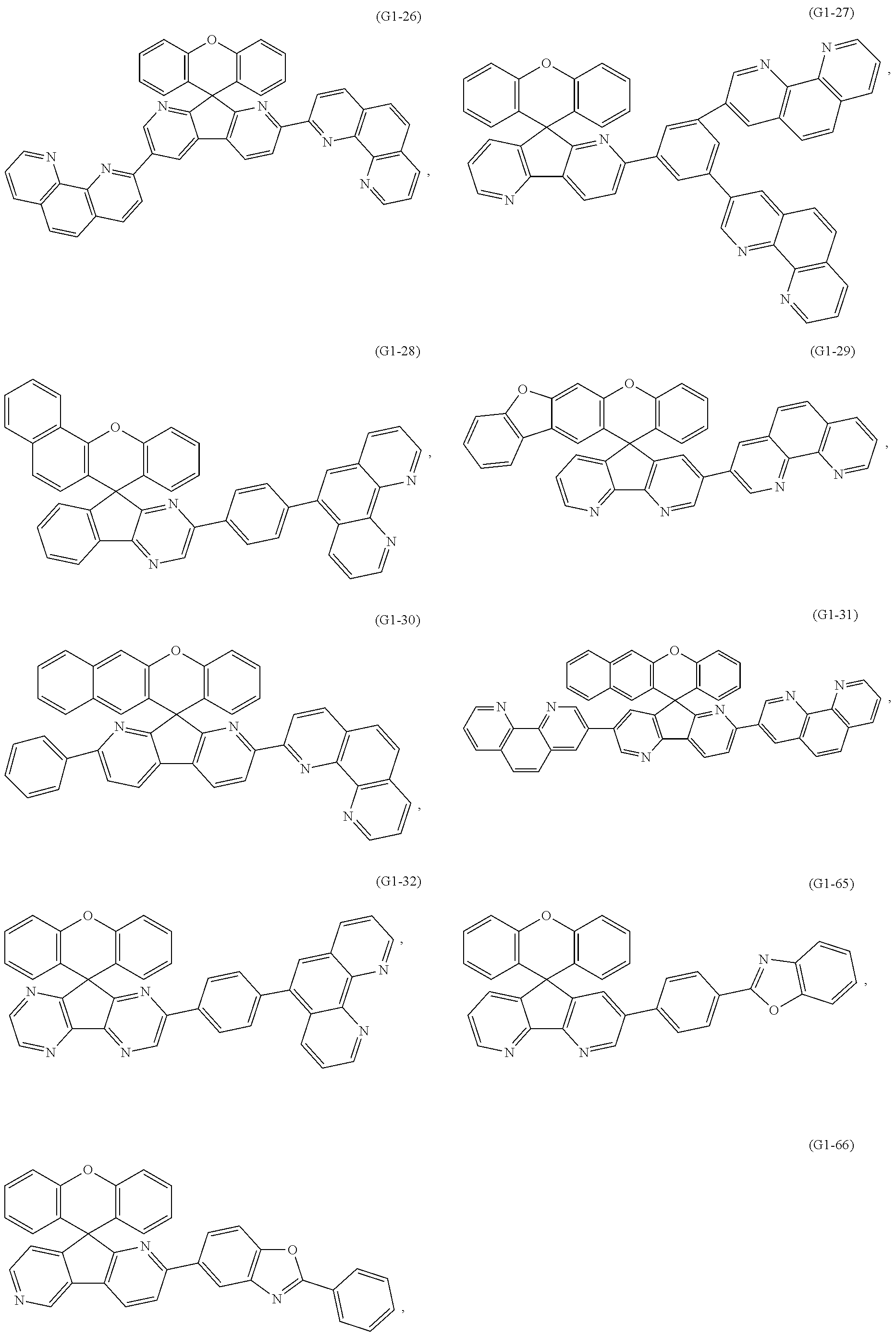

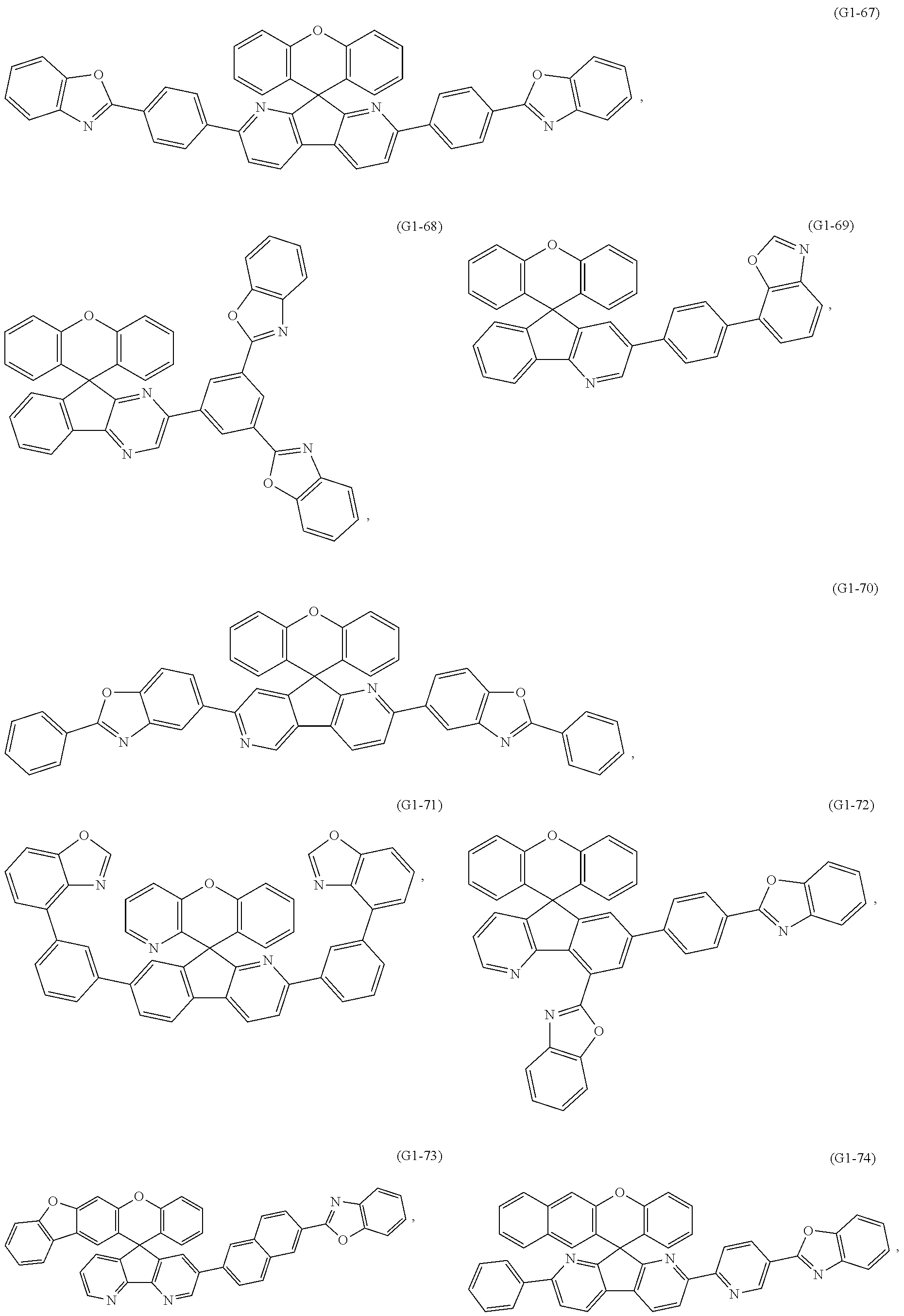

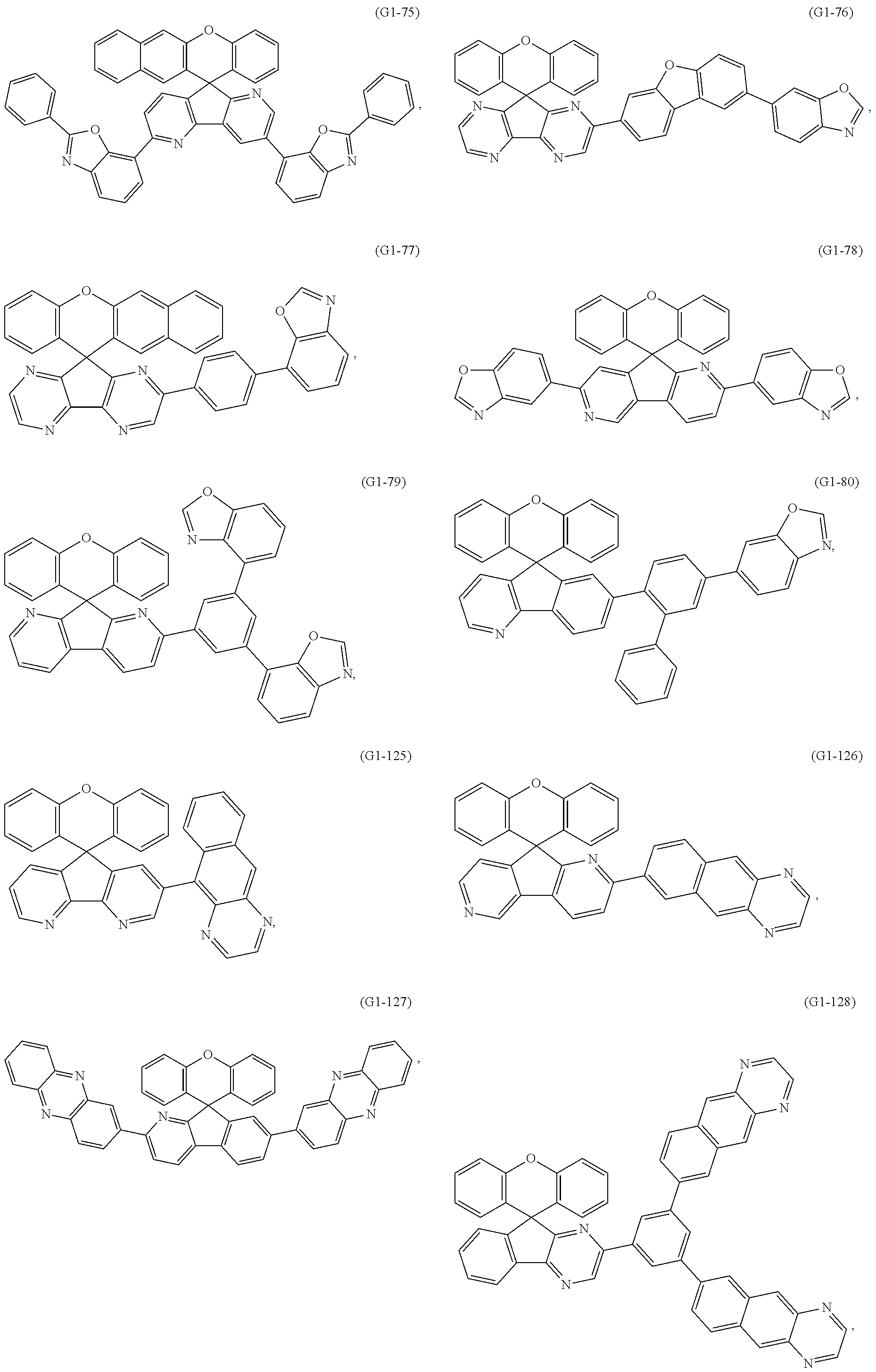

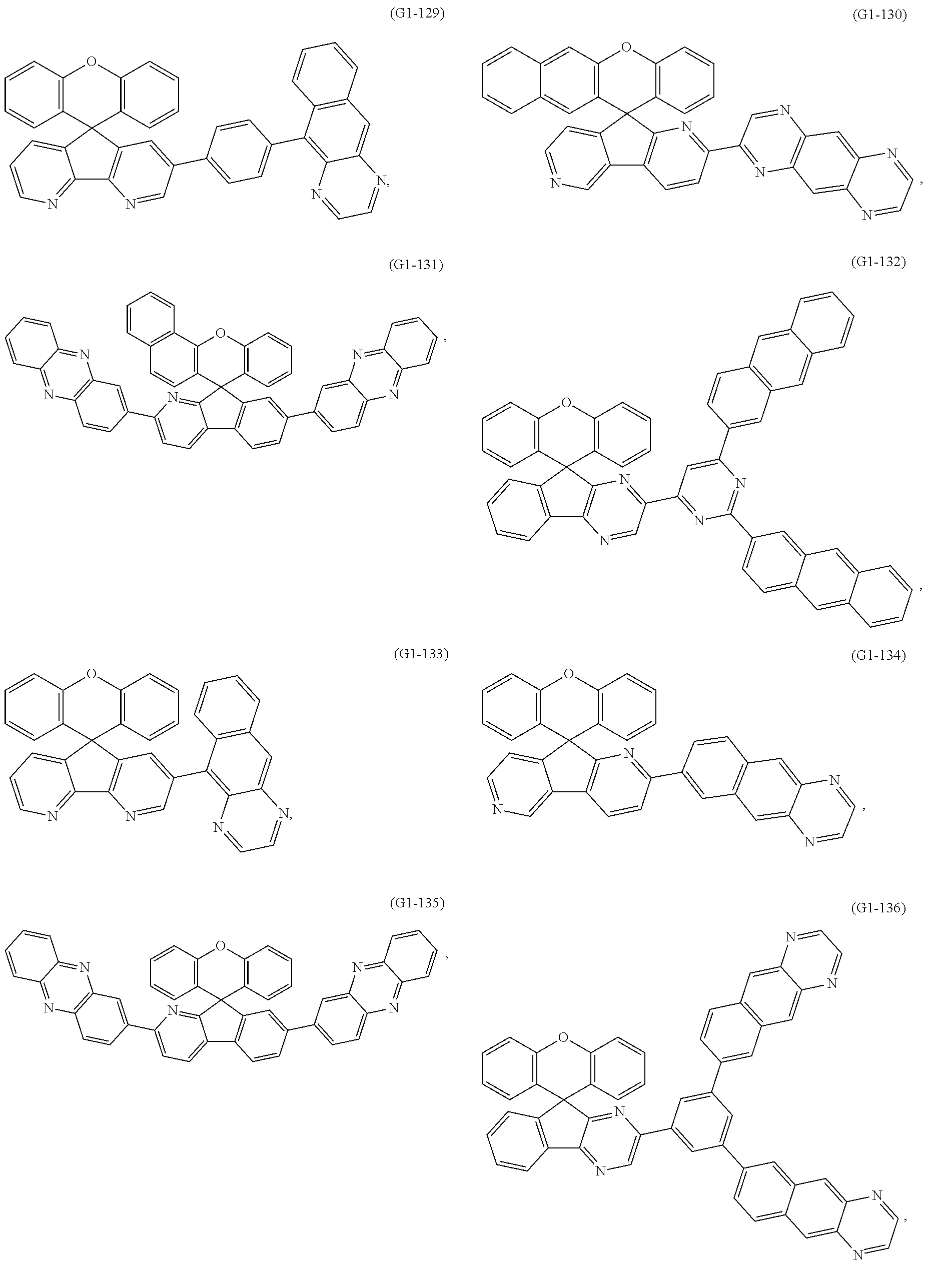

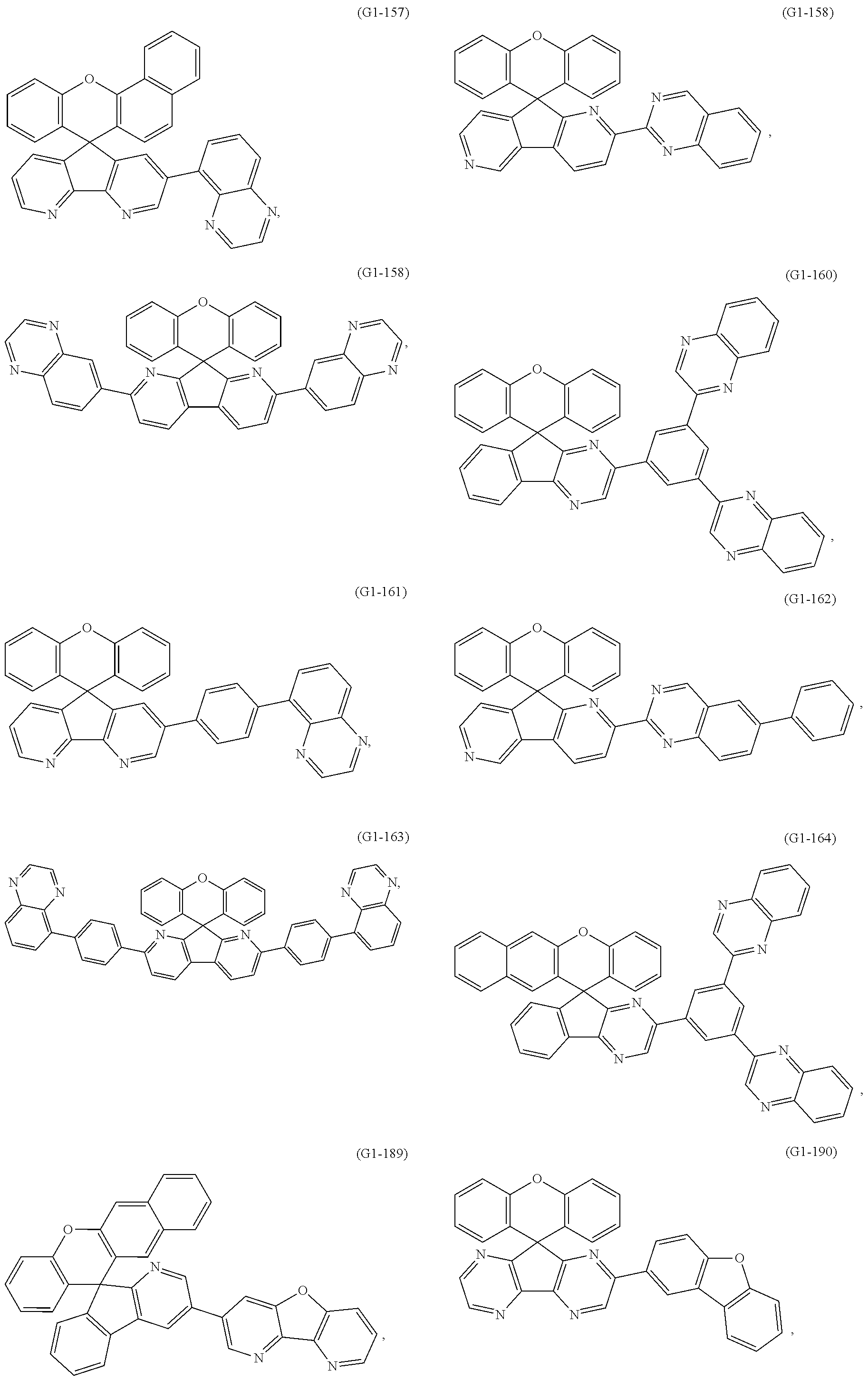

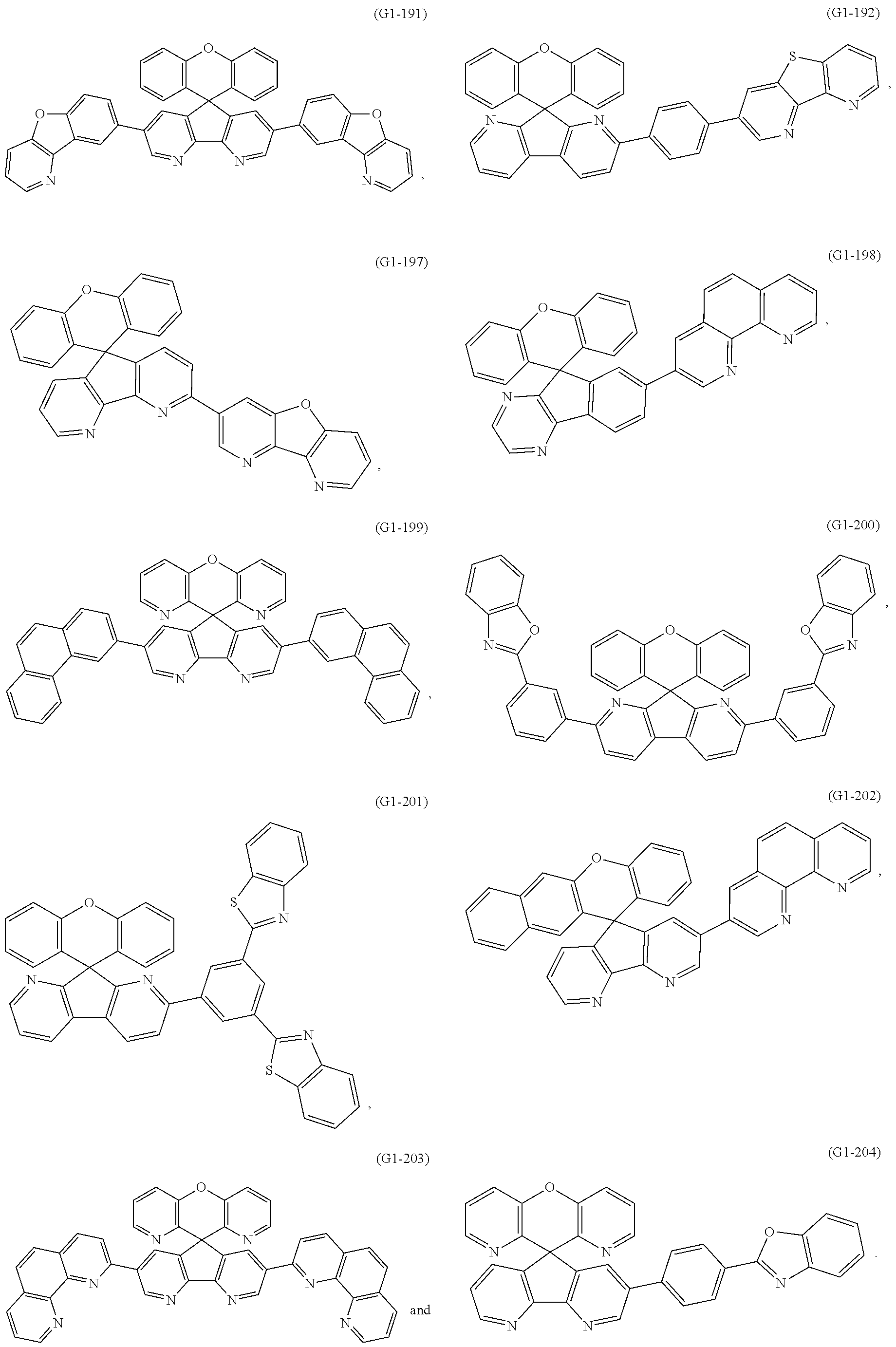

In some examples, in a case where Y₃₁ is sulfur, the structural formula of the first functional material G1 may be as shown below.

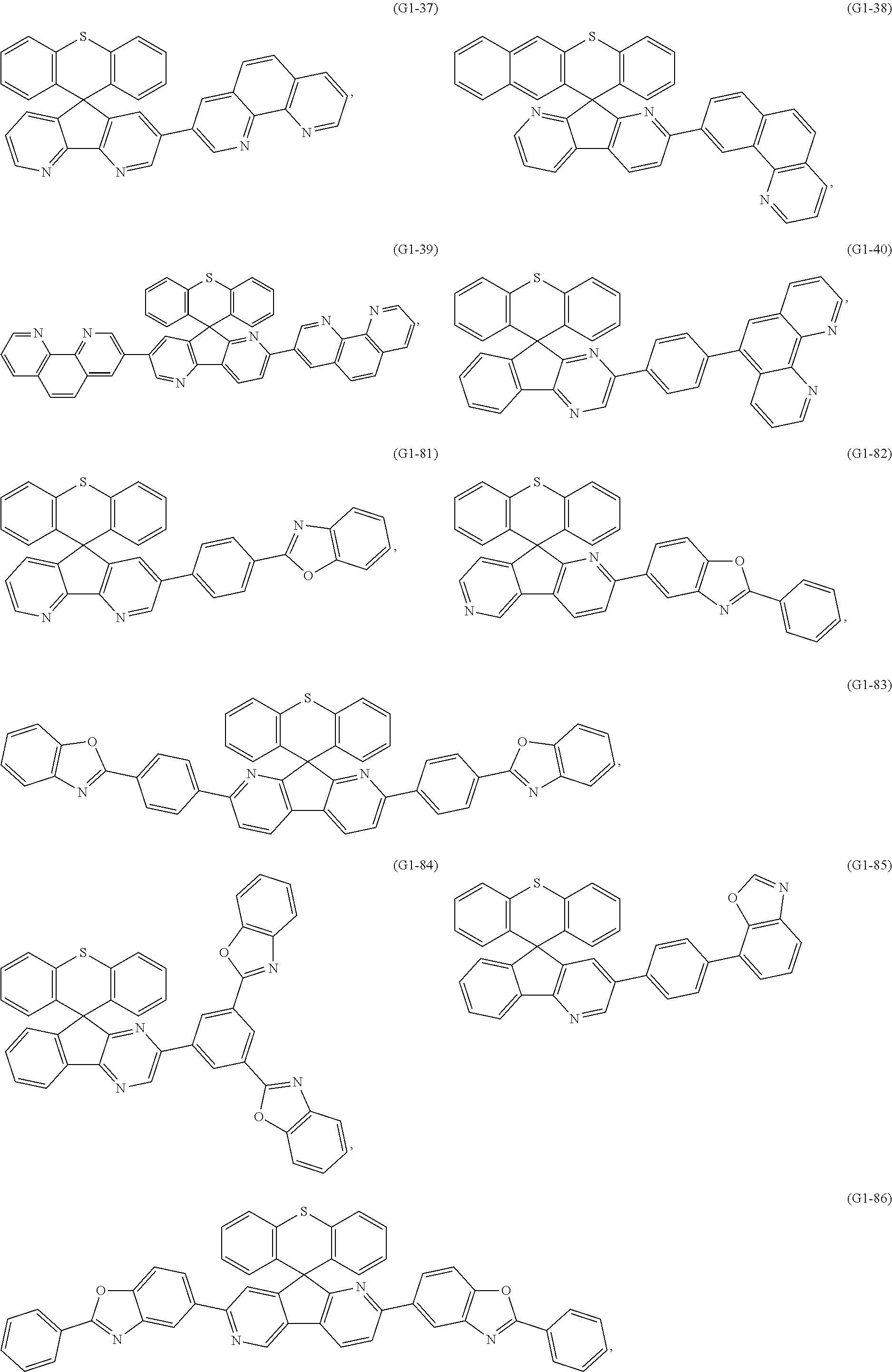

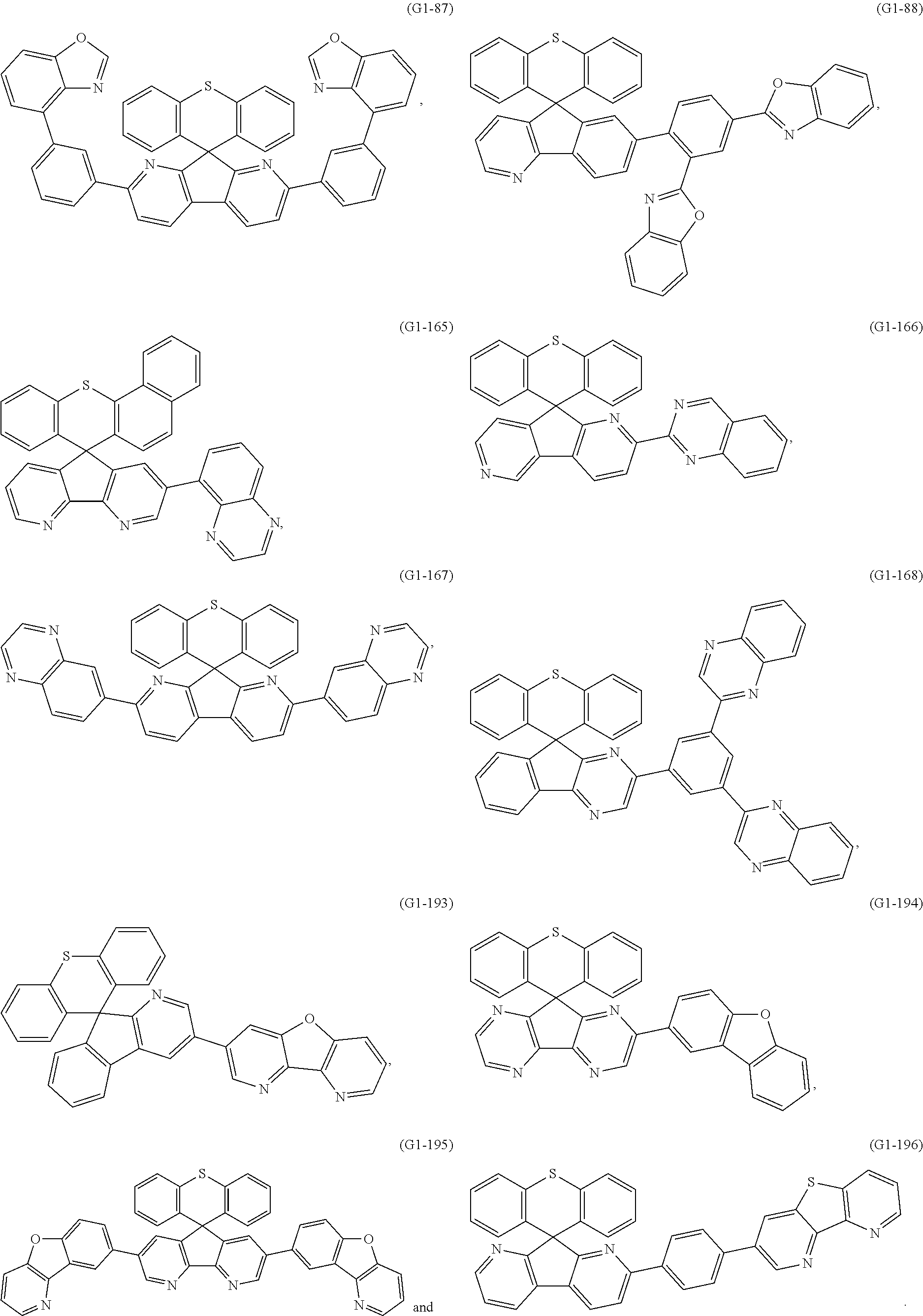

It will be noted that the structural formulas listed above are examples of the structure of the first functional material G1, but not limitations on the first functional material G1. Moreover, (G1-x) in the above structural formulas is a synonym for each structural formula and is not a part of the structure of the structural formula, where x is a positive integer.

In some embodiments, R₁₁ is a phenyl group; and R₁₂ is a phenyl group.

It can be understood that in a case where R₁₁ and R₁₂ in the structure represented by the general formula (I) are both phenyl groups, R₁₁, R₁₂ and the azafluorene group share the sp3 carbon atom. There is a certain angle between a plane where the benzene ring of R₁₁ is located and a plane where the azafluorene group is located, and there is a certain angle between a plane where the benzene ring of R₁₂ is located and the plane where the azafluorene group is located. The stereoscopic property of the configuration of the first functional material G1 may be improved. Thus, the first functional material G1 may be prevented from crystallizing, and the first functional material G1 may have a high glass transition temperature. In this way, the film-forming property of the first functional material G1 may be improved; and the thermal stability of the first functional material G1 may be improved, so that the life of the light-emitting device 100 may increase.

The exemplary structures of the first functional material G1 having a structure as represented by the general formula (I) are described below in a case where R₁₁ and R₁₂ are both phenyl groups.

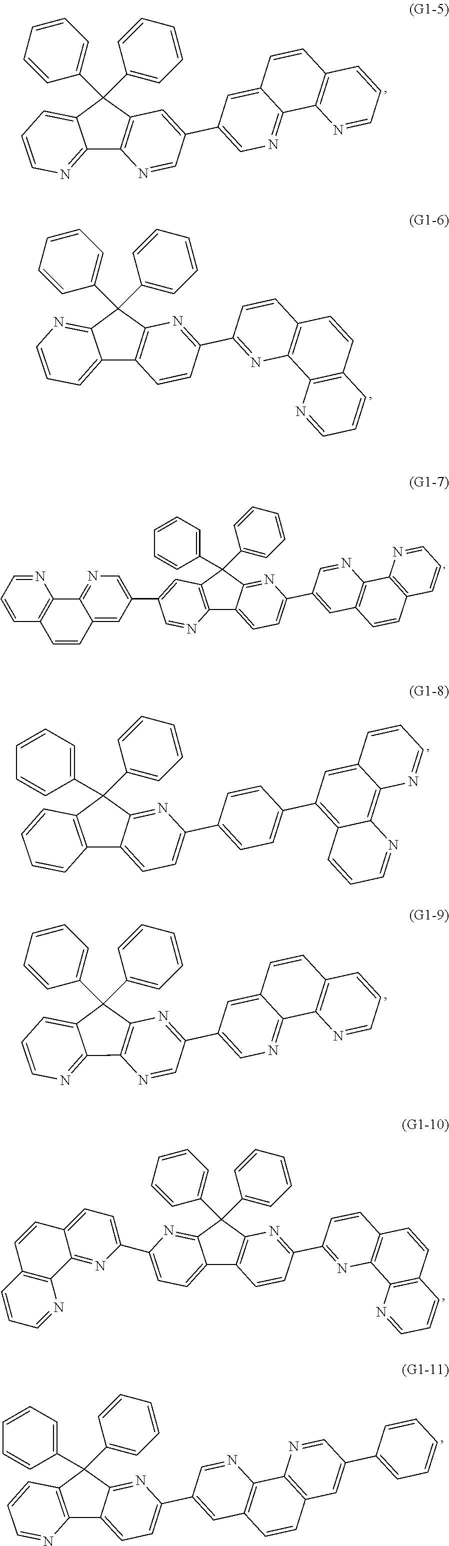

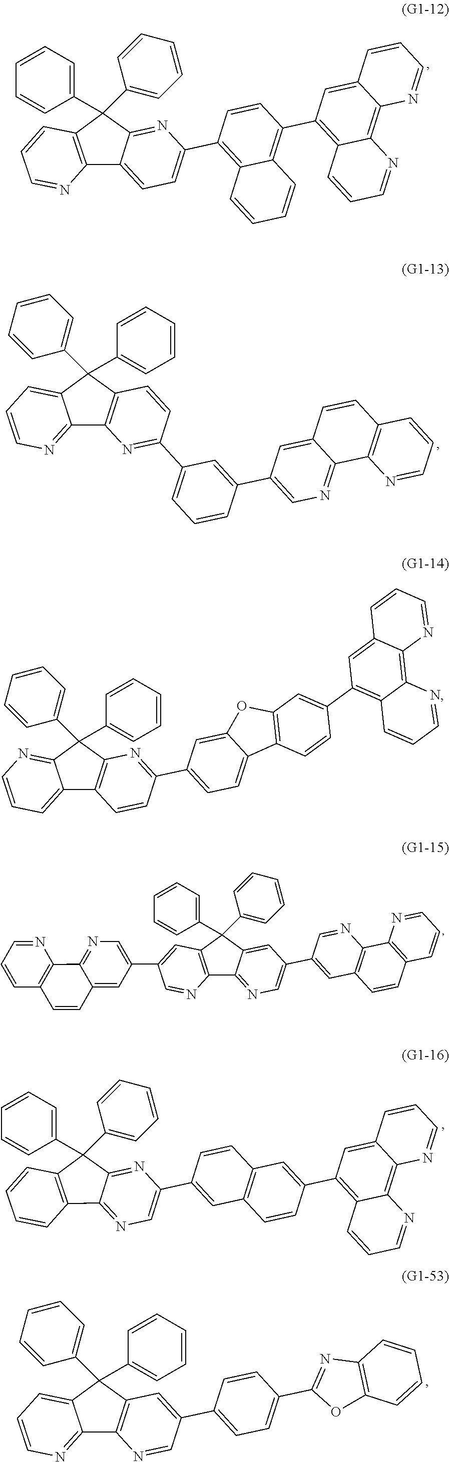

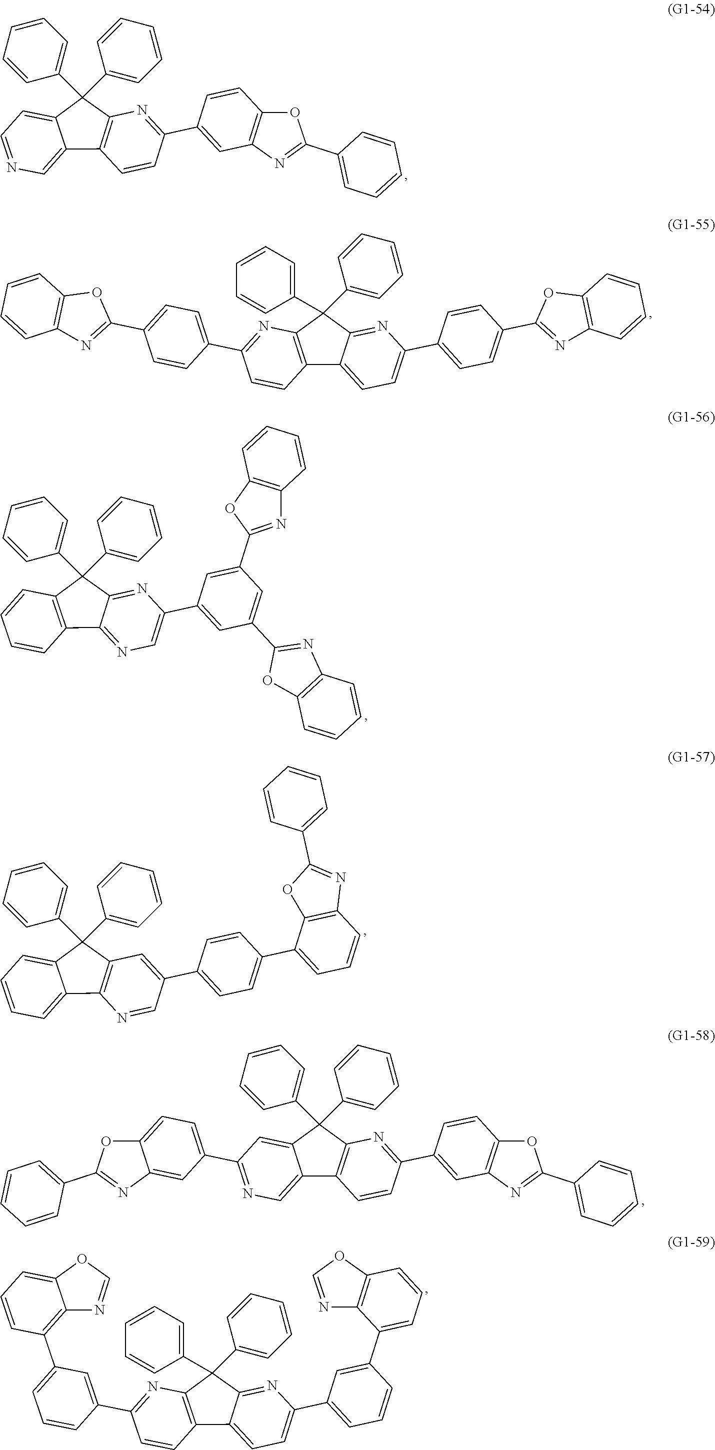

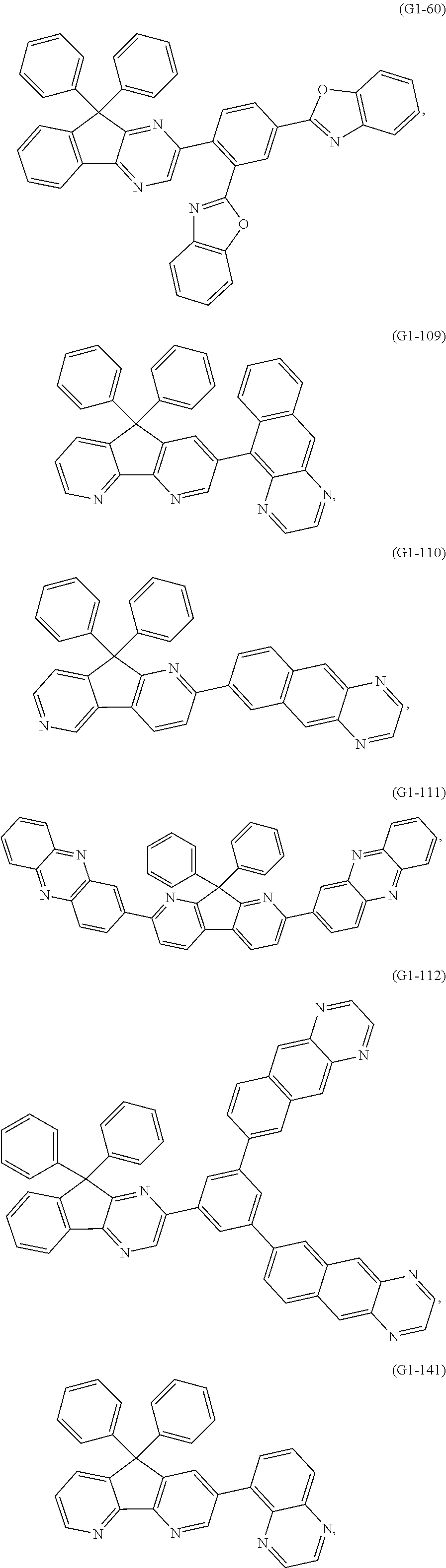

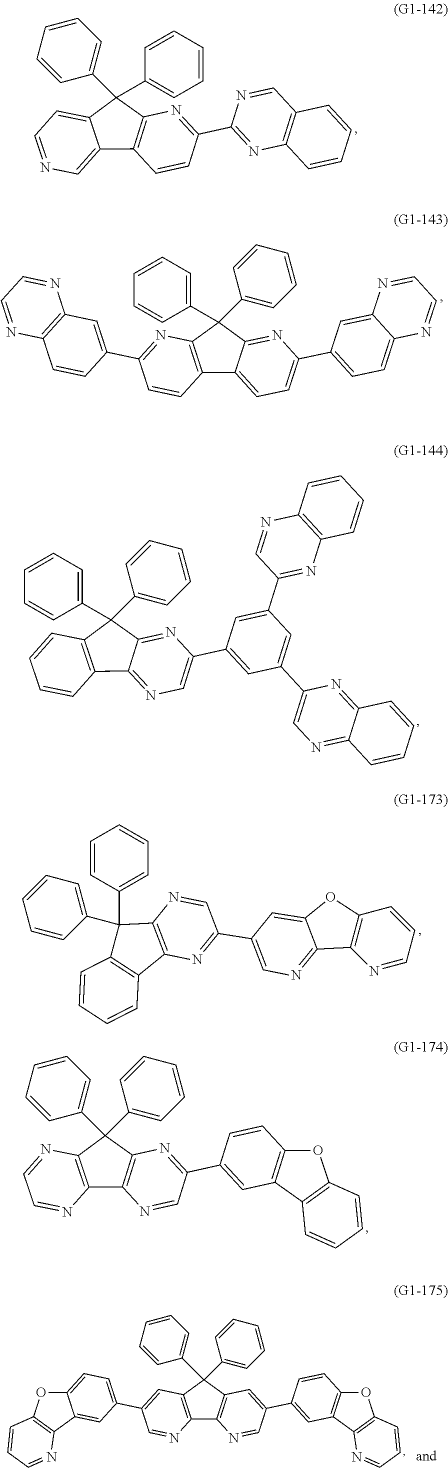

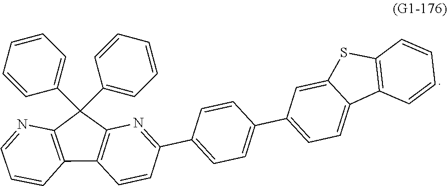

It will be noted that the structural formulas listed above are examples of the structure of the first functional material G1, but not limitations on the first functional material G1. Moreover, (G1-x) in the above structural formulas is a synonym for each structural formula and is not a part of the structure of the structural formula, where x is a positive integer.

In some embodiments, A is selected from any of structures represented by the general formula (A1-1), the general formula (A1-2), the general formula (A1-3) and the general formula (A1-4).

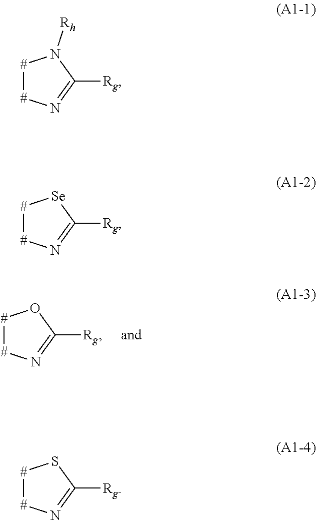

Where #indicates a fusion site.

R_{g} and Rₕ are the same or different. R_{g} and Rₕ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{g} and Rₕ are connected with an adjacent group to form substituted or unsubstituted 3- to 30-membered ring.

It will be noted that #represents a fusion site, which means that the A ring and the six-membered ring including X₁₅, X₁₆, X₁₇ and X₁₈ form the IA portion by sharing the atom located at the fusion site.

It will be noted that in a case where R_{g} or Rₕ is selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, the type and number of substituents are not limited here.

The description of the alkyl group of Cx, the alkenyl group of Cx and the like here may refer to the description of the alkylene group of Cx above; the description of the Z-membered heteroaryl group, the Z-membered heterocyclyl group, and the Z-membered ring here may refer to the description of the Z-membered heteroarylene group above; and details are not repeated here.

It will be noted that in a case where A is selected from any of the structures represented by the general formula (A1-1), the general formula (A1-2), the general formula (A1-3) and the general formula (A1-4), and L₁₁ in the structure represented by the general formula (I) is connected to the carbon on the A ring that is connected to R_{g}, R_{g} may not be present.

It will be noted that in a case where A is selected from any of the structures represented by the general formula (A1-1), the general formula (A1-2), the general formula (A1-3) and the general formula (A1-4), the types of R₁₁ and R₁₂ are not limited here. That is, R₁₁ and R₁₂ may each be independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₁₁ and R₁₂ are connected with an adjacent group to form substituted or unsubstituted 3- to 30-membered ring. In particular, R₁₁ and R₁₂ may be connected to form a six-membered ring, or R₁₁ and R₁₂ may be connected to form the structure shown in the IB portion, or R₁₁ and R₁₂ may both be phenyl groups.

It can be understood that in a case where A in the general formula (I) is selected from one of the structures shown in

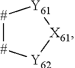

A may be the structure represented by the general formulas (A1-1), (A1-2), (A1-3) or (A1-4). In a case where Y₆₁ is —N(Rₕ)—, Y₆₂ is —N═, and X₆₁ is —C(R_{g})═, A has a structure represented by the general formula (A1-1), and in this case, A is an imidazole ring. In a case where Y₆₁ is —Se—, Y₆₂ is —N═, and X₆₁ is —C(R_{g})═, A has a structure represented by the general formula (A1-2), and in this case, A is a selenium-nitrogen heterocycle. In a case where Y₆₁ is —O—, Y₆₂ is —N═, and X₆₁ is —C(R_{g})═, A has a structure represented by the general formula (A1-3), and in this case, A is an oxazole ring. In a case where Y₆₁ is —S—, Y₆₂ is —N═, and X₆₁ is —C(R_{g})═, A has a structure represented by the general formula (A1-4), and in this case, A is a thiazole ring.

In a case where A is selected from any of the structures represented by the general formula (A1-1), the general formula (A1-2), the general formula (A1-3) and the general formula (A1-4), A may be one of an imidazole ring, a selenium-nitrogen heterocycle, an oxazole ring and a thiazole ring. In this way, since the imidazole ring, the selenium-nitrogen heterocycle, the oxazole ring and the thiazole ring all have a certain electron-withdrawing ability, the electron transport property of the first functional material G1 may be improved, so that the first functional material G1 may have a relatively high electron mobility, and the recombination probability of excitons may increase, thereby improving the efficiency and life of the light-emitting device 100. Moreover, in a case where the molecular weight of A is low, the molecular weight of the first functional material G1 is relatively low, so that the stability of the first functional material G1 is relatively low; and in a case where the molecular weight of A is high, the molecular weight of the first functional material G1 is relatively high, so that the difficulty of synthesizing the first functional material G1 may increase, and the matching with the preparation process (e.g., the evaporation process) of the first functional layer is relatively poor. Therefore, setting A to be one of the imidazole ring, the selenium-nitrogen heterocycle, the oxazole ring and the thiazole ring may make the molecular weight of A within a suitable range, so that the difficulty of synthesizing the first functional material G1 may be reduced while the stability of the first functional material G1 is ensured, and the matching of the first functional material G1 with the preparation process (e.g., the evaporation process) of the first functional layer may be improved.

The exemplary structures of the first functional material G1 are described below in a case where A is selected from any of the structures represented by the general formula (A1-1), the general formula (A1-2), the general formula (A1-3) and the general formula (A1-4).

In some examples, in a case where A is selected from the structure shown in the general formula (A1-3), the structural formula of the first functional material G1 may be as shown in (G1-49) to (G1-104), (G1-200) and (G1-204).

In some examples, in a case where A is selected from the structure shown in the general formula (A1-4), the structural formula of the first functional material G1 may be as shown in (G1-201).

It will be noted that the structural formulas listed above are examples of the structure of the first functional material G1, but not limitations on the first functional material G1.

In some embodiments, A is selected from any of the structures represented by the general formula (A2), the general formula (A3), the general formula (A4) and the general formula (A5).

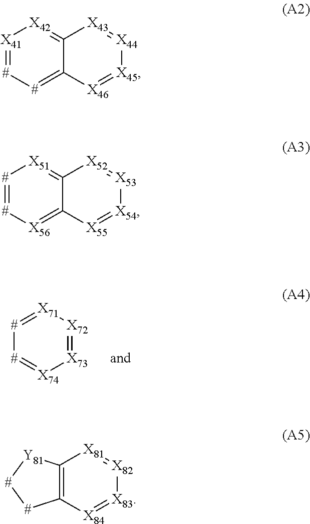

Where #indicates a fusion site.

X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are each independently selected from any of C(R_{f}) and N; any two of X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are the same or different; and C(R_{f}) is carbon substituted with R_{f}, and N is nitrogen.

Y₈₁ is selected from any of C(RᵢRⱼ), N(Rₖ), O, S and Se. C(RᵢRⱼ) is carbon substituted by Rᵢ and Rⱼ, N(Rₖ) is nitrogen substituted by Rₖ, O is oxygen, S is sulfur, and Se is selenium.

R_{f}, Rᵢ, Rⱼ and Rₖ are the same or different. R_{f}, Rᵢ, Rⱼ and Rₖ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{f}, Rᵢ, Rⱼ and Rₖ are connected with an adjacent group to form substituted or unsubstituted 3- to 30-membered ring.

It will be noted that in a case where R_{f}, Rᵢ, Rⱼ or Rₖ is selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, the type and number of substituents are not limited here.

The description of the alkyl group of Cx, the alkenyl group of Cx and the like here may refer to the description of the alkylene group of Cx above; the description of the Z-membered heteroaryl group, the Z-membered heterocyclyl group, and the Z-membered ring here may refer to the description of the Z-membered heteroarylene group above; the description of the fusion site here may refer to the description of the fusion site above; and details are not repeated here.

It will be noted that in a case where A is selected from any of the structures represented by the general formula (A2), the general formula (A3), the general formula (A4) and the general formula (A5), and L₁₁ in the structure represented by the general formula (I) is connected to the atom on the A ring that is connected to R_{f}, R_{f} may not be present. For understanding of other matters such as L₁₁ is connected to the atoms on the A ring that is connected to Rᵢ, Rⱼ and Rₖ, reference may be made to the above contents and details are not repeated here.

It will be noted that in a case where A is selected from any of the structures represented by the general formula (A2), the general formula (A3), the general formula (A4) and the general formula (A5), the types of R₁₁ and R₁₂ are not limited here. That is, R₁₁ and R₁₂ may each be independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₁₁ and R₁₂ are connected with an adjacent group to form substituted or unsubstituted 3- to 30-membered ring. In particular, R₁₁ and R₁₂ may be connected to form a six-membered ring, or R₁₁ and R₁₂ may be connected to form the structure shown in the IB portion, or R₁₁ and R₁₂ may both be phenyl groups.

It can be understood that in a case where the molecular weight of A is low, the molecular weight of the first functional material G1 is relatively low, so that the stability of the first functional material G1 is relatively low; and in a case where the molecular weight of A is high, the molecular weight of the first functional material G1 is relatively high, so that the difficulty of synthesizing the first functional material G1 may increase, and the matching with the preparation process (e.g., the evaporation process) of the first functional layer is relatively poor. In a case where A is selected from any of the structures represented by the general formula (A2), the general formula (A3), the general formula (A4) and the general formula (A5), the molecular weight of A may be within a suitable range, so that the difficulty of synthesizing the first functional material G1 may be reduced while the stability of the first functional material G1 is ensured, and the matching of the first functional material G1 with the preparation process (e.g., the evaporation process) of the first functional layer may be improved.

The exemplary structures of the first functional material G1 are described below in a case where A is selected from any of the structures represented by the general formula (A2), the general formula (A3), the general formula (A4) and the general formula (A5).

In some examples, in a case where A is selected from the structure shown in the general formula (A2), the structural formula of the first functional material G1 may be as shown in (G1-1) to (G1-48), (G1-198), (G1-199), and (G1-202) and (G1-203).

In some examples, in a case where A is selected from the structure shown in the general formula (A3), the structural formula of the first functional material G1 may be as shown in (G1-105) to (G1-136).

In some examples, in a case where A is selected from the structure shown in the general formula (A4), the structural formula of the first functional material G1 may be as shown in (G1-23), (G1-73), and (G1-137) to (G1-168).

In some examples, in a case where A is selected from the structure shown in the general formula (A5), the structural formula of the first functional material G1 may be as shown in (G1-76), and (G1-169) to (G1-197).

It will be noted that the structural formulas listed above are examples of the structure of the first functional material G1, but not limitations on the first functional material G1.

In some embodiments, A is selected from any of the structures represented by the general formula (A2). Furthermore, A and a six-membered ring containing X₁₅, X₁₆, X₁₇ and X₁₈ form a phenanthroline group.

It will be noted that A is selected from any of the structures represented by the general formula (A2), and A and a six-membered ring containing X₁₅, X₁₆, X₁₇ and X₁₈ form a phenanthroline group, which means that in the structure represented by the general formula (I), the IA portion is a phenanthroline group.

In a case where the IA portion is a phenanthroline group, since the phenanthroline group has a certain electron-withdrawing ability, the electron transport property of the first functional material G1 may be improved, so that the first functional material G1 may have a relatively high electron mobility, and the recombination probability of excitons may increase, thereby improving the efficiency and life of the light-emitting device 100. Moreover, setting the IA portion to be a phenanthroline group may make the molecular weight of the first functional material G1 within a suitable range, so that the difficulty of synthesizing the first functional material G1 may be reduced while the stability of the first functional material G1 is ensured, and the matching of the first functional material G1 with the preparation process (e.g., the evaporation process) of the first functional layer may be improved.

The exemplary structures of the first functional material G1 are described below in a case where A is selected from any of the structures represented by the general formula (A2), and A and a six-membered ring containing X₁₅, X₁₆, X₁₇ and X₁₈ form a phenanthroline group (i.e., the IA portion is a phenanthroline group). For example, the structural formula of the first functional material G1 may be as shown in (G1-1) to (G1-48), (G1-198), (G1-202) and (G1-203).

It will be noted that the structural formulas listed above are examples of the structure of the first functional material G1, but not limitations on the first functional material G1.

In some embodiments, A is selected from any of structures represented by the general formula (A4). Furthermore, A and a six-membered ring containing X₁₅, X₁₆, X₁₇ and X₁₈ form a benzodiazine group.

It will be noted that A is selected from any of structures represented by the general formula (A4), and A and a six-membered ring containing X₁₅, X₁₆, X₁₇ and X₁₈ form a benzodiazine group, which means that in the structure represented by the general formula (I), the IA portion is a benzodiazine group.

In a case where the IA portion is a benzodiazine group, since the benzodiazine group has a certain electron-withdrawing ability, the electron transport property of the first functional material G1 may be improved, so that the first functional material G1 may have a relatively high electron mobility, and the recombination probability of excitons may increase, thereby improving the efficiency and life of the light-emitting device 100. Moreover, setting the IA portion to be a benzodiazine group may make the molecular weight of the first functional material G1 within a suitable range, so that the difficulty of synthesizing the first functional material G1 may be reduced while the stability of the first functional material G1 is ensured, and the matching of the first functional material G1 with the preparation process (e.g., the evaporation process) of the first functional layer may be improved.

The exemplary structures of the first functional material G1 are described below in a case where A is selected from any of the structures represented by the general formula (A4), and A and a six-membered ring containing X₁₅, X₁₆, X₁₇ and X₁₈ form a benzodiazine group (i.e., the IA portion is a benzodiazine group). For example, the structural formula of the first functional material G1 may be as shown in (G1-137), (G1-139), and (G1-141) to (G1-168).

It will be noted that the structural formulas listed above are examples of the structure of the first functional material G1, but not limitations on the first functional material G1.

In some embodiments, the second functional material G2 is selected from any of structures represented by the following general formula (II).

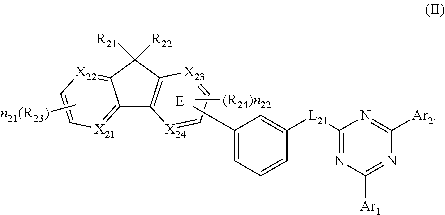

Where X₂₁, X₂₂, X₂₃ and X₂₄ are each independently selected from any of C(R_{b}) and N; any two of X₂₁, X₂₂, X₂₃ and X₂₄ are the same or different; and C(R_{b}) is carbon substituted with R_{b}, and N is nitrogen.

R₂₁, R₂₂, R₂₃, R₂₄ and R_{b} are the same or different. R₂₁, R₂₂, R₂₃, R₂₄ and R_{b} are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₂₁, R₂₂, R₂₃, R₂₄ and R_{b} are connected with an adjacent group to form substituted or unsubstituted 3- to 30-membered ring.

L₂₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups.

Ar₁ and Ar₂ are same or different; Ar₁ and Ar₂ are each independently selected from any of substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Ar₁ and Ar₂ are connected with an adjacent group to form substituted or unsubstituted 3- to 30-membered ring.

n₂₁ is selected from any of 0, 1 and 2.

n₂₂ is selected from any of 0 and 1.

Regarding the structure shown in general formula (II), the following points need to be explained.

L₂₁ may be a direct bond. In a case where L₂₁ is a direct bond, a triazine group and the phenylene group are directly connected by a covalent bond.

In the structure represented by the general formula (II), the phenylene group is connected to the E ring of the fluorene group. The connection position between the phenylene group and the E ring of the fluorene group means that the phenylene group may be connected to any atom on the E ring in the fluorene group that has a substitution position. Here, there is no limitation on the connection position between the phenylene group and the E ring of the fluorene group.

The description of the alkylene group of Cx and the arylene group of Cx here may refer to the description of the alkylene group of Cx above; the description of the Z-membered heteroarylene group here may refer to the description of the Z-membered heteroarylene group above; the description of the (R₂₃)ₙ₂₁ and (R₂₄)ₙ₂₂ here may refer to the description of the (Rₓ)_{ny} above; the description of the atom on the ring here may refer to the description of the atom on the ring above; and details are not repeated here.

In a case where R₂₁, R₂₂, R₂₃, R₂₄ or R_{b} is selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups; and/or L₂₁ is selected from any of substituted C3 to C30 alkylene groups, substituted C6 to C30 arylene groups, and substituted 5- to 30-membered heteroarylene groups; and/or Ar₁ or Ar₂ is selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, the type and number of substituents are not limited here.

It can be understood that, the structure represented by the general formula (II) contains a triazine group, and the triazine group has a low LUMO energy level and a strong electron-withdrawing ability, so that the LUMO electron cloud of the second functional material G2 is mainly distributed at the position of the triazine group. In addition, the fluorene group has a stronger electron-donating ability than other groups in the structure shown in general formula (II), so that the HOMO electron cloud of the second functional material G2 and the T1 energy level electron cloud are distributed at the position of the fluorene group, and thus the fluorene group becomes the main factor affecting the highest occupied molecular orbital (HOMO) energy level and the triplet energy level (T1 energy level). Moreover, the structure represented by the general formula (II) includes a phenylene group with two connection sites, and the two connection sites are distributed in a meta position. In this way, the phenylene group may be used to separate the fluorene group and the triazine group to reduce the delocalization of the HOMO electron cloud and the T1 energy level electron cloud distributed on the electron-donating group fluorene group to the electron-withdrawing group triazine group, so that the HOMO energy level of the second functional material G2 is deep and the T1 energy level is high. Thus, holes and excitons in the light-emitting layer 131 may be blocked from leaking to the cathode 12, thereby increasing the recombination probability of the excitons and improving the efficiency and life of the light-emitting device 100.

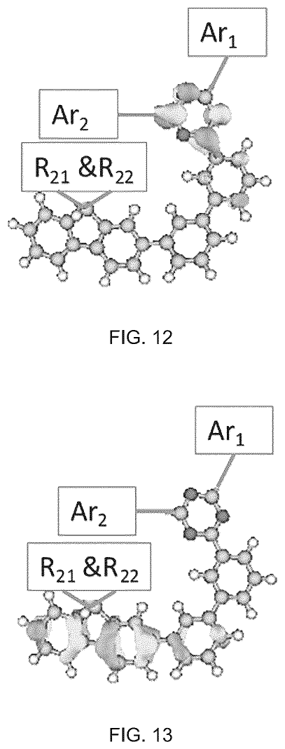

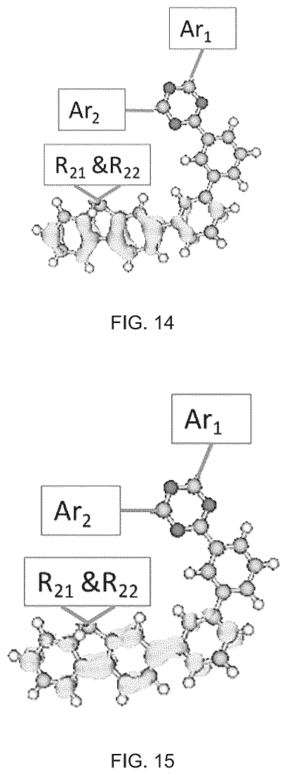

In some examples, the LUMO electron cloud distribution diagram of the second functional material G2 is shown in FIG. 12; the HOMO electron cloud distribution diagram of the second functional material G2 is shown in FIG. 13; the electron cloud distribution diagram of the T1 holes of the second functional material G2 is shown in FIG. 14; and the electron cloud distribution diagram of the T1 electrons of the second functional material G2 is shown in FIG. 15. It can be seen from FIGS. 12 to 15 that the LUMO electron cloud of the second functional material G2 is distributed at the position of the triazine group; the HOMO electron cloud of the second functional material G2 is mainly distributed at the position of the fluorene group; the electron cloud of the T1 holes of the second functional material G2 is mainly distributed at the position of the fluorene group; and the electron cloud of the T1 electrons of the second functional material G2 is mainly distributed at the position of the fluorene group. Moreover, due to the separation effect of the phenylene group, the delocalization of the HOMO electron cloud, the electron cloud of the T1 holes and the electron cloud of the T1 electrons of the second functional material G2 to the position of the triazine group is reduced compared to the first functional material G1.

The exemplary structures of the second functional material G2 having a structure as represented by the general formula (II) are described below.

In some embodiments, R₂₁ is a methyl group; and R₂₂ is a methyl group.

It can be understood that in a case where R₂₁ and R₂₂ in the structure represented by the general formula (II) are both methyl groups, the stability of the second functional material G2 may be relatively high on a basis of a relatively deep HOMO energy level of the second functional material G2 and a relatively high T1 energy level, thereby improving the life of the light-emitting device 100.

The exemplary structures of the second functional material G2 having a structure as represented by the general formula (II) are described below in a case where R₂₁ and R₂₂ are both methyl groups.

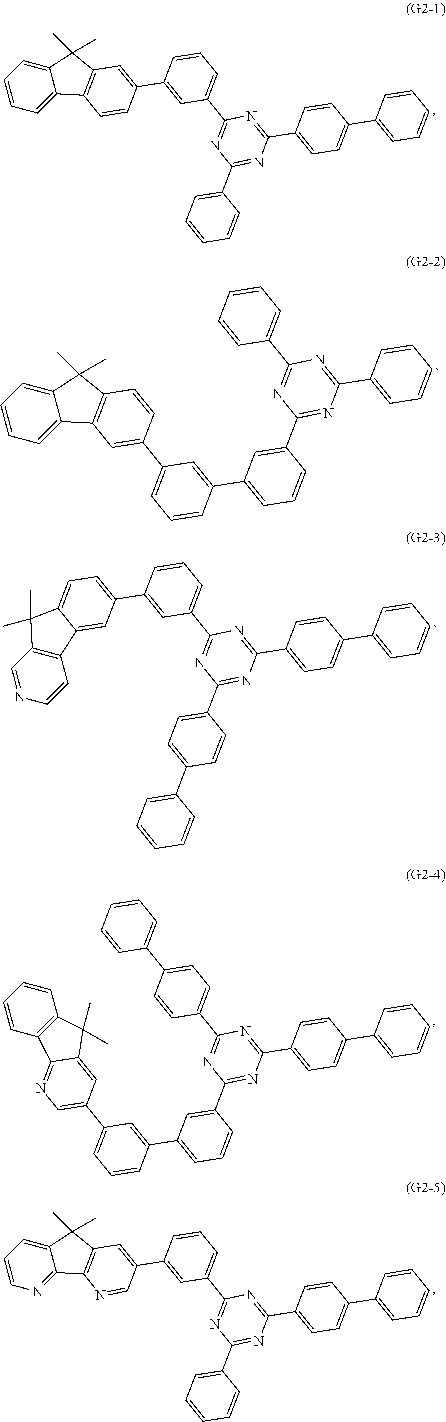

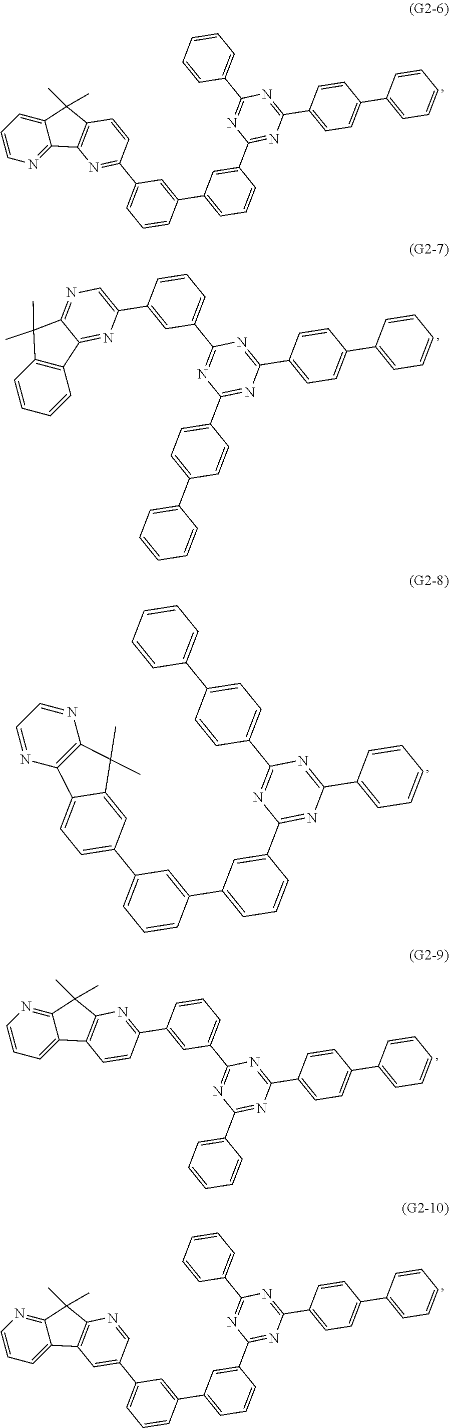

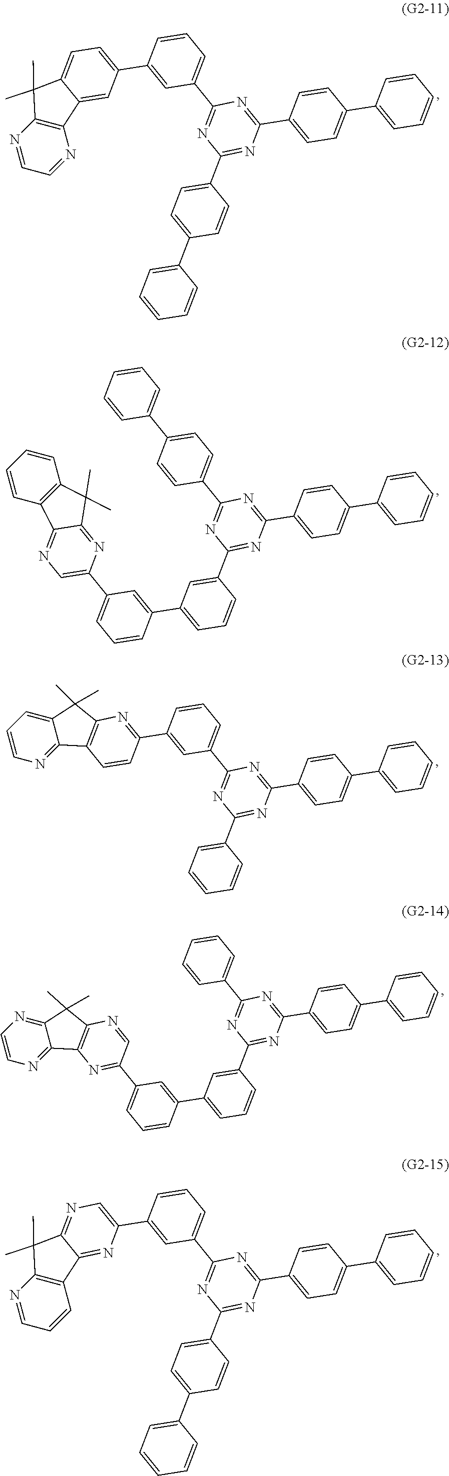

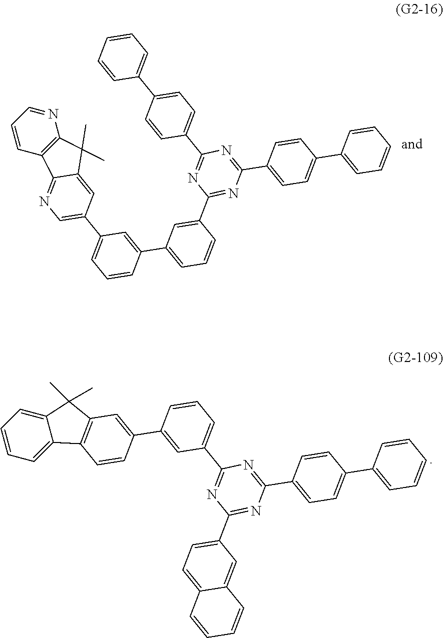

In some embodiments, R₂₁ is a phenyl group; and R₂₂ is a phenyl group.

It can be understood that in a case where R₂₁ and R₂₂ in the structure represented by the general formula (II) are both phenyl groups, R₂₁, R₂₂ and the fluorene group share the sp3 carbon atom. There is a certain angle between a plane where the benzene ring of R₂₁ is located and a plane where the fluorene group is located, and there is a certain angle between a plane where the benzene ring of R₂₂ is located and the plane where the fluorene group is located. The stereoscopic property of the configuration of the second functional material G2 may be improved. Thus, the second functional material G2 may be prevented from crystallizing, and the second functional material G2 may have a high glass transition temperature. In this way, the film-forming property of the second functional material G2 may be improved; and the thermal stability of the second functional material G2 may be improved, so that the life of the light-emitting device 100 may increase.

The exemplary structures of the second functional material G2 having a structure as represented by the general formula (II) are described below in a case where R₂₁ and R₂₂ are both phenyl groups.

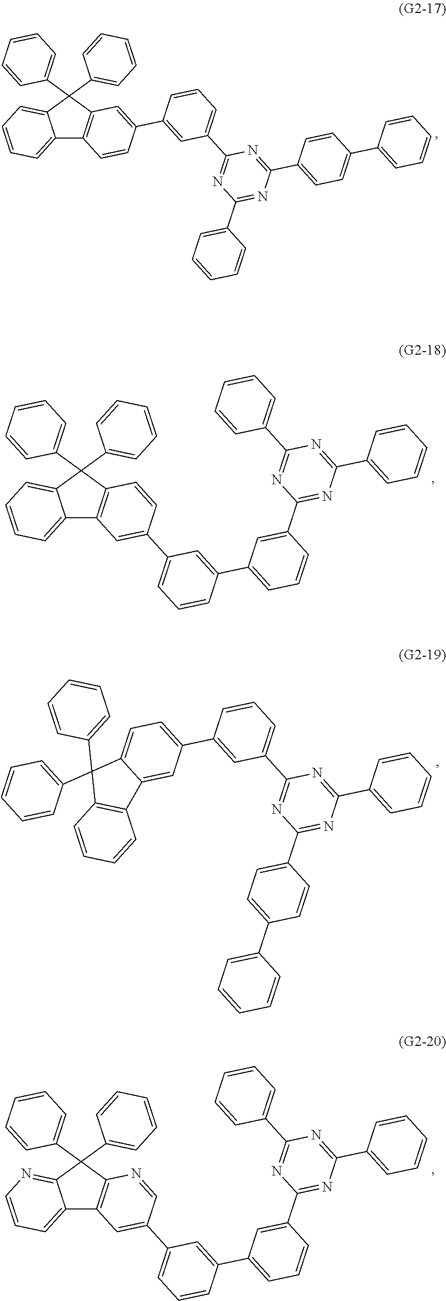

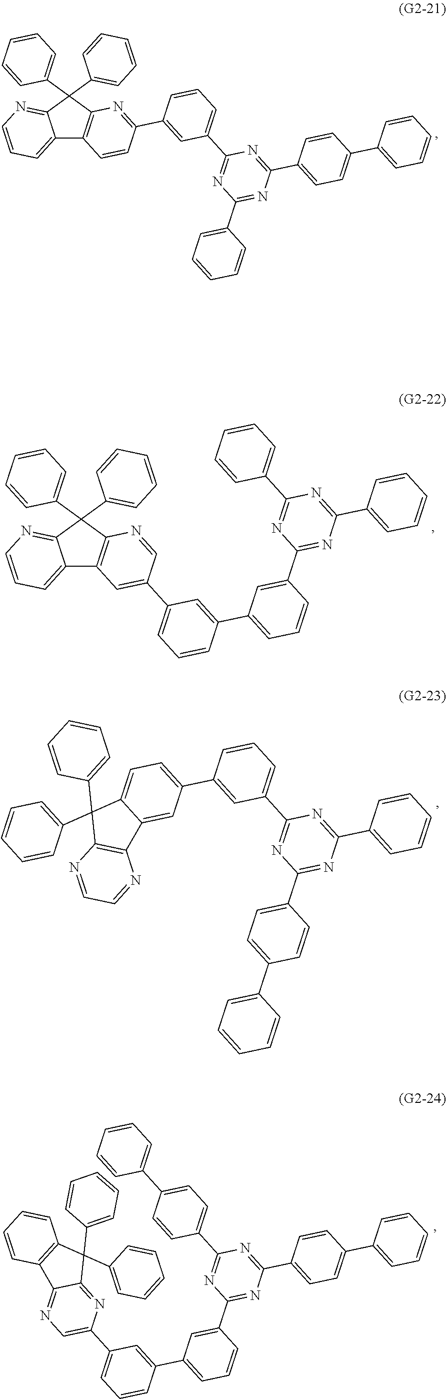

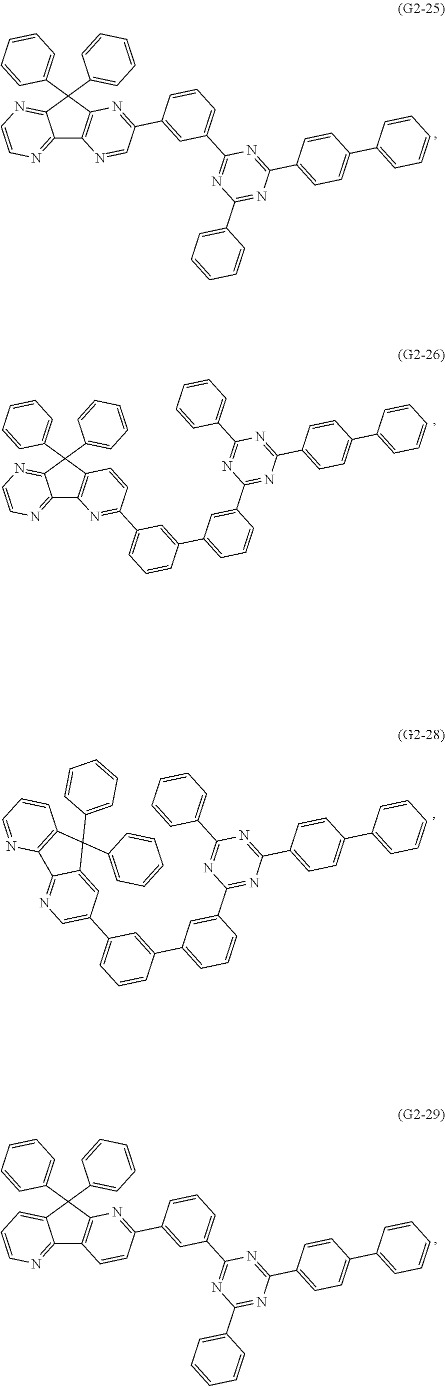

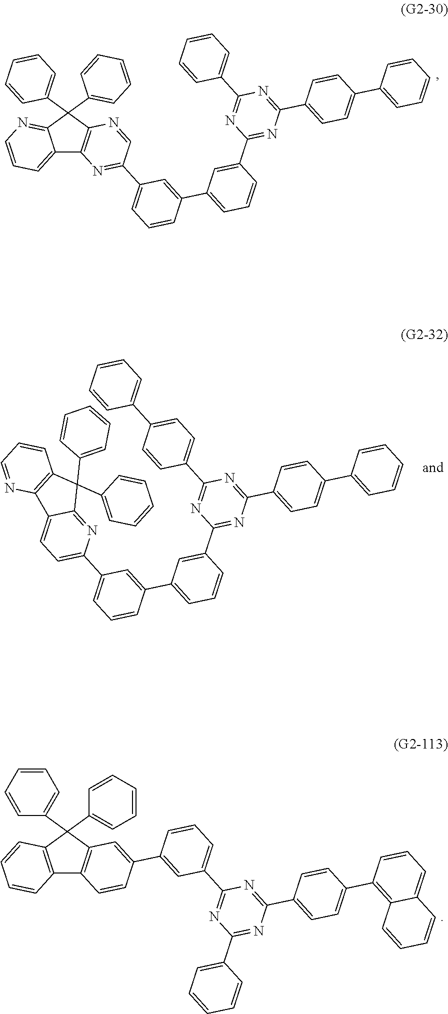

In some examples, in a case where one of R₂₁ and R₂₂ is a phenyl group and the other thereof is a naphthyl group, the structural formula of the second functional material G2 may be as shown below.

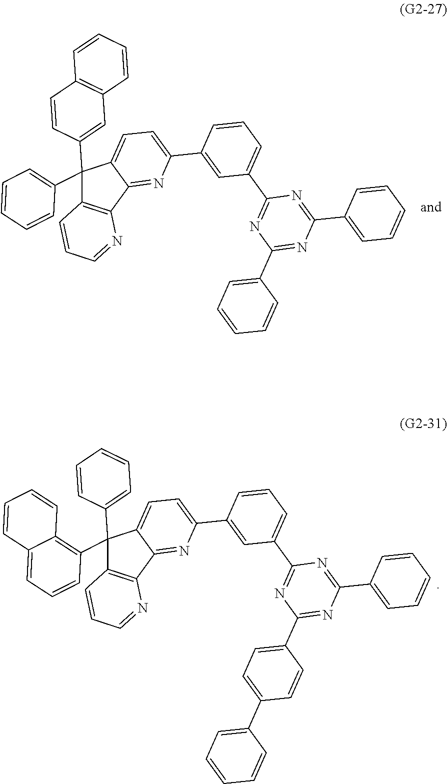 [SMILES: c1ccc(-c2nc(-c3ccccc3)nc(-c3cccc(-c4ccc5c(n4)-c4ncccc4C5(c4ccccc4)c4ccc5ccccc5c4)c3)n2)cc1 ; c1ccc(-c2ccc(-c3nc(-c4ccccc4)nc(-c4cccc(-c5ccc6c(n5)-c5ncccc5C6(c5ccccc5)c5cccc6ccccc56)c4)n3)cc2)cc1]

It can be understood that in a case where one of R₂₁ and R₂₂ is a phenyl group and the other thereof is a naphthyl group, similar to the case where R₂₁ and R₂₂ are both phenyl groups, R₂₁, R₂₂ and the fluorene group share the sp3 carbon atom. The stereoscopic property of the configuration of the second functional material G2 may be improved. Thus, the second functional material G2 may be prevented from crystallizing, and the second functional material G2 may have a high glass transition temperature. In this way, the film-forming property of the second functional material G2 may be improved; and the thermal stability of the second functional material G2 may be improved, so that the life of the light-emitting device 100 may increase.

In some examples, in a case where R₂₁ and R₂₂ are connected to form a six-membered ring, the structural formula of the second functional material G2 may be as shown below.

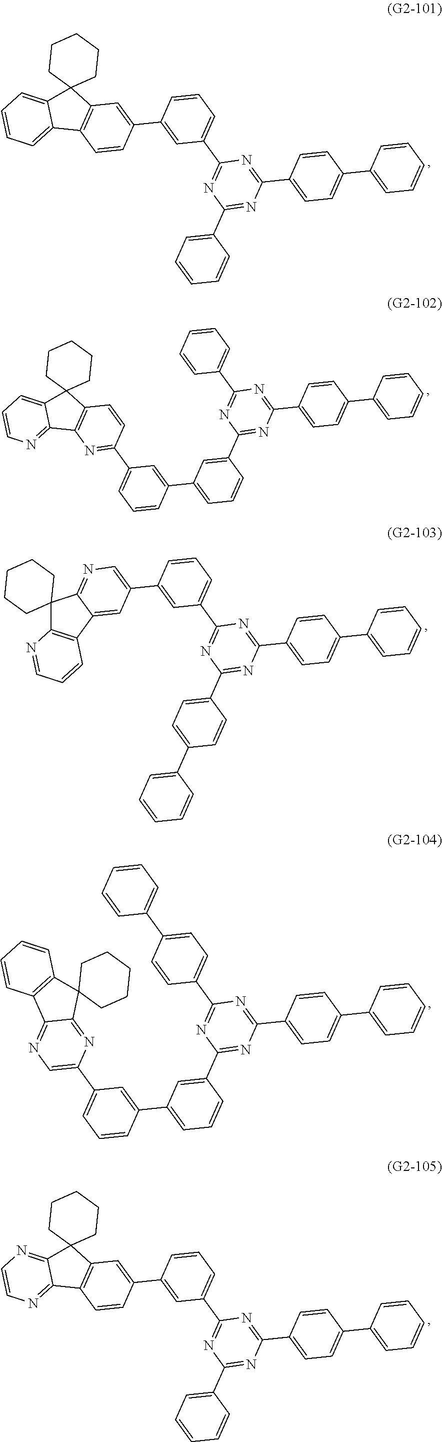 [SMILES: c1ccc(-c2ccc(-c3nc(-c4ccccc4)nc(-c4cccc(-c5ccc6c(c5)C5(CCCCC5)c5ccccc5-6)c4)n3)cc2)cc1 ; c1ccc(-c2ccc(-c3nc(-c4ccccc4)nc(-c4cccc(-c5cccc(-c6ccc7c(n6)-c6ncccc6C76CCCCC6)c5)c4)n3)cc2)cc1 ; c1ccc(-c2ccc(-c3nc(-c4ccc(-c5ccccc5)cc4)nc(-c4cccc(-c5cnc6c(c5)-c5cccnc5C65CCCCC5)c4)n3)cc2)cc1 ; c1ccc(-c2ccc(-c3nc(-c4ccc(-c5ccccc5)cc4)nc(-c4cccc(-c5cccc(-c6cnc7c(n6)C6(CCCCC6)c6ccccc6-7)c5)c4)n3)cc2)cc1 ; c1ccc(-c2ccc(-c3nc(-c4ccccc4)nc(-c4cccc(-c5ccc6c(c5)C5(CCCCC5)c5nccnc5-6)c4)n3)cc2)cc1]

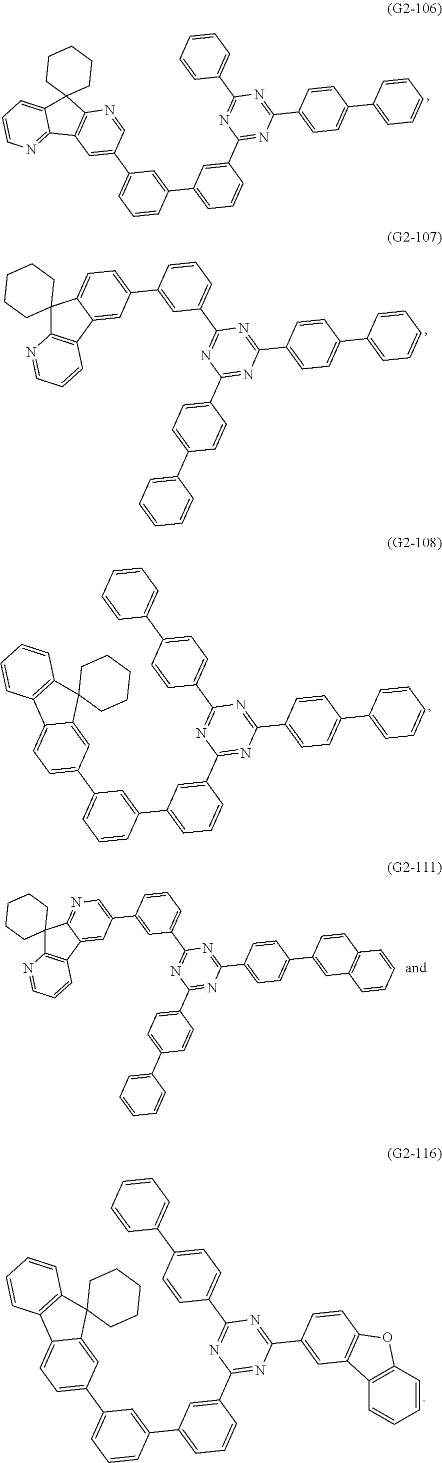

It can be understood that in a case where R₂₁ and R₂₂ are connected to form a six-membered ring, the six-membered ring and the fluorene group share the sp3 carbon atom to form a spirocyclic group. Since the spirocyclic group has an orthogonal stereo configuration, the stereoscopic property of the configuration of the second functional material G2 may be improved. Thus, the second functional material G2 may be prevented from crystallizing, and the second functional material G2 may have a high glass transition temperature. In this way, the film-forming property of the second functional material G2 may be improved; and the thermal stability of the second functional material G2 may be improved, so that the life of the light-emitting device 100 may increase.

It will be noted that the structural formulas listed above are examples of the structure of the second functional material G2, but not limitations on the second functional material G2. Moreover, (G2-x) in the above structural formulas is a synonym for each structural formula and is not a part of the structure of the structural formula, where x is a positive integer.

In some embodiments, the second functional material G2 is selected from any of structures represented by the following general formula (II-A).

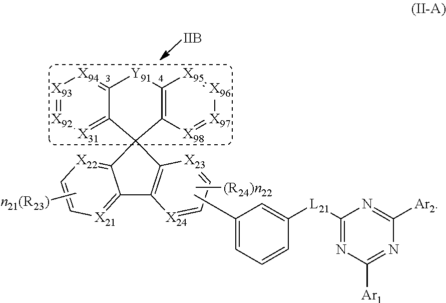

Where X₉₁, X₉₂, X₉₃, X₉₄, X₉₅, X₉₆, X₉₇ and X₉₈ are each independently selected from any of C(Rₙ) and N; any two of X₉₁, X₉₂, X₉₃, X₉₄, X₉₅, X₉₆, X₉₇ and X₉₈ are the same or different; and C(Rₙ) is carbon substituted by Rₙ, and N is nitrogen.

Y₉₁ is selected from any of a direct bond, C(RₒRₚ), O, S and Se. C(RₒRₚ) is carbon substituted by Rₒ and Rₚ, O is oxygen, S is sulfur, and Se is selenium.

Rₙ, Rₒ and Rₚ are the same or different. Rₙ, Rₒ and Rₚ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Rₙ, Rₒ and Rₚ are connected with an adjacent group to form substituted or unsubstituted 3- to 30-membered ring.

It will be noted that Y₉₁ may be a direct bond. In a case where Y₉₁ is a direct bond, a carbon of number 3 and a carbon of number 4 of the IIB portion are directly connected by a covalent bond.

It will be noted that in a case where Rₙ, Rₒ and Rₚ are each selected from any of substituted C1 to C30 alkyl groups, substituted C2 to C30 alkenyl groups, substituted C2 to C30 alkynyl groups, substituted C3 to C30 cycloalkyl groups, substituted C1 to C30 alkoxy groups, substituted C6 to C30 aryl groups, substituted 5- to 30-membered heteroaryl groups, and substituted 3- to 30-membered heterocyclyl groups, the type and number of substituents are not limited here.

The description of the alkyl group of Cx, the alkenyl group of Cx and the like here may refer to the description of the alkylene group of Cx above; the description of the Z-membered heteroaryl group, the Z-membered heterocyclyl group, and the Z-membered ring here may refer to the description of the Z-membered heteroarylene group above; and details are not repeated here. The meanings of symbols in the general formula (II-A) other than those mentioned above have the same meanings as in the general formula (II).

It can be understood that in a case where R₂₁ and R₂₂ in the structure represented by the general formula (II) are connected to form the structure shown in the IB portion, the structure represented by the general formula (II) may be transformed into the structure represented by the general formula (II-A).

In a case where the second functional material G2 is selected from any of the structures represented by the general formula (II-A), the IB portion and the fluorene group share the sp3 carbon atom to form a spirocyclic group. The spirocyclic group has an orthogonal stereo configuration. Therefore, in a first aspect, the stereoscopic property of the configuration of the second functional material G2 may be improved. Thus, the second functional material G2 may be prevented from crystallizing, and the second functional material G2 may have a high glass transition temperature. In this way, the film-forming property of the second functional material G2 may be improved; and the thermal stability of the second functional material G2 may be improved, so that the life of the light-emitting device 100 may increase. In a second aspect, in the structure represented by the general formula (II-A), in a case where the IIB portion forms a large conjugated fragment or a fragment with a strong electron-donating ability, the HOMO electron cloud and the T1 energy level electron cloud may be distributed in the IIB portion. In this way, the HOMO electron cloud and the T1 energy level electron cloud of the second functional material G2 are mainly distributed at the position of the fluorene group or the position of the IIB portion. Moreover, since in the structure represented by the general formula (II-A), the fluorene group and the IIB portion share the sp3 carbon atom to form a spirocyclic group, the delocalization of the HOMO electron cloud and the T1 energy level electron cloud from a side to the other side of the spirocyclic group may be reduced, so that the HOMO energy level of the second functional material G2 is relatively deep and the T1 energy level is relatively high. In this way, holes and excitons in the light-emitting layer 131 may be blocked from leaking to the cathode 12, thereby increasing the recombination probability of the excitons and improving the efficiency and life of the light-emitting device 100.

The exemplary structures of the second functional material G2 having a structure as represented by the general formula (II-A) are described below.

In some examples, in a case where Y₉₁ is a direct bond, the structural formula of the second functional material G2 may be as shown below.

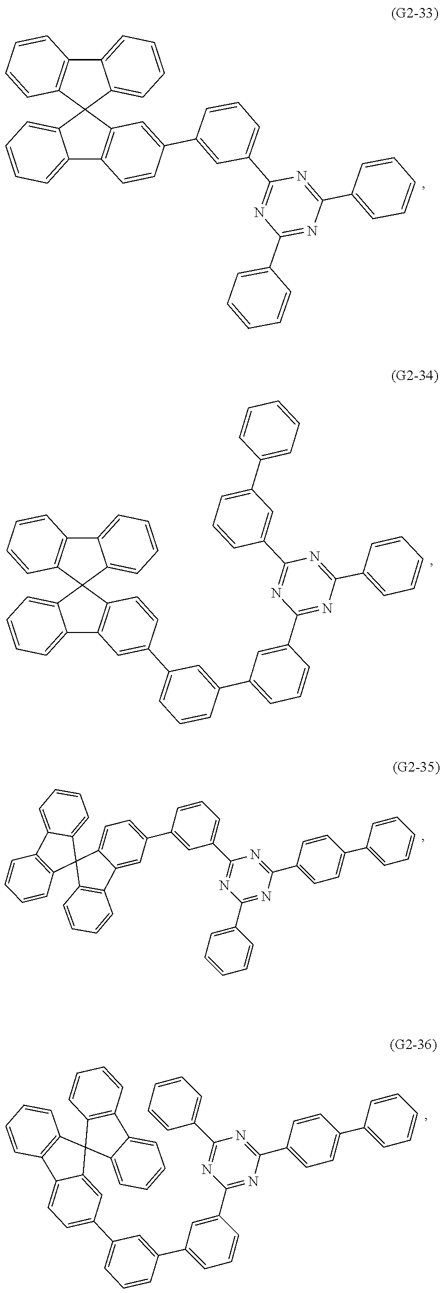 [SMILES: c1ccc(-c2nc(-c3ccccc3)nc(-c3cccc(-c4ccc5c(c4)C4(c6ccccc6-c6ccccc64)c4ccccc4-5)c3)n2)cc1 ; c1ccc(-c2cccc(-c3nc(-c4ccccc4)nc(-c4cccc(-c5cccc(-c6ccc7c(c6)-c6ccccc6C76c7ccccc7-c7ccccc76)c5)c4)n3)c2)cc1 ; c1ccc(-c2ccc(-c3nc(-c4ccccc4)nc(-c4cccc(-c5ccc6c(c5)-c5ccccc5C65c6ccccc6-c6ccccc65)c4)n3)cc2)cc1 ; c1ccc(-c2ccc(-c3nc(-c4ccccc4)nc(-c4cccc(-c5cccc(-c6ccc7c(c6)C6(c8ccccc8-c8ccccc86)c6ccccc6-7)c5)c4)n3)cc2)cc1]

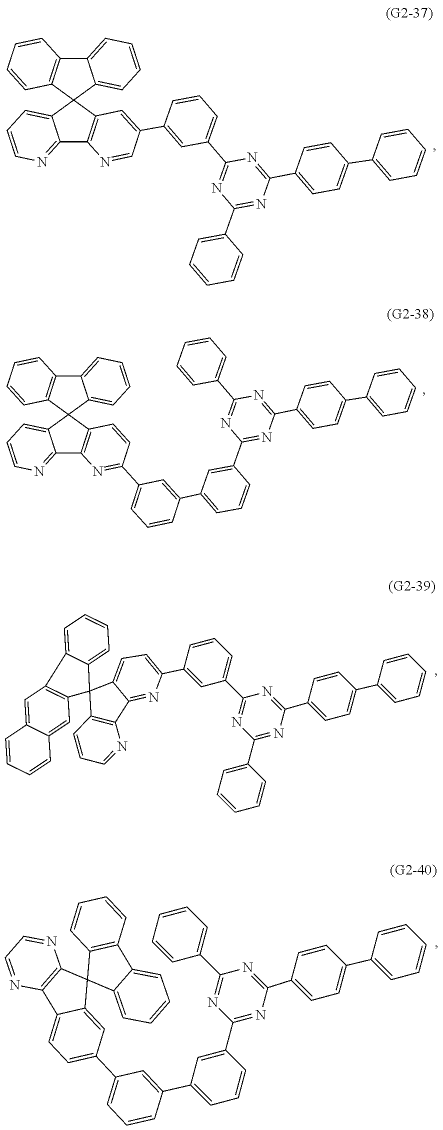 [SMILES: c1ccc(-c2ccc(-c3nc(-c4ccccc4)nc(-c4cccc(-c5cnc6c(c5)C5(c7ccccc7-c7ccccc75)c5cccnc5-6)c4)n3)cc2)cc1 ; c1ccc(-c2ccc(-c3nc(-c4ccccc4)nc(-c4cccc(-c5cccc(-c6ccc7c(n6)-c6ncccc6C76c7ccccc7-c7ccccc76)c5)c4)n3)cc2)cc1 ; c1ccc(-c2ccc(-c3nc(-c4ccccc4)nc(-c4cccc(-c5ccc6c(n5)-c5ncccc5C65c6ccccc6-c6cc7ccccc7cc65)c4)n3)cc2)cc1 ; c1ccc(-c2ccc(-c3nc(-c4ccccc4)nc(-c4cccc(-c5cccc(-c6ccc7c(c6)C6(c8ccccc8-c8ccccc86)c6nccnc6-7)c5)c4)n3)cc2)cc1]

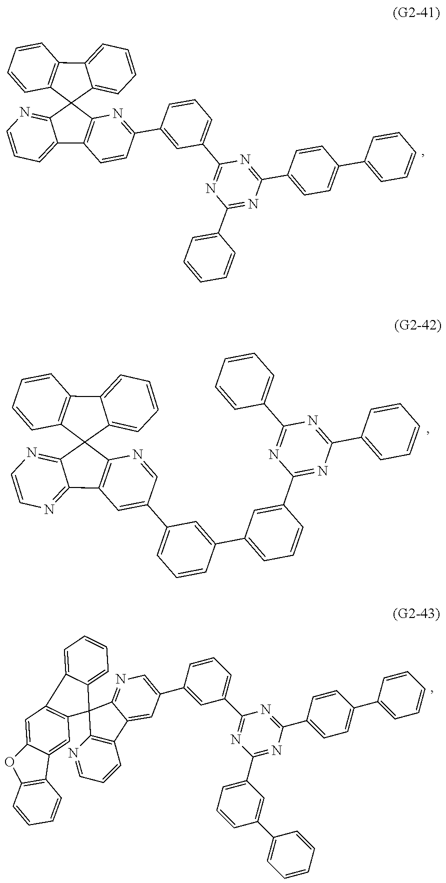 [SMILES: c1ccc(-c2ccc(-c3nc(-c4ccccc4)nc(-c4cccc(-c5ccc6c(n5)C5(c7ccccc7-c7ccccc75)c5ncccc5-6)c4)n3)cc2)cc1 ; c1ccc(-c2nc(-c3ccccc3)nc(-c3cccc(-c4cccc(-c5cnc6c(c5)-c5nccnc5C65c6ccccc6-c6ccccc65)c4)c3)n2)cc1 ; c1ccc(-c2ccc(-c3nc(-c4cccc(-c5ccccc5)c4)nc(-c4cccc(-c5cnc6c(c5)-c5cccnc5C65c6ccccc6-c6cc7oc8ccccc8c7cc65)c4)n3)cc2)cc1]

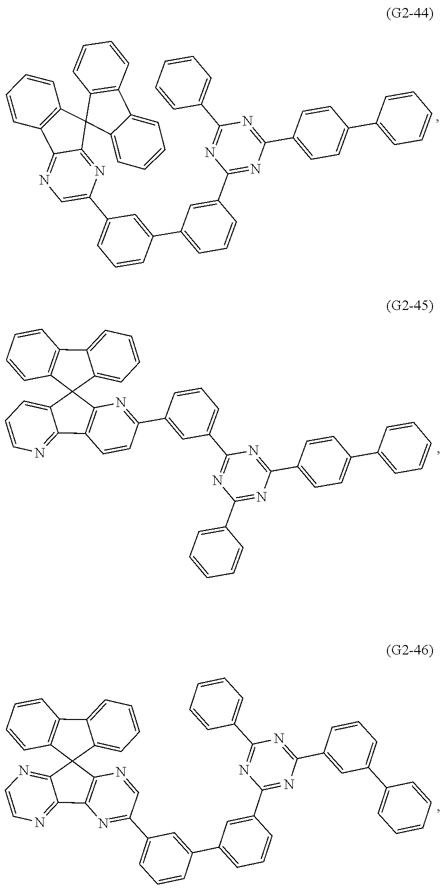 [SMILES: c1ccc(-c2ccc(-c3nc(-c4ccccc4)nc(-c4cccc(-c5cccc(-c6cnc7c(n6)C6(c8ccccc8-c8ccccc86)c6ccccc6-7)c5)c4)n3)cc2)cc1 ; c1ccc(-c2ccc(-c3nc(-c4ccccc4)nc(-c4cccc(-c5ccc6c(n5)C5(c7ccccc7-c7ccccc75)c5cccnc5-6)c4)n3)cc2)cc1 ; c1ccc(-c2cccc(-c3nc(-c4ccccc4)nc(-c4cccc(-c5cccc(-c6cnc7c(n6)-c6nccnc6C76c7ccccc7-c7ccccc76)c5)c4)n3)c2)cc1]

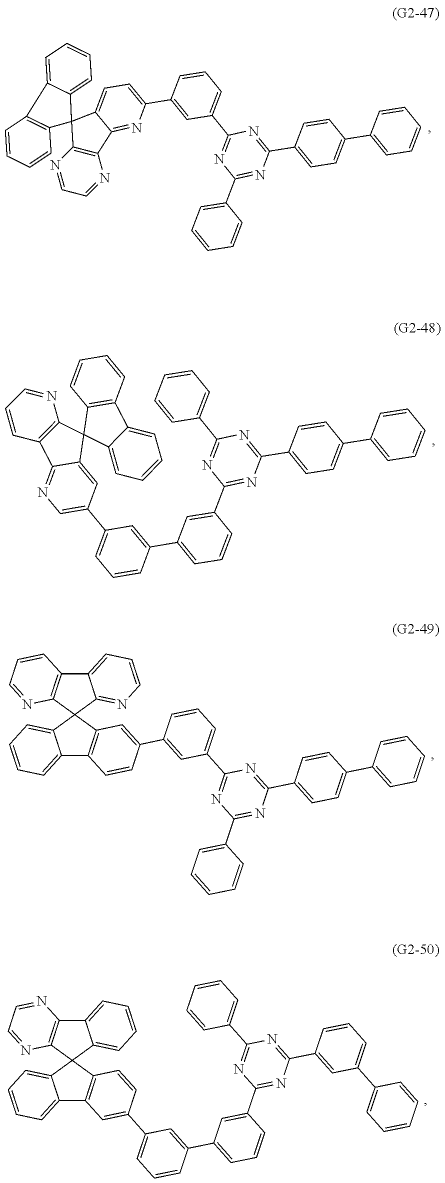 [SMILES: c1ccc(-c2ccc(-c3nc(-c4ccccc4)nc(-c4cccc(-c5ccc6c(n5)-c5nccnc5C65c6ccccc6-c6ccccc65)c4)n3)cc2)cc1 ; c1ccc(-c2ccc(-c3nc(-c4ccccc4)nc(-c4cccc(-c5cccc(-c6cnc7c(c6)C6(c8ccccc8-c8ccccc86)c6ncccc6-7)c5)c4)n3)cc2)cc1 ; c1ccc(-c2ccc(-c3nc(-c4ccccc4)nc(-c4cccc(-c5ccc6c(c5)C5(c7ccccc7-6)c6ncccc6-c6cccnc65)c4)n3)cc2)cc1 ; c1ccc(-c2cccc(-c3nc(-c4ccccc4)nc(-c4cccc(-c5cccc(-c6ccc7c(c6)-c6ccccc6C76c7ccccc7-c7nccnc76)c5)c4)n3)c2)cc1]

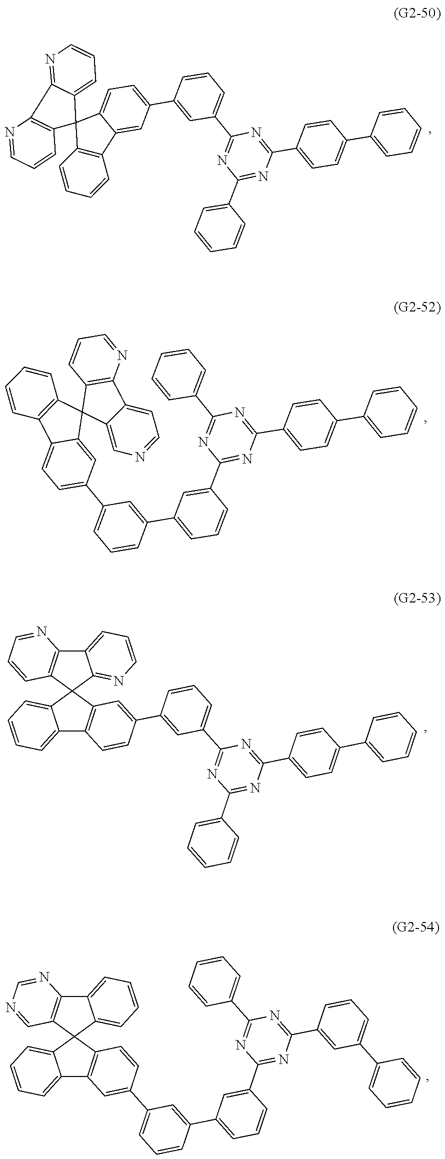 [SMILES: c1ccc(-c2ccc(-c3nc(-c4ccccc4)nc(-c4cccc(-c5ccc6c(c5)-c5ccccc5C65c6cccnc6-c6ncccc65)c4)n3)cc2)cc1 ; c1ccc(-c2ccc(-c3nc(-c4ccccc4)nc(-c4cccc(-c5cccc(-c6ccc7c(c6)C6(c8ccccc8-7)c7cnccc7-c7ncccc76)c5)c4)n3)cc2)cc1 ; c1ccc(-c2ccc(-c3nc(-c4ccccc4)nc(-c4cccc(-c5ccc6c(c5)C5(c7ccccc7-6)c6cccnc6-c6cccnc65)c4)n3)cc2)cc1 ; c1ccc(-c2cccc(-c3nc(-c4ccccc4)nc(-c4cccc(-c5cccc(-c6ccc7c(c6)-c6ccccc6C76c7ccccc7-c7ncncc76)c5)c4)n3)c2)cc1]

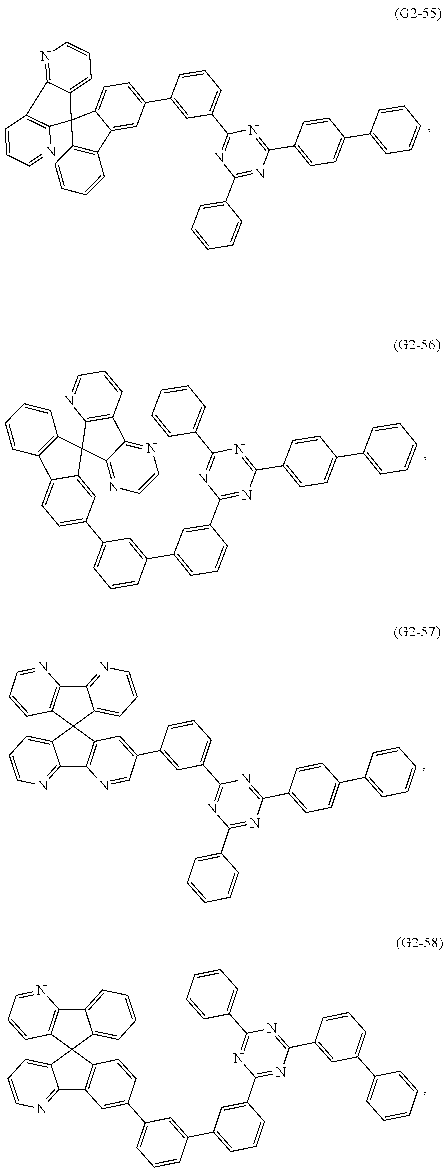 [SMILES: c1ccc(-c2ccc(-c3nc(-c4ccccc4)nc(-c4cccc(-c5ccc6c(c5)-c5ccccc5C65c6cccnc6-c6cccnc65)c4)n3)cc2)cc1 ; c1ccc(-c2ccc(-c3nc(-c4ccccc4)nc(-c4cccc(-c5cccc(-c6ccc7c(c6)C6(c8ccccc8-7)c7ncccc7-c7nccnc76)c5)c4)n3)cc2)cc1 ; c1ccc(-c2ccc(-c3nc(-c4ccccc4)nc(-c4cccc(-c5cnc6c(c5)C5(c7cccnc7-c7ncccc75)c5cccnc5-6)c4)n3)cc2)cc1 ; c1ccc(-c2cccc(-c3nc(-c4ccccc4)nc(-c4cccc(-c5cccc(-c6ccc7c(c6)-c6ncccc6C76c7ccccc7-c7ncccc76)c5)c4)n3)c2)cc1]

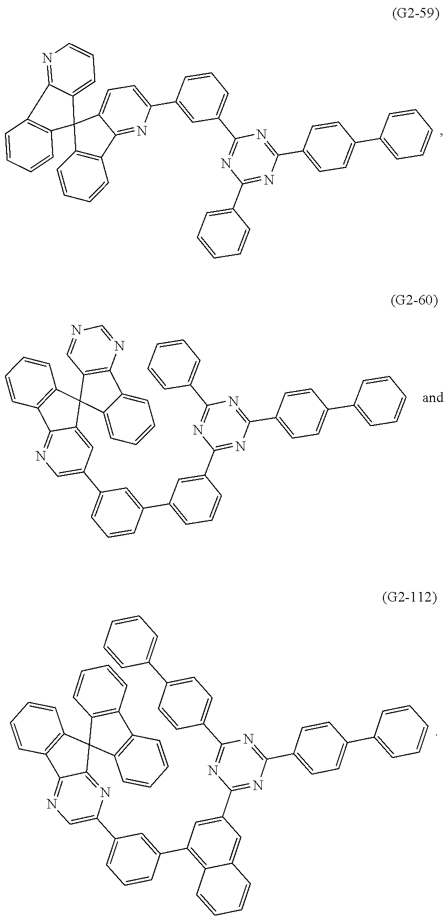 [SMILES: c1ccc(-c2ccc(-c3nc(-c4ccccc4)nc(-c4cccc(-c5ccc6c(n5)-c5ccccc5C65c6ccccc6-c6ncccc65)c4)n3)cc2)cc1 ; c1ccc(-c2ccc(-c3nc(-c4ccccc4)nc(-c4cccc(-c5cccc(-c6cnc7c(c6)C6(c8ccccc8-c8ncncc86)c6ccccc6-7)c5)c4)n3)cc2)cc1 ; c1ccc(-c2ccc(-c3nc(-c4ccc(-c5ccccc5)cc4)nc(-c4cc(-c5cccc(-c6cnc7c(n6)C6(c8ccccc8-c8ccccc86)c6ccccc6-7)c5)c5ccccc5c4)n3)cc2)cc1]

In some examples, in a case where Y₉₁ is substituted carbon, the structural formula of the second functional material G2 may be as shown below.

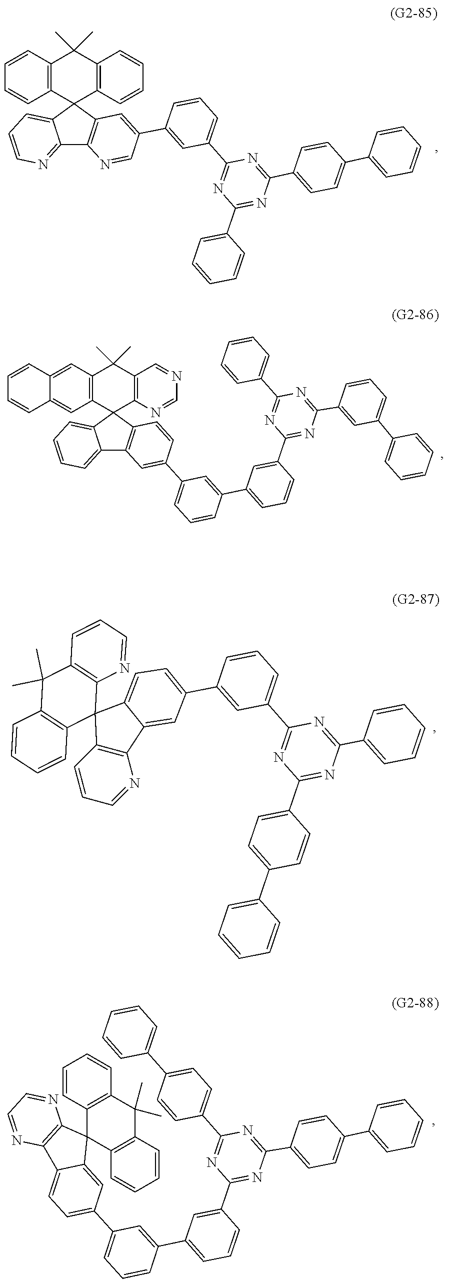 [SMILES: CC1(C)c2ccccc2C2(c3ccccc31)c1cccnc1-c1ncc(-c3cccc(-c4nc(-c5ccccc5)nc(-c5ccc(-c6ccccc6)cc5)n4)c3)cc12 ; CC1(C)c2cc3ccccc3cc2C2(c3ccccc3-c3cc(-c4cccc(-c5cccc(-c6nc(-c7ccccc7)nc(-c7cccc(-c8ccccc8)c7)n6)c5)c4)ccc32)c2ncncc21 ; CC1(C)c2ccccc2C2(c3ccc(-c4cccc(-c5nc(-c6ccccc6)nc(-c6ccc(-c7ccccc7)cc6)n5)c4)cc3-c3ncccc32)c2ncccc21 ; CC1(C)c2ccccc2C2(c3cc(-c4cccc(-c5cccc(-c6nc(-c7ccc(-c8ccccc8)cc7)nc(-c7ccc(-c8ccccc8)cc7)n6)c5)c4)ccc3-c3nccnc32)c2ccccc21]

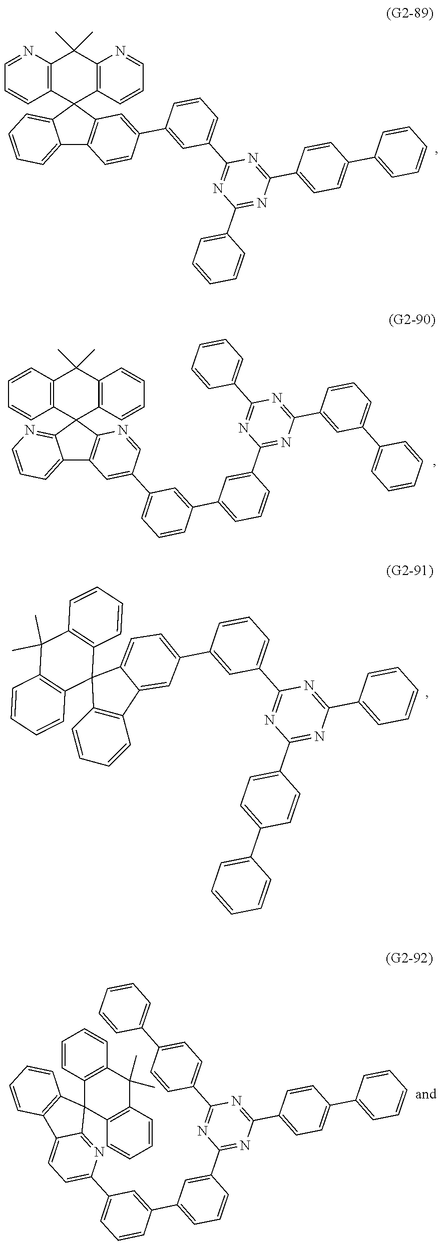 [SMILES: CC1(C)c2ncccc2C2(c3ccccc3-c3ccc(-c4cccc(-c5nc(-c6ccccc6)nc(-c6ccc(-c7ccccc7)cc6)n5)c4)cc32)c2cccnc21 ; CC1(C)c2ccccc2C2(c3ccccc31)c1ncccc1-c1cc(-c3cccc(-c4cccc(-c5nc(-c6ccccc6)nc(-c6cccc(-c7ccccc7)c6)n5)c4)c3)cnc12 ; CC1(C)c2ccccc2C2(c3ccccc3-c3cc(-c4cccc(-c5nc(-c6ccccc6)nc(-c6ccc(-c7ccccc7)cc6)n5)c4)ccc32)c2ccccc21 ; CC1(C)c2ccccc2C2(c3ccccc3-c3ccc(-c4cccc(-c5cccc(-c6nc(-c7ccc(-c8ccccc8)cc7)nc(-c7ccc(-c8ccccc8)cc7)n6)c5)c4)nc32)c2ccccc21]

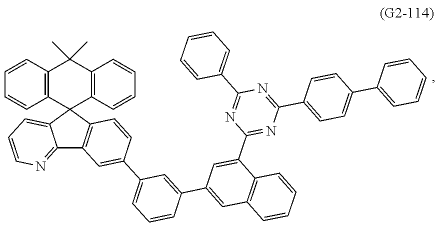 [SMILES: CC1(C)c2ccccc2C2(c3ccc(-c4cccc(-c5cc(-c6nc(-c7ccccc7)nc(-c7ccc(-c8ccccc8)cc7)n6)c6ccccc6c5)c4)cc3-c3ncccc32)c2ccccc21]

In some examples, in a case where Y₉₁ is oxygen, the structural formula of the second functional material G2 may be as shown below.

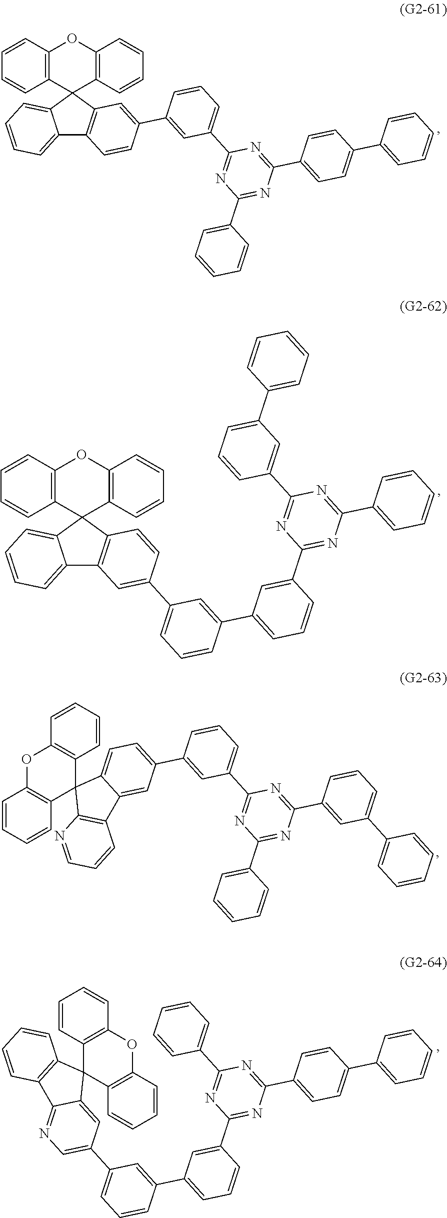 [SMILES: c1ccc(-c2ccc(-c3nc(-c4ccccc4)nc(-c4cccc(-c5ccc6c(c5)C5(c7ccccc7Oc7ccccc75)c5ccccc5-6)c4)n3)cc2)cc1 ; c1ccc(-c2cccc(-c3nc(-c4ccccc4)nc(-c4cccc(-c5cccc(-c6ccc7c(c6)-c6ccccc6C76c7ccccc7Oc7ccccc76)c5)c4)n3)c2)cc1 ; c1ccc(-c2cccc(-c3nc(-c4ccccc4)nc(-c4cccc(-c5ccc6c(c5)-c5cccnc5C65c6ccccc6Oc6ccccc65)c4)n3)c2)cc1 ; c1ccc(-c2ccc(-c3nc(-c4ccccc4)nc(-c4cccc(-c5cccc(-c6cnc7c(c6)C6(c8ccccc8Oc8ccccc86)c6ccccc6-7)c5)c4)n3)cc2)cc1]

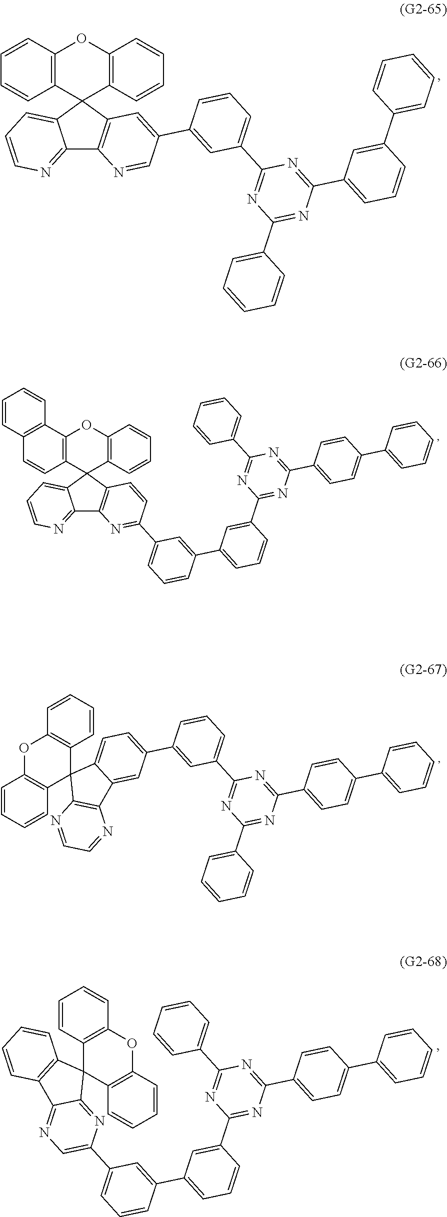 [SMILES: c1ccc(-c2cccc(-c3nc(-c4ccccc4)nc(-c4cccc(-c5cnc6c(c5)C5(c7ccccc7Oc7ccccc75)c5cccnc5-6)c4)n3)c2)cc1 ; c1ccc(-c2ccc(-c3nc(-c4ccccc4)nc(-c4cccc(-c5cccc(-c6ccc7c(n6)-c6ncccc6C76c7ccccc7Oc7c6ccc6ccccc76)c5)c4)n3)cc2)cc1 ; c1ccc(-c2ccc(-c3nc(-c4ccccc4)nc(-c4cccc(-c5ccc6c(c5)-c5nccnc5C65c6ccccc6Oc6ccccc65)c4)n3)cc2)cc1 ; c1ccc(-c2ccc(-c3nc(-c4ccccc4)nc(-c4cccc(-c5cccc(-c6cnc7c(n6)C6(c8ccccc8Oc8ccccc86)c6ccccc6-7)c5)c4)n3)cc2)cc1]

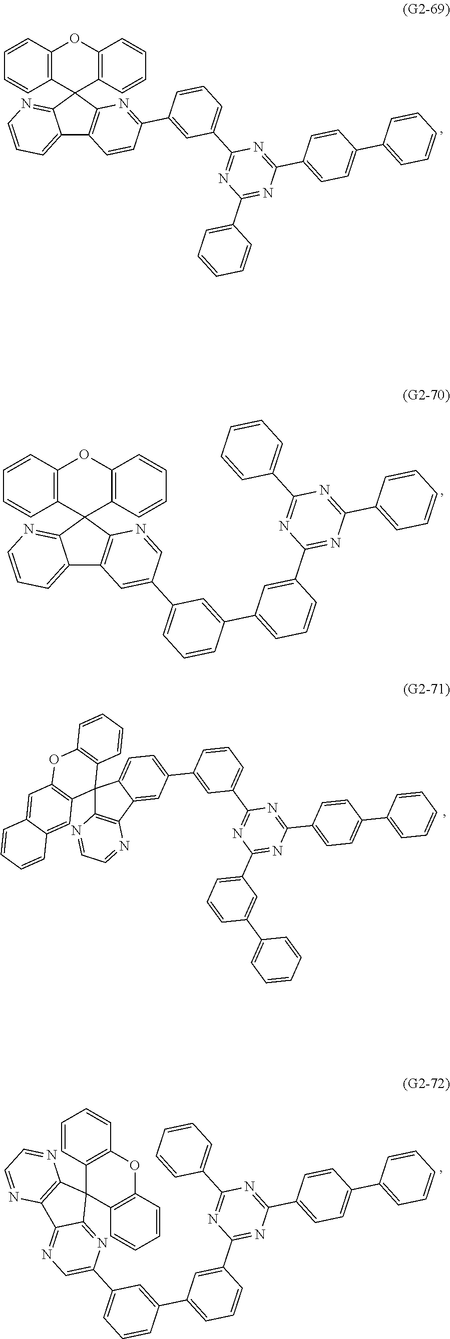 [SMILES: c1ccc(-c2ccc(-c3nc(-c4ccccc4)nc(-c4cccc(-c5ccc6c(n5)C5(c7ccccc7Oc7ccccc75)c5ncccc5-6)c4)n3)cc2)cc1 ; c1ccc(-c2nc(-c3ccccc3)nc(-c3cccc(-c4cccc(-c5cnc6c(c5)-c5cccnc5C65c6ccccc6Oc6ccccc65)c4)c3)n2)cc1 ; c1ccc(-c2ccc(-c3nc(-c4cccc(-c5ccccc5)c4)nc(-c4cccc(-c5ccc6c(c5)-c5nccnc5C65c6ccccc6Oc6cc7ccccc7cc65)c4)n3)cc2)cc1 ; c1ccc(-c2ccc(-c3nc(-c4ccccc4)nc(-c4cccc(-c5cccc(-c6cnc7c(n6)C6(c8ccccc8Oc8ccccc86)c6nccnc6-7)c5)c4)n3)cc2)cc1]

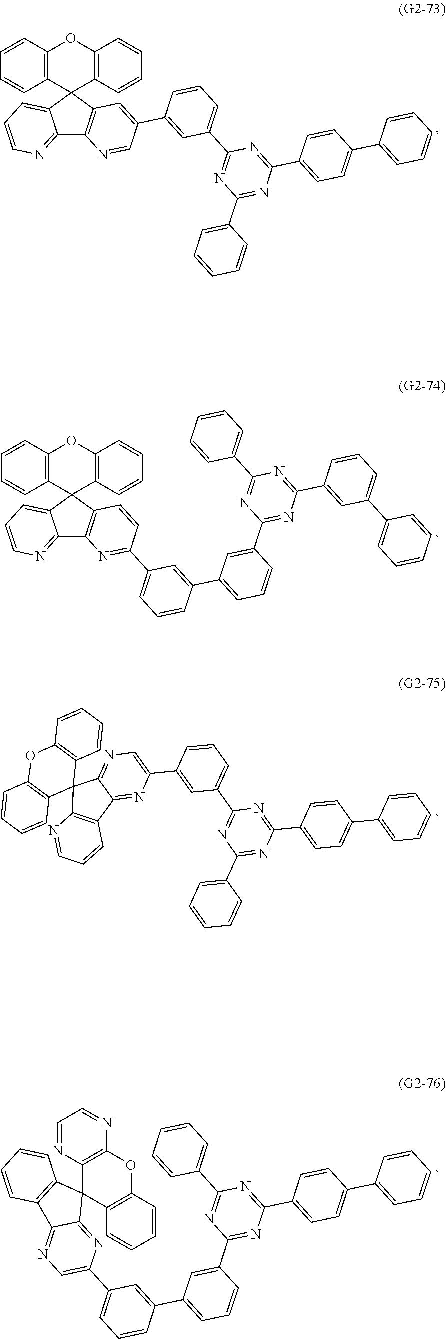 [SMILES: c1ccc(-c2ccc(-c3nc(-c4ccccc4)nc(-c4cccc(-c5cnc6c(c5)C5(c7ccccc7Oc7ccccc75)c5cccnc5-6)c4)n3)cc2)cc1 ; c1ccc(-c2cccc(-c3nc(-c4ccccc4)nc(-c4cccc(-c5cccc(-c6ccc7c(n6)-c6ncccc6C76c7ccccc7Oc7ccccc76)c5)c4)n3)c2)cc1 ; c1ccc(-c2ccc(-c3nc(-c4ccccc4)nc(-c4cccc(-c5cnc6c(n5)-c5cccnc5C65c6ccccc6Oc6ccccc65)c4)n3)cc2)cc1 ; c1ccc(-c2ccc(-c3nc(-c4ccccc4)nc(-c4cccc(-c5cccc(-c6cnc7c(n6)C6(c8ccccc8Oc8nccnc86)c6ccccc6-7)c5)c4)n3)cc2)cc1]

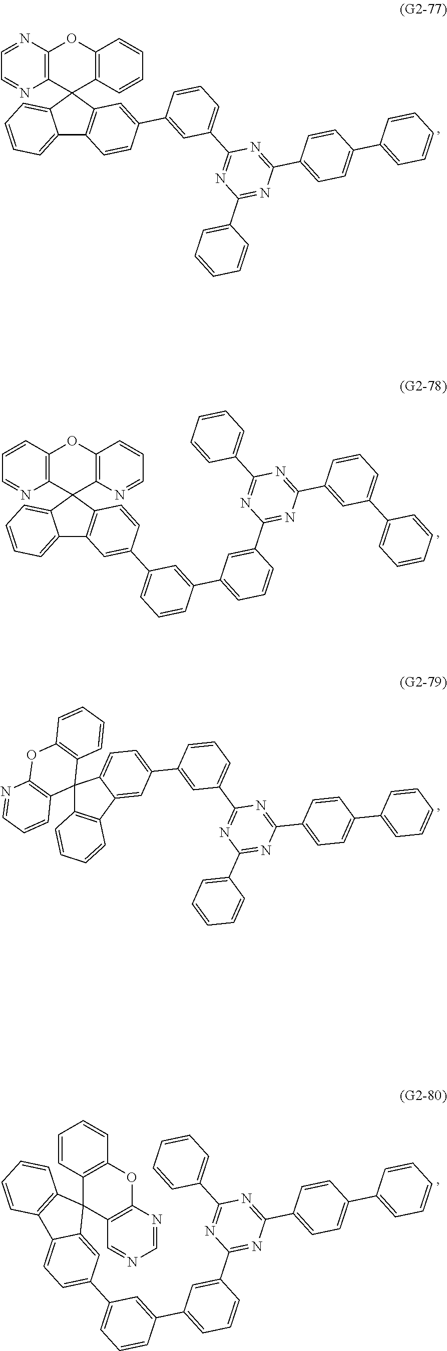 [SMILES: c1ccc(-c2ccc(-c3nc(-c4ccccc4)nc(-c4cccc(-c5ccc6c(c5)C5(c7ccccc7Oc7nccnc75)c5ccccc5-6)c4)n3)cc2)cc1 ; c1ccc(-c2cccc(-c3nc(-c4ccccc4)nc(-c4cccc(-c5cccc(-c6ccc7c(c6)-c6ccccc6C76c7ncccc7Oc7cccnc76)c5)c4)n3)c2)cc1 ; c1ccc(-c2ccc(-c3nc(-c4ccccc4)nc(-c4cccc(-c5ccc6c(c5)-c5ccccc5C65c6ccccc6Oc6ncccc65)c4)n3)cc2)cc1 ; c1ccc(-c2ccc(-c3nc(-c4ccccc4)nc(-c4cccc(-c5cccc(-c6ccc7c(c6)C6(c8ccccc8Oc8ncncc86)c6ccccc6-7)c5)c4)n3)cc2)cc1]

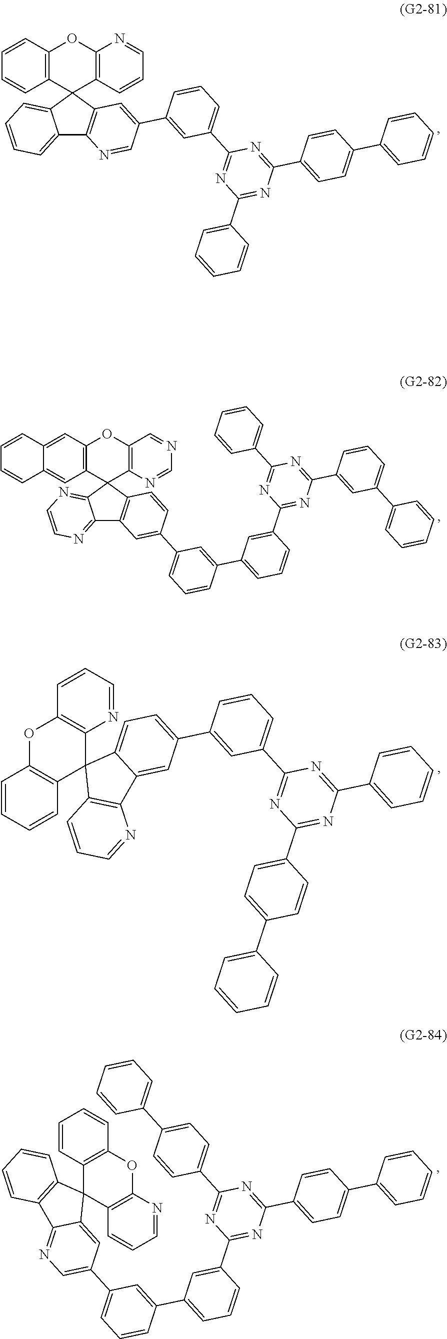 [SMILES: c1ccc(-c2ccc(-c3nc(-c4ccccc4)nc(-c4cccc(-c5cnc6c(c5)C5(c7ccccc7Oc7ncccc75)c5ccccc5-6)c4)n3)cc2)cc1 ; c1ccc(-c2cccc(-c3nc(-c4ccccc4)nc(-c4cccc(-c5cccc(-c6ccc7c(c6)-c6nccnc6C76c7cc8ccccc8cc7Oc7cncnc76)c5)c4)n3)c2)cc1 ; c1ccc(-c2ccc(-c3nc(-c4ccccc4)nc(-c4cccc(-c5ccc6c(c5)-c5ncccc5C65c6ccccc6Oc6cccnc65)c4)n3)cc2)cc1 ; c1ccc(-c2ccc(-c3nc(-c4ccc(-c5ccccc5)cc4)nc(-c4cccc(-c5cccc(-c6cnc7c(c6)C6(c8ccccc8Oc8ncccc86)c6ccccc6-7)c5)c4)n3)cc2)cc1]

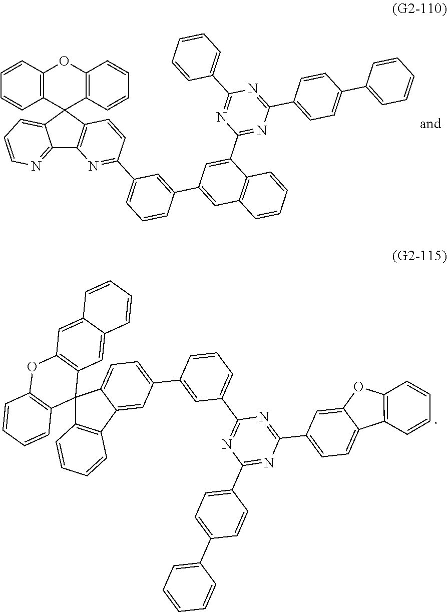 [SMILES: c1ccc(-c2ccc(-c3nc(-c4ccccc4)nc(-c4cc(-c5cccc(-c6ccc7c(n6)-c6ncccc6C76c7ccccc7Oc7ccccc76)c5)cc5ccccc45)n3)cc2)cc1 ; c1ccc(-c2ccc(-c3nc(-c4cccc(-c5ccc6c(c5)-c5ccccc5C65c6ccccc6Oc6cc7ccccc7cc65)c4)nc(-c4ccc5c(c4)oc4ccccc45)n3)cc2)cc1]

In some examples, in a case where Y₉₁ is sulfur, the structural formula of the second functional material G2 may be as shown below.

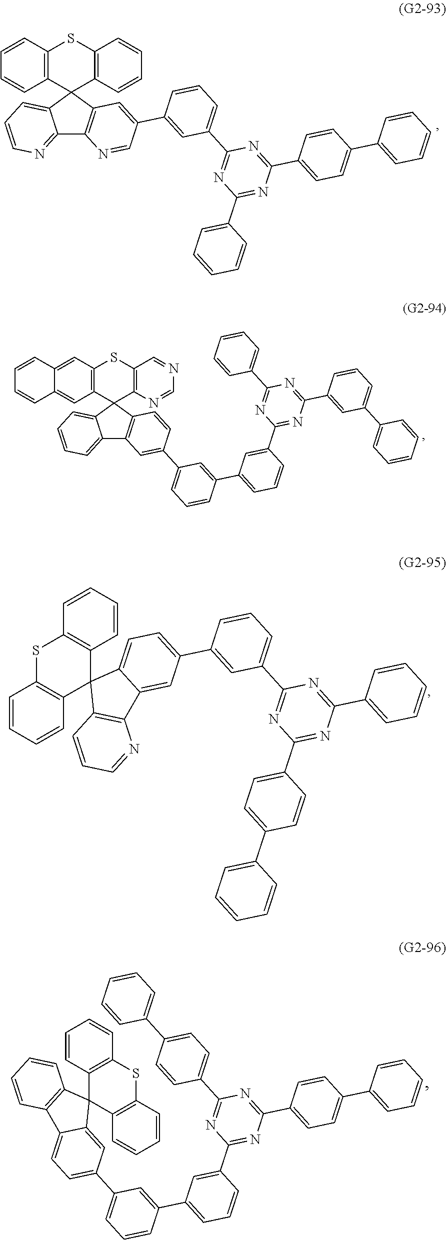 [SMILES: c1ccc(-c2ccc(-c3nc(-c4ccccc4)nc(-c4cccc(-c5cnc6c(c5)C5(c7ccccc7Sc7ccccc75)c5cccnc5-6)c4)n3)cc2)cc1 ; c1ccc(-c2cccc(-c3nc(-c4ccccc4)nc(-c4cccc(-c5cccc(-c6ccc7c(c6)-c6ccccc6C76c7cc8ccccc8cc7Sc7cncnc76)c5)c4)n3)c2)cc1 ; c1ccc(-c2ccc(-c3nc(-c4ccccc4)nc(-c4cccc(-c5ccc6c(c5)-c5ncccc5C65c6ccccc6Sc6ccccc65)c4)n3)cc2)cc1 ; c1ccc(-c2ccc(-c3nc(-c4ccc(-c5ccccc5)cc4)nc(-c4cccc(-c5cccc(-c6ccc7c(c6)C6(c8ccccc8Sc8ccccc86)c6ccccc6-7)c5)c4)n3)cc2)cc1]

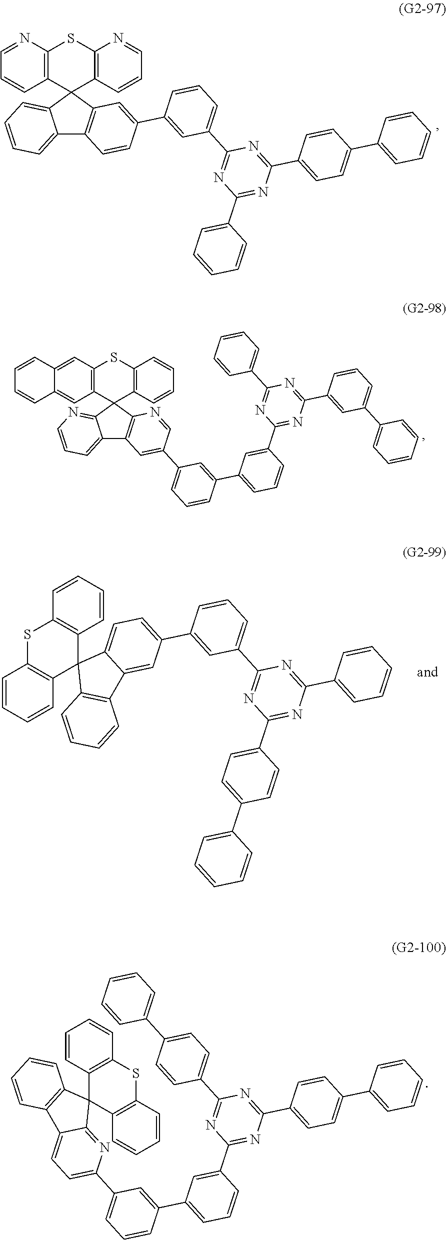 [SMILES: c1ccc(-c2ccc(-c3nc(-c4ccccc4)nc(-c4cccc(-c5ccc6c(c5)C5(c7ccccc7-6)c6cccnc6Sc6ncccc65)c4)n3)cc2)cc1 ; c1ccc(-c2cccc(-c3nc(-c4ccccc4)nc(-c4cccc(-c5cccc(-c6cnc7c(c6)-c6cccnc6C76c7ccccc7Sc7cc8ccccc8cc76)c5)c4)n3)c2)cc1 ; c1ccc(-c2ccc(-c3nc(-c4ccccc4)nc(-c4cccc(-c5ccc6c(c5)-c5ccccc5C65c6ccccc6Sc6ccccc65)c4)n3)cc2)cc1 ; c1ccc(-c2ccc(-c3nc(-c4ccc(-c5ccccc5)cc4)nc(-c4cccc(-c5cccc(-c6ccc7c(n6)C6(c8ccccc8Sc8ccccc86)c6ccccc6-7)c5)c4)n3)cc2)cc1]

It will be noted that the structural formulas listed above are examples of the structure of the second functional material G2, but not limitations on the second functional material G2. Moreover, (G2-x) in the above structural formulas is a synonym for each structural formula and is not a part of the structure of the structural formula, where x is a positive integer.

In some embodiments, L₂₁ has a structure represented by the following structure (IIA).

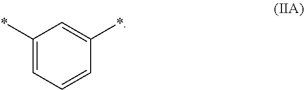

Where * indicates a connection site.

It will be noted that * represents a connection site, which refers to a position where IIA and a group connected thereto are connected. In a case where L₂₁ has the structure represented by the structure (IIA), the two connection sites are a connection site between the triazine group and IIA (i.e., L₂₁), and another connection site between the phenylene group and IIA (i.e., L₂₁). Moreover, the two connection sites are distributed in the meta position.

It will be noted that in a case where L₂₁ has the structure represented by (IIA), there is no limitation on the types of R₂₁ and R₂₂. That is, R₂₁ and R₂₂ may each be independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₂₁ and R₂₂ are connected with an adjacent group to form substituted or unsubstituted 3- to 30-membered ring. In particular, R₂₁ and R₂₂ may be connected to form a six-membered ring, or R₂₁ and R₂₂ may be connected to form the structure shown in the IIB portion, or R₂₁ and R₂₂ may both be phenyl groups or both be methyl groups.

It can be understood that in a case where L₂₁ has the structure shown in (IIA), in the structure shown in the general formula (II) or the general formula (II-A), the triazine group and the fluorene group are separated by a biphenyl group composed of L₂₁ and a phenylene group, and a connection site between the fluorene group and the phenylene group and a connection site between the phenylene group and L₂₁ are distributed in the meta position. Moreover, the connection site between the phenylene group and L₂₁ and a connection site between L₂₁ and the triazine group are distributed in the meta position. In this way, the separation effect between the fluorene group and the triazine group may be improved, and the delocalization of the HOMO electron cloud and the T1 energy level electron cloud distributed on the fluorene group (or IIB portion) to the electron-withdrawing group triazine group may be reduced, so that the HOMO energy level of the second functional material G2 is deep and the T1 energy level is high. Thus, holes and excitons in the light-emitting layer 131 may be blocked from leaking to the cathode 12, thereby increasing the recombination probability of the excitons and improving the efficiency and life of the light-emitting device 100.

The exemplary structures of the second functional material G2 are described below in a case where L₂₁ has the structure shown in (IIA). For example, the structural formula of the second functional material G2 may be as shown in (G2-2), (G2-4), (G2-6), (G2-8), (G2-10), (G2-12), (G2-14), (G2-16), (G2-18), (G2-20), (G2-22), (G2-24), (G2-26), (G2-28), (G2-30), (G2-32), (G2-34), (G2-36), (G2-38), (G2-40), (G2-42), (G2-44), (G2-46), (G2-48), (G2-50), (G2-52), (G2-54), (G2-56), (G2-58), (G2-60), (G2-62), (G2-64), (G2-66), (G2-68), (G2-70), (G2-72), (G2-74), (G2-76), (G2-78), (G2-80), (G2-82), (G2-84), (G2-86), (G2-88), (G2-90), (G2-92), (G2-94), (G2-96), (G2-98), (G2-100), (G2-102), (G2-104), (G2-106), (G2-108) and (G2-116) above.

In some examples, L₂₁ is a naphthylene group, and a connection site between the phenylene group and the naphthylene group and a connection site between the naphthylene group and the triazine group are distributed in the meta position.

With such a provision, similar to the case where L₂₁ has the structure shown as (IIA) above, the separation effect between the fluorene group and the triazine group may be improved, and the delocalization of the HOMO electron cloud and the T1 energy level electron cloud distributed on the fluorene group (or IIB portion) to the electron-withdrawing group triazine group may be reduced, so that the HOMO energy level of the second functional material G2 is deep and the T1 energy level is high. Thus, holes and excitons in the light-emitting layer 131 may be blocked from leaking to the cathode 12, thereby increasing the recombination probability of the excitons and improving the efficiency and life of the light-emitting device 100.

For example, in a case where L₂₁ is a naphthylene group, and the connection site between the phenylene group and the naphthylene group and the connection site between the naphthylene group and the triazine group are distributed in the meta position, the structural formula of the second functional material G2 may be as shown in (G2-110), (G2-112) and (G2-114) above.

In some embodiments, X₂₁, X₂₂, X₂₃ and X₂₄ are substituted or unsubstituted carbon.

It can be understood that in a case where X₂₁, X₂₂, X₂₃ and X₂₄ are substituted or unsubstituted carbon, the fluorene group in the structure represented by the general formula (II) or the general formula (II-A) does not contain a nitrogen atom. Compared with the case where the fluorene group contains a nitrogen atom, in a case where the fluorene group does not contain the nitrogen atom, the electron-donating ability of the fluorene group is relatively strong, so that the HOMO electron cloud of the second functional material G2 and the T1 energy level electron cloud are distributed at the position of the fluorene group. In this way, in a case where the phenylene group separates the fluorene group and the triazine group, the HOMO energy level of the second functional material G2 is deep and the T1 energy level is high. Thus, holes and excitons in the light-emitting layer 131 may be blocked from leaking to the cathode 12, thereby increasing the recombination probability of the excitons and improving the efficiency and life of the light-emitting device 100.

The exemplary structures of the second functional material G2 are described below in a case where X₂₁, X₂₂, X₂₃ and X₂₄ are substituted or unsubstituted carbon. For example, the structural formula of the second functional material G2 may be as shown in (G2-1), (G2-2), (G2-17), (G2-18), (G2-19), (G2-33) to (G2-36), (G2-49) to (G2-56), (G2-61), (G2-62), (G2-77) to (G2-80), (G2-86), (G2-89), (G2-91), (G2-94), (G2-97), (G2-99), (G2-101), (G2-108), (G2-109), (G2-113), (G2-115) and (G2-116) above.

It will be noted that the structural formulas listed above are examples of the structure of the second functional material G2, but not limitations on the second functional material G2.

The above is an exemplary introduction to the first functional material G1 and the second functional material G2 in the first-type functional layer of the light-emitting device 100, and other film materials (e.g., a third functional material) in the first-type functional layer will be introduced below.

In some embodiments, the first-type functional layer further includes a third functional layer, and the third functional layer is located on a side of the first functional layer away from the second functional layer. A material of the third functional layer includes a third functional material, and the third functional material is selected from any of ytterbium and lithium fluoride.

In a case where the first functional layer is the electron transport layer 1332 and the second functional layer is the hole blocking layer 1333, the third functional layer is the electron injection layer 1331.

It can be understood that in a case where the first-type functional layer includes the third functional layer, and the material of the third functional layer (i.e., the third functional material) is selected from any of ytterbium and lithium fluoride, injection of electrons may increase. When used in combination with the first functional material G1 and the second functional material G2 above, good electron injection and electron transport may be achieved, so as to balance the distribution of carriers (holes and/or electrons), so that electroluminescence may increase, and the recombination probability of excitons may increase, thereby improving the efficiency and life of the light-emitting device 100.

In some examples, the third functional material is ytterbium (e.g., as described in detail in Embodiment 12 to Embodiment 14 below). In other examples, the third functional material is lithium fluoride (e.g., as described in detail in Embodiment 1 to Embodiment 11 and Embodiment 15 to Embodiment 25 below).

The above is an exemplary introduction to the materials of the first-type functional layer of the light-emitting device 100, and the materials of the light-emitting layer 131 of the light-emitting device 100 will be introduced below.

In some embodiments, the guest material D is configured to emit blue light.

It can be understood that in a case where the structures of the first functional material G1 and the second functional material G2 both contain fluorene groups, and the guest material D is configured to emit blue light, in the first light-emitting device 101, an interface between the first functional layer and the second functional layer may be optimized, which is beneficial to transport of electrons between the first functional layer and the second functional layer in the first light-emitting device 101. In this way, the electron transport effect of the first light-emitting device 101 may be improved, and the electron transport may be well controlled, so that electrons and holes in the light-emitting layer 131 are rather balanced, and the recombination probability of the excitons increases, which may meet the electron transport requirements of the first light-emitting device 101, thereby improving the efficiency and life of the first light-emitting device 101.

Compared with a guest material D of the second light-emitting device 102 and a guest material D of the third light-emitting device 103, the guest material D of the first light-emitting device 101 for emitting blue light generally has a large singlet energy level (S1 energy level) and a large triplet energy level (T1 energy level), and a difference between the LUMO energy level and the HOMO energy level is also relatively large. Moreover, as described above, in a case where the display panel 200 includes the first light-emitting device 101, the second light-emitting device 102 and the third light-emitting device 103, the first functional layer (e.g., the electron transport layer 1332) and the second functional layer (e.g., the hole blocking layer 1333) may be common film layers shared by the plurality of light-emitting devices 100. Therefore, compared with the second light-emitting device 102 and the third light-emitting device 103, the first light-emitting device 101 proposes relatively high requirements on the electron transport properties of the first functional layer (e.g., the electron transport layer 1332) and the second functional layer (e.g., the hole blocking layer 1333). In a case where the first functional layer (e.g., the electron transport layer 1332) and the second functional layer (e.g., the hole blocking layer 1333) meet the electron transport requirements of the first light-emitting device 101, the first functional layer and the second functional layer also meet the electron transport effects of the second light-emitting device 102 and the third light-emitting device 103. In this way, the efficiency and life of the display panel 200 may be improved.

In some embodiments, the structural formula of the host material H is as follows.

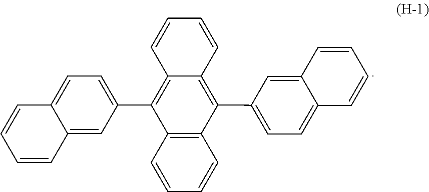 [SMILES: c1ccc2cc(-c3c4ccccc4c(-c4ccc5ccccc5c4)c4ccccc34)ccc2c1]

It can be understood that the host material H represented by the structure (H-1) is 9,10-di(2-naphthyl) anthracene (ADN), which is an anthracene-core fluorescent material and may be used as the host material H of the light-emitting device 100 (e.g., the first light-emitting device 101) to effectively transfer energy with the guest material D. For example, the LUMO energy level of the host material H is −2.98 eV, and the HOMO energy level of the host material H is −5.74 eV.

In a case where the structure of the second functional material G2 contains a fluorene group (e.g., the second functional material G2 is selected from one of the structures represented by the general formula (II)), and the structure of the host material H is as shown in (H-1), the difference between the HOMO energy level of the second functional material G2 and the HOMO energy level of the host material H may be within a suitable range, for example, the difference is 0.8 eV. In this way, holes may be effectively prevented from leaking to the cathode 12, and the recombination probability of excitons may increase, so that the utilization rate of excitons may increase, thereby improving the efficiency and life of the light-emitting device 100 (e.g., the first light-emitting device 101).

In some embodiments, the structural formula of the host material H is as follows.

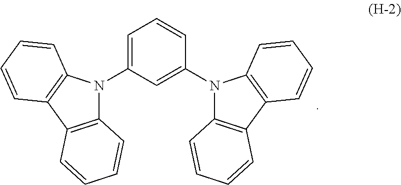 [SMILES: c1cc(-n2c3ccccc3c3ccccc32)cc(-n2c3ccccc3c3ccccc32)c1]

It can be understood that the host material H represented by the structure (H-2) is 9,9′-(1,3-phenylene)bis-9H-carbazole (MCP), which is a TADF host material H with a high singlet energy level and a high triplet energy level (e.g., 2.91 eV), and may be used as the host material H of the light-emitting device 100 (e.g., the first light-emitting device 101) to effectively transfer energy with the guest material D. For example, the LUMO energy level of the host material H is −2.3 eV, and the HOMO energy level of the host material H is −5.8 eV.

In a case where the structure of the second functional material G2 contains a fluorene group (e.g., the second functional material G2 is selected from one of the structures represented by the general formula (II)), and the structure of the host material H is as shown in (H-2), the difference between the HOMO energy level of the second functional material G2 and the HOMO energy level of the host material H may be within a suitable range. In this way, holes may be effectively prevented from leaking to the cathode 12, and the recombination probability of excitons may increase, so that the utilization rate of excitons may increase, thereby improving the efficiency and life of the light-emitting device 100 (e.g., the first light-emitting device 101).

In some embodiments, the guest material D is selected from any of a fluorescent material, a phosphorescent material and a delayed fluorescent material.

It can be understood that in a case where the structures of the first functional material G1 and the second functional material G2 both contain fluorene groups, and the guest material D is a fluorescent material, the first functional material G1 (e.g., the material of the electron transport layer 1332) and the second functional material G2 (e.g., the material of the hole blocking layer 1333) may be used to effectively transport electrons to the light-emitting layer 131, thereby improving the electron transport effect of the first-type functional layer. Then, the electrons transported to the light-emitting layer 131 and the holes from the anode 11 recombine to generate singlet excitons, and the guest material D utilizes the singlet excitons to emit light, thereby achieving a purpose of emitting light of a set wavelength.

It can be understood that in a case where the structures of the first functional material G1 and the second functional material G2 both contain fluorene groups, and the guest material D is a phosphorescent material or a delayed fluorescent material, the first functional material G1 (e.g., the material of the electron transport layer 1332) and the second functional material G2 (e.g., the material of the hole blocking layer 1333) may be used to effectively transport electrons to the light-emitting layer 131, thereby improving the electron transport effect of the first-type functional layer. Then, the electrons transported to the light-emitting layer 131 and the holes from the anode 11 recombine to generate triplet excitons, and the guest material D utilizes the triplet excitons to emit light, thereby achieving a purpose of emitting light of a set wavelength.

For example, the guest material D is configured to emit light of a set color. The set color may be red, green, blue, yellow, orange or white.

For example, in a case where the guest material D is configured to emit blue light, the guest material D may be a pyrene derivative, a fluorene derivative, a perylene derivative, a styrylamine derivative, a metal complex or a TADF material, such as TBPe, BDAVBi, DPAVBi, Firpic, SpiroAC-TRZ or 4CzFCN.

For example, in a case where the guest material D is configured to emit green light, the guest material D may be a metal complex, such as Ir(ppy)₃ or Ir(ppy)₂(acac).

For example, in a case where the guest material D is configured to emit red light, the guest material D may be a metal complex, such as Ir(piq)₂(acac), PtOEP, or Ir(btp)₂(acac).

For example, as described in detail in Embodiment 1 to Embodiment 7, Embodiment 12 to Embodiment 14, and Embodiment 19 to Embodiment 25 below, the fluorescent material may have the following structure (DPAVBi). The fluorescent material has an absorption peak wavelength of 405 nm, and may emit blue light.

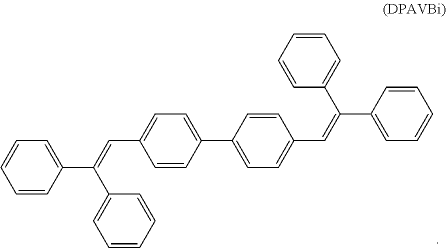 [SMILES: C(=C(c1ccccc1)c1ccccc1)c1ccc(-c2ccc(C=C(c3ccccc3)c3ccccc3)cc2)cc1]

For example, as described in detail in Embodiment 8 and Embodiment 9 below, the phosphorescent material may have the following structure (Firpic).

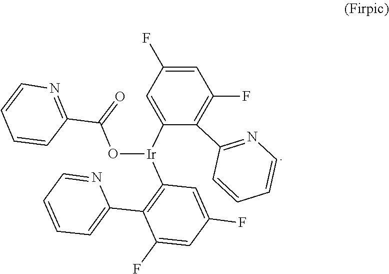

For example, as described in detail in Embodiment 10 and Embodiment 11 below, the delayed fluorescent material may have the following structure (SpiroAC-TRZ).

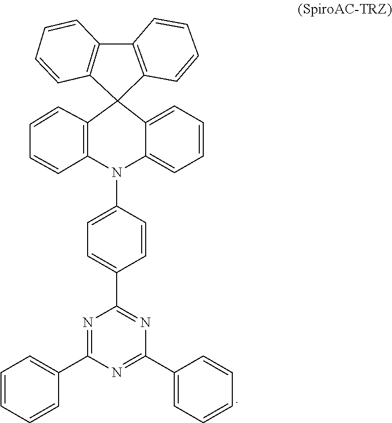 [SMILES: c1ccc(-c2nc(-c3ccccc3)nc(-c3ccc(N4c5ccccc5C5(c6ccccc6-c6ccccc65)c5ccccc54)cc3)n2)cc1]

In some embodiments, the light-emitting device 100 includes at least two light-emitting units 13. A material of a second functional layer of each light-emitting unit 13 includes a second functional material G2.

It can be understood that in a case where the material of the second functional layer of each light-emitting unit 13 includes the second functional material G2 (e.g., the second functional material G2 having a structure represented by the general formula (II)), an interface between the first functional layer and the second functional layer in each light-emitting unit 13 may be optimized, which is beneficial to transport of electrons in each light-emitting unit 13. Thus, an overall electron transport effect of the stacked light-emitting device 100 may be improved, and the recombination probability of excitons in the light-emitting layer 131 of each light-emitting unit 13 may increase, so that the efficiency and life of each light-emitting unit 13 may be improved, thereby improving the efficiency and life of the light-emitting device 100.

Moreover, in a case where the material of the second functional layer of each light-emitting unit 13 is selected from one of the structures represented by the general formula (II), the HOMO electron cloud and the T1 energy level electron cloud of the second functional material G2 in each light-emitting unit 13 are distributed at the position of the fluorene group. Moreover, the phenylene group in the structure represented by the general formula (II) may be used to separate the fluorene group and the triazine group to reduce the delocalization of the HOMO electron cloud and the T1 energy level electron cloud distributed on the electron-donating group fluorene group to the electron-withdrawing group triazine group, so that the HOMO energy level of the second functional material G2 is deep and the T1 energy level is high. Thus, holes and excitons in the light-emitting layer 131 may be blocked from leaking to the cathode 12, so as to increase the recombination probability of the excitons, so that the efficiency and life of each light-emitting unit 13 may be improved, thereby improving the efficiency and life of the light-emitting device 100.

In order to objectively evaluate technical effects of the embodiments of the present disclosure, technical solutions provided by the present disclosure will be exemplarily described in detail below through experimental examples and comparative examples. According to different structures of the light-emitting devices 100 and different materials of the light-emitting layers 131, experimental examples and comparative examples in the following are divided into a first group of experimental examples, a second group of experimental examples, a third group of experimental examples, a fourth group of experimental examples and a fifth group of experimental examples.

### First Group of Experimental Examples

The embodiments and comparative examples in the following produce the electron transport layer 1332 (i.e., the first functional layer) and the hole blocking layer 1333 (i.e., the second functional layer) in the first light-emitting device 101 using different materials, and perform comparison on a driving voltage, a current efficiency and a device life of the first light-emitting device 101.

In the following Comparative Example 2 and Embodiments 1 to 7, structures of the first light-emitting devices 101 are all the same. In the following Comparative Example 1, the first-type functional layer (i.e., the electron transport functional layer 133) does not include the hole blocking layer 1333, and structures of other film layers except the hole blocking layer 1333 are the same as those of Comparative Example 2 and Embodiments 1 to 7. In the following Comparative Examples 1 and 2 and Embodiments 1 to 7, test conditions of the first light-emitting devices 101 are the same.

As shown in FIG. 5, the manufacture method of the first light-emitting device 101 is as follows: taking a substrate 210 provided with an array layer, a pixel defining layer and an anode 11 as a substrate, cleaning and drying the substrate, placing the substrate into a vacuum evaporation device, and using the material of the hole injection layer 1321, the material of the hole transport layer 1322, the material of the electron blocking layer 1323, the material of the light-emitting layer 131, the material of the hole blocking layer 1333, the material of the electron transport layer 1332, the material of the electron injection layer 1331 and the material of the cathode 12 to sequentially form the hole injection layer 1321, the hole transport layer 1322, the electron blocking layer 1323, the light-emitting layer 131, the hole blocking layer 1333, the electron transport layer 1332, the electron injection layer 1331 and the cathode 12 on the substrate.

It will be noted that the thicknesses of the hole injection layer 1321, the hole transport layer 1322, the electron blocking layer 1323, the light-emitting layer 131, the hole blocking layer 1333, the electron transport layer 1332, the electron injection layer 1331 and the cathode 12 in the embodiments and comparative examples are all the same, which are 10 nm, 110 nm, 5 nm, 20 nm, 5 nm, 30 nm, 1 nm and 130 nm, respectively. The materials of the anode 11, the hole injection layer 1321, the hole transport layer 1322, the electron blocking layer 1323, the light-emitting layer 131, the electron injection layer 1331 and the cathode 12 in the embodiments and comparative examples are all the same. The material of the anode 11 is indium tin oxide (ITO), the structure of the material of the hole injection layer 1321 is as shown in the following structure (HAT-CN), the structure of the material of the hole transport layer 1322 is as shown in the following structure (NPB), the structure of the material of the electron blocking layer 1323 is as shown in the following structure (TCTA), the structure of the host material H of the light-emitting layer 131 (EML) is as shown in the above structure (H-1), the structure of the guest material D (also called blue fluorescent dopant) of the light-emitting layer 131 (EML) is as shown in the above structure (DPAVBi), the material of the electron injection layer 1331 is lithium fluoride (LiF), and the material of the cathode 12 is aluminum. Furthermore, in the light-emitting layer 131, a mass ratio of the host material H to the guest material D is 95:5.

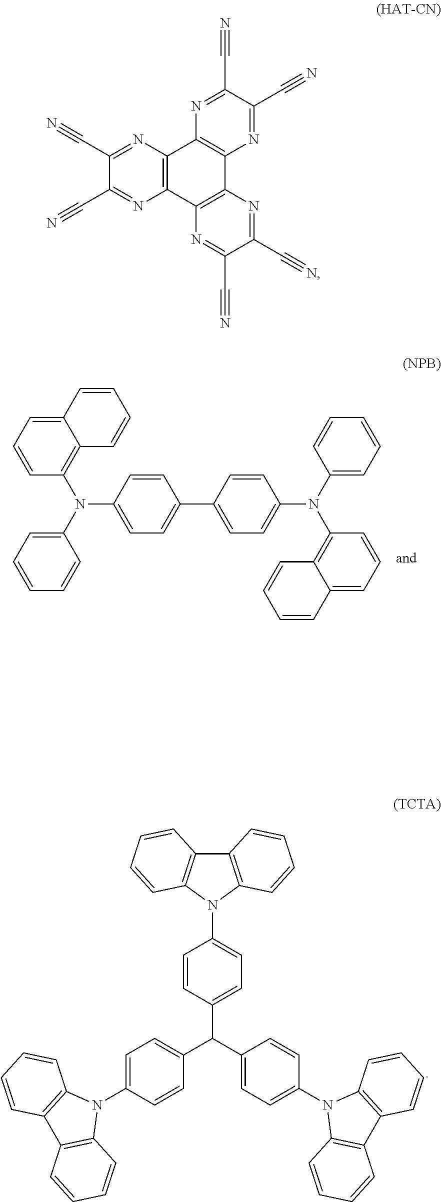 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc2c(c1)c1ccccc1n2-c1ccc(C(c2ccc(-n3c4ccccc4c4ccccc43)cc2)c2ccc(-n3c4ccccc4c4ccccc43)cc2)cc1]

It will be noted that (HAT-CN), (NPB) and (TCTA) in the above structural formulas are each a synonym for a respective structural formula and is not a part of the structure of the structural formula.

The materials of the first functional layers (i.e., the electron transport layers 1332, ETL) and the second functional layers (i.e., the hole blocking layers 1333, HBL) of the first light-emitting devices 101 in the embodiments and comparative examples will be described below.

In Embodiment 1, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-2).

In Embodiment 2, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-18).

In Embodiment 3, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-20).

In Embodiment 4, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-33).

In Embodiment 5, the material of the first functional layer is composed of the first functional material G1 having a structure as shown in (G1-42) and 8-hydroxyquinoline lithium (LiQ), and a mass ratio of the two is 1:1; and the structural formula of the material of the second functional layer is as shown in (G2-18).

In Embodiment 6, the material of the first functional layer is composed of the first functional material G1 having a structure as shown in (G1-67) and 8-hydroxyquinoline lithium (LiQ), and a mass ratio of the two is 1:1; and the structural formula of the material of the second functional layer is as shown in (G2-18).

In Embodiment 7, the material of the first functional layer is composed of the first functional material G1 having a structure as shown in (G1-97) and 8-hydroxyquinoline lithium (LiQ), and a mass ratio of the two is 1:1; and the structural formula of the material of the second functional layer is as shown in (G2-18).

In Comparative Example 1, the material of the first functional layer is composed of the first functional material G1 having a structure as shown in (G1-18) and 8-hydroxyquinoline lithium (LiQ), and a mass ratio of the two is 1:1.

In Comparative Example 2, the material of the first functional layer is composed of the second functional material G2 having a structure as shown in (G2-2) and 8-hydroxyquinoline lithium (LiQ), and a mass ratio of the two is 1:1; and the structural formula of the material of the second functional layer is shown in (G1-18).

In order to more clearly describe the difference between the material of the first functional layer (i.e., the electron transport layer 1332 ETL) and the material of the second functional layer (i.e., the hole blocking layer 1333 HBL) used in the embodiments and comparative examples, the following Table 1 is used to more clearly show the materials of the first functional layers (i.e., the electron transport layers 1332 ETL) and the materials of the second functional layers (i.e., the hole blocking layers 1333 HBL) used in the embodiments and comparative examples.

Based on the above materials, driving voltages (V), current efficiencies (cd/A) and device lives of the first light-emitting devices 101 in Embodiments 1 to 7 and Comparative Examples 1 and 2 are tested. The test results of the driving voltages (V), the current efficiencies (cd/A) and the device lives take Comparative Example 1 as a reference, and the test results are shown in Table 1 below. The device life is characterized by the parameter LT95.

TABLE 1

| | | HBL | ETL | Driving | Current | |
|---|---|---|---|---|---|---|
| | EML material | material | material | voltage | efficiency | LT95 |
| Embodiment 1 | (H-1):(DPAVBi) | (G2-2) | (G1-18):LiQ | 94% | 108% | 106% |
| Embodiment 2 | (H-1):(DPAVBi) | (G2-18) | (G1-18):LiQ | 94% | 115% | 110% |
| Embodiment 3 | (H-1):(DPAVBi) | (G2-20) | (G1-18):LiQ | 95% | 107% | 105% |
| Embodiment 4 | (H-1):(DPAVBi) | (G2-33) | (G1-18):LiQ | 94% | 110% | 108% |
| Embodiment 5 | (H-1):(DPAVBi) | (G2-18) | (G1-42):LiQ | 94% | 116% | 111% |
| Embodiment 6 | (H-1):(DPAVBi) | (G2-18) | (G1-67):LiQ | 96% | 118% | 112% |
| Embodiment 7 | (H-1):(DPAVBi) | (G2-18) | (G1-97):LiQ | 95% | 117% | 111% |
| Comparative | (H-1):(DPAVBi) | / | (G1-18):LiQ | 100% | 100% | 100% |
| Example 1 | | | | | | |
| Comparative | (H-1):(DPAVBi) | (G1-18) | (G2-2):LiQ | 102% | 98% | 97% |
| Example 2 | | | | | | |

The highest occupied molecular orbital (HOMO) energy levels, the lowest unoccupied molecular orbital (LUMO) energy levels, the triplet (T1) energy levels and the electron mobilities of the first functional materials G1 and the second functional materials G2 shown in Table 1 are shown in Table 2.

TABLE 2

| Material | HOMO energy | LUMO energy | T1 energy | Electron |
|---|---|---|---|---|
| structure | level (eV) | level (eV) | level (eV) | mobility |
| (G1-18) | −6.59 | −3.12 | 2.49 | 9.42 × 10⁻⁶ |
| (G1-42) | −6.45 | −3.10 | 2.30 | 1.03 × 10⁻⁵ |
| (G1-67) | −6.30 | −3.46 | 2.13 | 5.53 × 10⁻⁴ |
| (G1-97) | −6.48 | −3.25 | 2.34 | 3.24 × 10⁻⁵ |
| (G2-2) | −6.66 | −3.24 | 2.65 | 2.35 × 10⁻⁷ |
| (G2-18) | −6.62 | −3.26 | 2.63 | 4.68 × 10⁻⁷ |
| (G2-20) | −6.70 | −3.31 | 2.68 | 3.22 × 10⁻⁶ |
| (G2-33) | −6.53 | −3.22 | 2.58 | 8.46 × 10⁻⁷ |

It will be noted that “(A-x)” in Table 1 and Table 2 means that the corresponding structural formula is as shown in the above structural formula (A-x). For example, a content of a sub-grid corresponding to the material of the HBL (i.e., the hole blocking layer 1333) in Embodiment 1 is “(G2-2)”, which means that in Embodiment 1, the structural formula of the material of the HBL (i.e., the hole blocking layer 1333) is as shown in the above structural formula (G2-2). The structural formulas represented by (G1-x), (G2-x) (x is a positive integer), (H-1) and (DPAVBi) refer to the above contents, and details are not repeated here.

It will be noted that the HOMO energy level and the LUMO energy level in Table 2 are measured by AC3&CV&UV spectroscopy, where AC3 is photoelectron spectroscopy, CV is Raman spectroscopy, and UV is ultraviolet spectroscopy. The T1 energy level is measured by low-temperature phosphorescence; and the electron mobility is calculated by SCLC (based on space charge limited current technology) method.

Comparing Embodiments 1 to 7 with Comparative Examples 1 and 2, referring to Table 1, the current efficiencies and the device lives in Embodiments 1 to 7 are relatively high. This is because that the first light-emitting device 101 in Comparative Example 1 is not provided with a hole blocking layer 1333, and in Comparative Example 2, the material of the electron transport layer 1332 includes the second functional material G2 having a structure as shown in (G2-2), and the material of the hole blocking layer 1333 is the first functional material G1 having a structure as shown in (G1-18). In this way, compared with Embodiments 1 to 7, the electron transport properties in Comparative Examples 1 and 2 are relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the first light-emitting device 101 may be improved. As a result, electrons and holes in the light-emitting layer 131 are rather balanced, and the recombination probability of the excitons increases. In this way, firstly, the yield of excitons may increase, so that the efficiency of the first light-emitting device 101 may be improved; secondly, the distribution of the carriers may be balanced to block holes or excitons from leaking to a side of the cathode 12, so that the life of the first light-emitting device 101 may be improved.

Comparing Embodiments 1 to 7 with Comparative Examples 1 and 2, referring to Table 1, the driving voltages in Embodiments 1 to 7 are relatively low. This is because that compared with Embodiments 1 to 7, the electron transport properties in Comparative Examples 1 and 2 are relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage is relatively low.

Comparing Embodiment 2 with Embodiment 1, referring to Table 1, the current efficiency and the device life in Embodiment 2 are relatively high. This is because that compared with the second functional material G2 shown in the structure (G2-2), the electron mobility of the second functional material G2 shown in the structure (G2-18) is relatively high, so that electrons and holes in the light-emitting layer 131 are relatively more balanced, and the recombination probability of excitons may increase, thereby improving the efficiency and life of the first light-emitting device 101.

Comparing Embodiment 3 with Embodiment 2, referring to Table 1, the current efficiency and the device life in Embodiment 2 are relatively high. This is because that the fluorene group in the second functional material G2 with a structure as shown in (G2-20) contains a nitrogen atom, so that the electron mobility of the hole blocking layer 1333 in Embodiment 3 is relatively high; while the fluorene group in the second functional material G2 with a structure as shown in (G2-18) does not contain a nitrogen atom. In this case, compared with Embodiment 3, the electron mobility of the hole blocking layer 1333 in Embodiment 2 may be within a relatively appropriate range, so that electrons and holes are relatively more balanced, thereby improving the efficiency and life of the first light-emitting device 101.

Comparing Embodiment 4 with Embodiment 2, referring to Table 1, the current efficiency and the device life in Embodiment 2 are relatively high. This is because that compared with the second functional material G2 shown in the structure (G2-18), the second functional material G2 shown in the structure (G2-33) has a relatively shallow HOMO energy level and a relatively low T1 energy level. In this case, compared with Embodiment 4, the hole blocking layer 1333 in Embodiment 2 has relatively good properties in blocking holes and excitons, and the recombination probability of the excitons may increase, thereby improving the efficiency and life of the first light-emitting device 101.

Comparing Embodiments 5 to 7 with Embodiment 2, referring to Table 1, the current efficiencies and the device lives in Embodiments 5 to 7 are relatively high. This is because that compared with the first functional material G1 shown in the structure (G1-18), the first functional materials G1 shown in the structures (G1-42), (G1-67) and (G1-97) have relatively high electron mobilities, which may optimize the electron injection and transport properties of the first light-emitting device 101, so that electrons and holes in the light-emitting layer 131 are relatively more balanced, and the recombination probability of the excitons increases, thereby improving the efficiency and life of the first light-emitting device 101.

It can be seen from the above embodiments and comparative examples that, in a case where the material of the electron transport layer 1332 of the first light-emitting device 101 is the first functional material G1 described in the present disclosure, the material of the hole blocking layer 1333 of the first light-emitting device 101 is the second functional material G2 described in the present disclosure, and the guest material D is a fluorescent material for emitting blue light, the efficiency and device life of the first light-emitting device 101 are relatively high, and the driving voltage is relatively low, thereby achieving the electroluminescent performance of high efficiency, low driving voltage and long life of the first light-emitting device 101.

### Second Group of Experimental Examples

The embodiments and comparative examples in the following produce the electron transport layer 1332 (i.e., the first functional layer) and the hole blocking layer 1333 (i.e., the second functional layer) in the first light-emitting device 101 using different materials, and perform comparison on a driving voltage, a current efficiency and a device life of the first light-emitting device 101.

In the following Comparative Examples 4 and 6, and Embodiments 8 to 11, structures of the first light-emitting devices 101 are all the same. In the following Comparative Examples 3 and 5, the first-type functional layer (i.e., the electron transport functional layer 133) does not include the hole blocking layer 1333, and structures of other film layers except the hole blocking layer 1333 are the same as those of Embodiments 8 to 11. In the following Comparative Examples 3 to 6 and Embodiments 8 to 11, test conditions of the first light-emitting devices 101 are the same.

As shown in FIG. 5, the manufacture method of the first light-emitting device 101 is as follows: taking a substrate 210 provided with an array layer, a pixel defining layer and an anode 11 as a substrate, cleaning and drying the substrate, placing the substrate into a vacuum evaporation device, and using the material of the hole injection layer 1321, the material of the hole transport layer 1322, the material of the electron blocking layer 1323, the material of the light-emitting layer 131, the material of the hole blocking layer 1333, the material of the electron transport layer 1332, the material of the electron injection layer 1331 and the material of the cathode 12 to sequentially form the hole injection layer 1321, the hole transport layer 1322, the electron blocking layer 1323, the light-emitting layer 131, the hole blocking layer 1333, the electron transport layer 1332, the electron injection layer 1331 and the cathode 12 on the substrate.

It will be noted that the thicknesses of the hole injection layer 1321, the hole transport layer 1322, the electron blocking layer 1323, the light-emitting layer 131, the hole blocking layer 1333, the electron transport layer 1332, the electron injection layer 1331 and the cathode 12 in the embodiments and comparative examples are all the same, which are 10 nm, 110 nm, 5 nm, 20 nm, 5 nm, 30 nm, 1 nm and 130 nm, respectively. The materials of the anode 11, the hole injection layer 1321, the hole transport layer 1322, the electron blocking layer 1323, the electron injection layer 1331 and the cathode 12 in the embodiments and comparative examples are all the same. The material of the anode 11 is indium tin oxide (ITO), the structure of the material of the hole injection layer 1321 is as shown in the above structure (HAT-CN), the structure of the material of the hole transport layer 1322 is as shown in the above structure (NPB), the structure of the material of the electron blocking layer 1323 is as shown in the above structure (TCTA), the material of the electron injection layer 1331 is lithium fluoride (LiF), and the material of the cathode 12 is aluminum.

In the materials of the light-emitting layer 131 in the embodiments and comparative examples, a mass ratio of the host material H to the guest material D is 95:5. The structure of the host material H of the light-emitting layer 131 (EML) in the embodiments and the comparative examples is as shown in the above structure (H-2). The structure of the guest material D (also called blue phosphorescent dopant) of the light-emitting layer 131 (EML) in Embodiments 8 and 9 and Comparative Examples 3 and 4 is as shown in the above structure (Firpic). The structure of the guest material D (also referred to as a blue TADF dopant) of the light-emitting layer 131 (EML) in Embodiments 10 and 11 and Comparative Examples 5 and 6 is as shown in the above structure (SpiroAC-TRZ).

The materials of the first functional layers (i.e., the electron transport layers 1332 ETL) and the second functional layers (i.e., the hole blocking layers 1333 HBL) of the first light-emitting devices 101 in the embodiments and comparative examples will be described below.

In Embodiment 8, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-2).

In Embodiment 9, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-18).

In Comparative Example 3, the material of the first functional layer is composed of the first functional material G1 having a structure as shown in (G1-18) and 8-hydroxyquinoline lithium (LiQ), and a mass ratio of the two is 1:1.

In Comparative Example 4, the material of the first functional layer is composed of the second functional material G2 having a structure as shown in (G2-2) and 8-hydroxyquinoline lithium (LiQ), and a mass ratio of the two is 1:1; and the structural formula of the material of the second functional layer is shown in (G1-18).

In Embodiment 10, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-2).

In Embodiment 11, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-18).

In Comparative Example 5, the material of the first functional layer is composed of the first functional material G1 having a structure as shown in (G1-18) and 8-hydroxyquinoline lithium (LiQ), and a mass ratio of the two is 1:1.

In Comparative Example 6, the material of the first functional layer is composed of the second functional material G2 having a structure as shown in (G2-2) and 8-hydroxyquinoline lithium (LiQ), and a mass ratio of the two is 1:1; and the structural formula of the material of the second functional layer is shown in (G1-18).

In order to more clearly describe the difference between the material of the first functional layer (i.e., the electron transport layer 1332 ETL) and the material of the second functional layer (i.e., the hole blocking layer 1333 HBL) used in the embodiments and comparative examples, the following Table 3 is used to more clearly show the materials of the first functional layers (i.e., the electron transport layers 1332 ETL) and the materials of the second functional layers (i.e., the hole blocking layers 1333 HBL) used in Embodiments 8 and 9 and Comparative Examples 3 and 4; and the following Table 4 is used to more clearly show the materials of the first functional layers (i.e., the electron transport layers 1332 ETL) and the materials of the second functional layers (i.e., the hole blocking layers 1333 HBL) used in Embodiments 10 and 11 and Comparative Examples 5 and 6.

Based on the above materials, driving voltages (V), current efficiencies (cd/A) and device lives of the first light-emitting devices 101 in Embodiments 8 to 11 and Comparative Examples 3 to 6 are tested. In Embodiments 8 and 9 and Comparative Examples 3 and 4, the test results of the driving voltages (V), the current efficiencies (cd/A) and the device lives take Comparative Example 3 as a reference, and the test results are shown in Table 3 below. In Embodiments 10 and 11 and Comparative Examples 5 and 6, the test results of the driving voltages (V), the current efficiencies (cd/A) and the device lives take Comparative Example 5 as a reference, and the test results are shown in Table 4 below. The device life is characterized by the parameter LT95.

TABLE 3

| | | HBL | ETL | Driving | Current | |
|---|---|---|---|---|---|---|
| | EML material | material | material | voltage | efficiency | LT95 |
| Embodiment 8 | (H-2):(Firpic) | (G2-2) | (G1-18):LiQ | 93% | 113% | 112% |
| Embodiment 9 | (H-2):(Firpic) | (G2-18) | (G1-18):LiQ | 93% | 120% | 115% |
| Comparative | (H-2):(Firpic) | / | (G1-18):LiQ | 100% | 100% | 100% |
| Example 3 | | | | | | |
| Comparative | (H-2):(Firpic) | (G1-18) | (G2-2):LiQ | 101% | 96% | 95% |
| Example 4 | | | | | | |

TABLE 4

| | | HBL | ETL | Driving | Current | |
|---|---|---|---|---|---|---|
| | EML material | material | material | voltage | efficiency | LT95 |
| Embodiment 10 | (H-2):(SpiroAC-TRZ) | (G2-2) | (G1-18):LiQ | 94% | 113% | 106% |
| Embodiment 11 | (H-2):(SpiroAC-TRZ) | (G2-18) | (G1-18):LiQ | 94% | 118% | 108% |
| Comparative | (H-2):(SpiroAC-TRZ) | / | (G1-18):LiQ | 100% | 100% | 100% |
| Example 5 | | | | | | |
| Comparative | (H-2):(SpiroAC-TRZ) | (G1-18) | (G2-2):LiQ | 102% | 95% | 93% |
| Example 6 | | | | | | |

It will be noted that “(A-x)” in Table 3 and Table 4 means that the corresponding structural formula is as shown in the above structural formula (A-x). For example, a content of a sub-grid corresponding to the material of the HBL (i.e., the hole blocking layer 1333) in Embodiment 8 is “(G2-2)”, which means that in Embodiment 8, the structural formula of the material of the HBL (i.e., the hole blocking layer 1333) is as shown in the above structural formula (G2-2). The structural formulas represented by (G1-x), (G2-x) (x is a positive integer), (H-2), (SpiroAC-TRZ) and (Firpic) refer to the above contents, and details are not repeated here.

Comparing Embodiments 8 and 9 with Comparative Examples 3 and 4, referring to Table 3, the current efficiencies and the device lives in Embodiments 8 and 9 are relatively high. This is because that the first light-emitting device 101 in Comparative Example 3 is not provided with a hole blocking layer 1333, and in Comparative Example 4, the material of the electron transport layer 1332 includes the second functional material G2 having a structure as shown in (G2-2), and the material of the hole blocking layer 1333 is the first functional material G1 having a structure as shown in (G1-18). In this way, compared with Embodiments 8 and 9, the electron transport properties in Comparative Examples 3 and 4 are relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the first light-emitting device 101 may be improved, and the recombination probability of the excitons may increase, thereby improving the efficiency and life of the first light-emitting device 101.

Comparing Embodiments 8 and 9 with Comparative Examples 3 and 4, referring to Table 3, the driving voltages in Embodiments 8 and 9 are relatively low. This is because that compared with Embodiments 8 and 9, the electron transport properties in Comparative Examples 3 and 4 are relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage is relatively low.

Comparing Embodiment 9 with Embodiment 8, referring to Table 3, the current efficiency and the device life in Embodiment 9 are relatively high. This is because that compared with the second functional material G2 shown in the structure (G2-2), the electron mobility of the second functional material G2 shown in the structure (G2-18) is relatively high, so that electrons and holes in the light-emitting layer 131 are relatively more balanced, and the recombination probability of the excitons may increase, thereby improving the efficiency and life of the first light-emitting device 101.

Comparing Embodiments 10 and 11 with Comparative Examples 5 and 6, referring to Table 4, the current efficiencies and the device lives in Embodiments 10 and 11 are relatively high. This is because that the first light-emitting device 101 in Comparative Example 5 is not provided with a hole blocking layer 1333, and in Comparative Example 6, the material of the electron transport layer 1332 includes the second functional material G2 having a structure as shown in (G2-2), and the material of the hole blocking layer 1333 is the first functional material G1 having a structure as shown in (G1-18). In this way, compared with Embodiments 10 and 11, the electron transport properties in Comparative Examples 5 and 6 are relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the first light-emitting device 101 may be improved, and the recombination probability of excitons may increase, thereby improving the efficiency and life of the first light-emitting device 101.

Comparing Embodiments 10 and 11 with Comparative Examples 5 and 6, referring to Table 4, the driving voltages in Embodiments 10 and 11 are relatively low. This is because that compared with Embodiments 10 and 11, the electron transport properties in Comparative Examples 5 and 6 are relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage is relatively low.

Comparing Embodiment 11 with Embodiment 10, referring to Table 4, the current efficiency and the device life in Embodiment 11 are relatively high. This is because that compared with the second functional material G2 shown in the structure (G2-2), the electron mobility of the second functional material G2 shown in the structure (G2-18) is relatively high, so that electrons and holes in the light-emitting layer 131 are relatively more balanced, and the recombination probability of excitons may increase, thereby improving the efficiency and life of the first light-emitting device 101.

It can be seen from the above embodiments and comparative examples that, in a case where the material of the electron transport layer 1332 of the first light-emitting device 101 is the first functional material G1 described in the present disclosure, the material of the hole blocking layer 1333 of the first light-emitting device 101 is the second functional material G2 described in the present disclosure, and the guest material D is a phosphorescent material or a delayed fluorescent material for emitting blue light, the efficiency and device life of the first light-emitting device 101 are relatively high, and the driving voltage is relatively low, thereby achieving the electroluminescent performance of high efficiency, low driving voltage and long life of the first light-emitting device 101.

### Third Group of Experimental Examples

The embodiments in the following produce the electron transport layer 1332 (i.e., the first functional layer) and the hole blocking layer 1333 (i.e., the second functional layer) in the first light-emitting device 101 using different materials, and perform comparison on a driving voltage, a current efficiency and a device life of the first light-emitting device 101.

In the following Embodiments 12 to 14, the structures of the first light-emitting devices 101 are all the same, and the test conditions of the first light-emitting devices 101 are all the same.

As shown in FIG. 5, the manufacture method of the first light-emitting device 101 is as follows: taking a substrate 210 provided with an array layer, a pixel defining layer and an anode 11 as a substrate, cleaning and drying the substrate, placing the substrate into a vacuum evaporation device, and using the material of the hole injection layer 1321, the material of the hole transport layer 1322, the material of the electron blocking layer 1323, the material of the light-emitting layer 131, the material of the hole blocking layer 1333, the material of the electron transport layer 1332, the material of the electron injection layer 1331 and the material of the cathode 12 to sequentially form the hole injection layer 1321, the hole transport layer 1322, the electron blocking layer 1323, the light-emitting layer 131, the hole blocking layer 1333, the electron transport layer 1332, the electron injection layer 1331 and the cathode 12 on the substrate.

It will be noted that the thicknesses of the hole injection layer 1321, the hole transport layer 1322, the electron blocking layer 1323, the light-emitting layer 131, the hole blocking layer 1333, the electron transport layer 1332, the electron injection layer 1331 and the cathode 12 in the embodiments are all the same, which are 10 nm, 110 nm, 5 nm, 20 nm, 5 nm, 30 nm, 1 nm and 130 nm, respectively. The materials of the anode 11, the hole injection layer 1321, the hole transport layer 1322, the electron blocking layer 1323, the light-emitting layer 131, the electron injection layer 1331 and the cathode 12 in the embodiments are all the same. The material of the anode 11 is indium tin oxide (ITO), the structure of the material of the hole injection layer 1321 is as shown in the above structure (HAT-CN), the structure of the material of the hole transport layer 1322 is as shown in the above structure (NPB), the structure of the material of the electron blocking layer 1323 is as shown in the above structure (TCTA), the structure of the host material H of the light-emitting layer 131 (EML) is as shown in the above structure (H-1), the structure of the guest material D (also called blue fluorescent dopant) of the light-emitting layer 131 (EML) is as shown in the above structure (DPAVBi), the material of the electron injection layer 1331 (EIL) is ytterbium (Yb), and the material of the cathode 12 is aluminum. Furthermore, in the light-emitting layer 131, a mass ratio of the host material H to the guest material D is 95:5.

The materials of the first functional layers (i.e., the electron transport layers 1332 ETL) and the second functional layers (i.e., the hole blocking layers 1333 HBL) of the first light-emitting devices 101 in the embodiments will be described below.

In Embodiment 12, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-2).

In Embodiment 13, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-18).

In Embodiment 14, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-20).

In order to more clearly describe the difference between the material of the first functional layer (i.e., the electron transport layer 1332 ETL) and the material of the second functional layer (i.e., the hole blocking layer 1333 HBL) used in the embodiments, the following Table 5 is used to more clearly show the materials of the first functional layers (i.e., the electron transport layers 1332 ETL) and the materials of the second functional layers (i.e., the hole blocking layers 1333 HBL) used in the embodiments.

Based on the above materials, driving voltages (V), current efficiencies (cd/A) and device lives of the first light-emitting devices 101 in Embodiments 12 to 14 are tested. The test results of the driving voltages (V), the current efficiencies (cd/A) and the device lives take Comparative Example 1 as a reference, and the test results are shown in Table 5 below. The device life is characterized by the parameter LT95.

For convenience of comparison, Table 5 also lists the materials in the above Embodiments 1 to 3 and Comparative Example 1, as well as the test results of the driving voltages (V), the current efficiencies (cd/A) and the device lives.

TABLE 5

| | EML | HBL | ETL | EIL | Driving | Current | |
|---|---|---|---|---|---|---|---|
| | material | material | material | material | voltage | efficiency | LT95 |
| Embodiment 1 | (H-1):(DPAVBi) | (G2-2) | (G1-18):LiQ | LiF | 94% | 108% | 106% |
| Embodiment 2 | (H-1):(DPAVBi) | (G2-18) | (G1-18):LiQ | LiF | 94% | 115% | 110% |
| Embodiment 3 | (H-1):(DPAVBi) | (G2-20) | (G1-18):LiQ | LiF | 95% | 107% | 105% |
| Embodiment 12 | (H-1):(DPAVBi) | (G2-2) | (G1-18):LiQ | Yb | 94% | 110% | 105% |
| Embodiment 13 | (H-1):(DPAVBi) | (G2-18) | (G1-18):LiQ | Yb | 94% | 114% | 110% |
| Embodiment 14 | (H-1):(DPAVBi) | (G2-20) | (G1-18):LiQ | Yb | 95% | 108% | 106% |
| Comparative | (H-1):(DPAVBi) | / | (G1-18):LiQ | LiF | 100% | 100% | 100% |
| Example 1 | | | | | | | |

It will be noted that “(A-x)” in Table 5 means that the corresponding structural formula is as shown in the above structural formula (A-x). For example, a content of a sub-grid corresponding to the material of the HBL (i.e., the hole blocking layer 1333) in Embodiment 1 is “(G2-2)”, which means that in Embodiment 1, the structural formula of the material of the HBL (i.e., the hole blocking layer 1333) is as shown in the above structural formula (G2-2). The structural formulas represented by (G1-x), (G2-x) (x is a positive integer), (H-1) and (DPAVBi) refer to the above contents, and details are not repeated here.

Comparing Embodiments 12 to 14 with Comparative Example 1, referring to Table 5, the current efficiencies and the device lives in Embodiments 12 to 14 are relatively high. This is because that the first light-emitting device 101 in Comparative Example 1 is not provided with a hole blocking layer 1333, compared with Embodiments 12 to 14, the electron transport property in Comparative Example 1 is relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the first light-emitting device 101 may be improved. As a result, electrons and holes in the light-emitting layer 131 are rather balanced, and the recombination probability of the excitons increases. In this way, firstly, the yield of excitons may increase, so that the efficiency of the first light-emitting device 101 may be improved; secondly, the distribution of the carriers may be balanced to block holes or excitons from leaking to a side of the cathode 12, so that the life of the first light-emitting device 101 may be improved.

Comparing Embodiments 12 to 14 with Comparative Example 1, referring to Table 5, the driving voltages in Embodiments 12 to 14 are relatively low. This is because that compared with Embodiments 12 to 14, the electron transport property in Comparative Example 1 is relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage is relatively low.

Comparing Embodiments 12 to 14 with Embodiments 1 to 3, referring to Table 5, in a case where the material of the electron injection layer 1331 of the first light-emitting device 101 is ytterbium or lithium fluoride, the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the efficiency and device life of the first light-emitting device 101 are both within a relatively high range, and the driving voltage thereof is within a relatively low range. It can be seen that the first functional material G1 described in the present disclosure and the second functional material G2 described in the present disclosure, combined with the material of the electron injection layer 1331, may achieve the electroluminescent performance of high efficiency, low driving voltage and long life of the first light-emitting device 101.

### Fourth Group of Experimental Examples

The embodiments and comparative examples in the following produce the electron transport layer 1332 (i.e., the first functional layer) and the hole blocking layer 1333 (i.e., the second functional layer) in the third light-emitting device 103 using different materials, and perform comparison on a driving voltage, a current efficiency and a device life of the third light-emitting device 103.

In the following Comparative Example 8 and Embodiments 15 to 18, structures of the third light-emitting devices 103 are all the same. In the following Comparative Example 7, the first-type functional layer (i.e., the electron transport functional layer 133) does not include the hole blocking layer 1333, and structures of other film layers except the hole blocking layer 1333 are the same as those of Comparative Example 8 and Embodiments 15 to 18. In the following Comparative Examples 7 and 8 and Embodiments 15 to 18, test conditions of the third light-emitting devices 103 are the same.

As shown in FIG. 5, the manufacture method of the third light-emitting device 103 is as follows: taking a substrate 210 provided with an array layer, a pixel defining layer and an anode 11 as a substrate, cleaning and drying the substrate, placing the substrate into a vacuum evaporation device, and using the material of the hole injection layer 1321, the material of the hole transport layer 1322, the material of the electron blocking layer 1323, the material of the light-emitting layer 131, the material of the hole blocking layer 1333, the material of the electron transport layer 1332, the material of the electron injection layer 1331 and the material of the cathode 12 to sequentially form the hole injection layer 1321, the hole transport layer 1322, the electron blocking layer 1323, the light-emitting layer 131, the hole blocking layer 1333, the electron transport layer 1332, the electron injection layer 1331 and the cathode 12 on the substrate.

It will be noted that the thicknesses of the hole injection layer 1321, the hole transport layer 1322, the electron blocking layer 1323, the light-emitting layer 131, the hole blocking layer 1333, the electron transport layer 1332, the electron injection layer 1331 and the cathode 12 in the embodiments and comparative examples are all the same, which are 10 nm, 110 nm, 60 nm, 40 nm, 5 nm, 30 nm, 1 nm and 130 nm, respectively. The materials of the anode 11, the hole injection layer 1321, the hole transport layer 1322, the electron blocking layer 1323, the light-emitting layer 131, the electron injection layer 1331 and the cathode 12 in the embodiments and comparative examples are all the same. The material of the anode 11 is indium tin oxide (ITO), the structure of the material of the hole injection layer 1321 is as shown in the above structure (HAT-CN), the structure of the material of the hole transport layer 1322 is as shown in the above structure (NPB), the structure of the material of the electron blocking layer 1323 is as shown in the above structure (TCTA), and the host material H of the light-emitting layer 131 (EML) includes a first host material and a second host material, which is beneficial to injection and transport of holes and electrons, and further beneficial to energy transport to the guest material D. The structure of the first host material is as shown in the following structure (RH-N1), and the structure of the second host material is as shown in the following structure (RH-P1). The structure of the guest material D of the light-emitting layer 131 (EML) is as shown in the following structure (RD). Furthermore, in the light-emitting layer 131, a mass ratio of the first host material, the second host material, and the guest material D is 49:49:5. The material of the electron injection layer 1331 is lithium fluoride (LiF), and the material of the cathode 12 is aluminum.

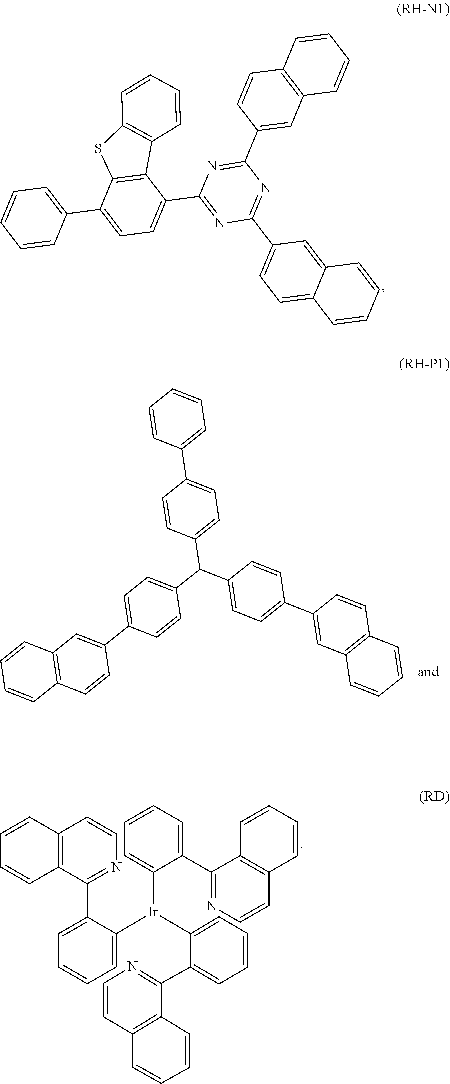

It will be noted that (RH-N1), (RH-P1) and (RD) in the above structural formulas are each a synonym for a respective structural formula and is not a part of the structure of the structural formula.

The materials of the first functional layers (i.e., the electron transport layers 1332, ETL) and the second functional layers (i.e., the hole blocking layers 1333, HBL) of the third light-emitting devices 103 in the embodiments and comparative examples will be described below.

In Embodiment 15, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-2).

In Embodiment 16, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-18).

In Embodiment 17, the material of the first functional layer is composed of the first functional material G1 having a structure as shown in (G1-18) and 8-hydroxyquinoline lithium (LiQ), and a mass ratio of the two is 1:1; and the structural formula of the material of the second functional layer is as shown in (G2-20).

In Embodiment 18, the material of the first functional layer is composed of the first functional material G1 having a structure as shown in (G1-42) and 8-hydroxyquinoline lithium (LiQ), and a mass ratio of the two is 1:1; and the structural formula of the material of the second functional layer is as shown in (G2-18).

In Comparative Example 7, the material of the first functional layer is composed of the first functional material G1 having a structure as shown in (G1-18) and 8-hydroxyquinoline lithium (LiQ), and a mass ratio of the two is 1:1.

In Comparative Example 8, the material of the first functional layer is composed of the second functional material G2 having a structure as shown in (G2-2) and 8-hydroxyquinoline lithium (LiQ), and a mass ratio of the two is 1:1; and the structural formula of the material of the second functional layer is shown in (G1-18).

In order to more clearly describe the difference between the material of the first functional layer (i.e., the electron transport layer 1332 ETL) and the material of the second functional layer (i.e., the hole blocking layer 1333 HBL) used in the embodiments and comparative examples, the following Table 6 is used to more clearly show the materials of the first functional layers (i.e., the electron transport layers 1332 ETL) and the materials of the second functional layers (i.e., the hole blocking layers 1333 HBL) used in the embodiments and comparative examples.

Based on the above materials, driving voltages (V), current efficiencies (cd/A) and device lives of the third light-emitting devices 103 in Embodiments 15 to 18 and Comparative Examples 7 and 8 are tested. The test results of the driving voltages (V), the current efficiencies (cd/A) and the device lives take Comparative Example 7 as a reference, and the test results are shown in Table 6 below. The device life is characterized by the parameter LT95.

TABLE 6

| | | HBL | ETL | Driving | Current | |
|---|---|---|---|---|---|---|
| | EML material | material | material | voltage | efficiency | LT95 |
| Embodiment 15 | (RH-N1):(RH-P1):(RD) | (G2-2) | (G1-18):LiQ | 95% | 106% | 105% |
| Embodiment 16 | (RH-N1):(RH-P1):(RD) | (G2-18) | (G1-18):LiQ | 95% | 113% | 108% |
| Embodiment 17 | (RH-N1):(RH-P1):(RD) | (G2-20) | (G1-18):LiQ | 96% | 104% | 103% |
| Embodiment 18 | (RH-N1):(RH-P1):(RD) | (G2-18) | (G1-42):LiQ | 95% | 114% | 109% |
| Comparative | (RH-N1):(RH-P1):(RD) | / | (G1-18):LiQ | 100% | 100% | 100% |
| Example 7 | | | | | | |
| Comparative | (RH-N1):(RH-P1):(RD) | (G1-18) | (G2-2):LiQ | 101% | 96% | 95% |
| Example 8 | | | | | | |

It will be noted that “(A-x)” in Table 6 means that the corresponding structural formula is as shown in the above structural formula (A-x). For example, a content of a sub-grid corresponding to the material of the HBL (i.e., the hole blocking layer 1333) in Embodiment 15 is “(G2-2)”, which means that in Embodiment 15, the structural formula of the material of the HBL (i.e., the hole blocking layer 1333) is as shown in the above structural formula (G2-2). The structural formulas represented by (G1-x), (G2-x) (x is a positive integer), (RH-N1), (RH-P1) and (RD) refer to the above contents, and details are not repeated here.

Comparing Embodiments 15 to 18 with Comparative Examples 7 and 8, referring to Table 6, the current efficiencies and the device lives in Embodiments 15 to 18 are relatively high. This is because that the third light-emitting device 103 in Comparative Example 7 is not provided with a hole blocking layer 1333, and in Comparative Example 8, the material of the electron transport layer 1332 includes the second functional material G2 having a structure as shown in (G2-2), and the material of the hole blocking layer 1333 is the first functional material G1 having a structure as shown in (G1-18). In this way, compared with Embodiments 15 to 18, the electron transport properties in Comparative Examples 7 and 8 are relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the third light-emitting device 103 may be improved. As a result, electrons and holes in the light-emitting layer 131 are rather balanced, and the recombination probability of the excitons increases. In this way, firstly, the yield of excitons may increase, so that the efficiency of the third light-emitting device 103 may be improved; secondly, the distribution of the carriers may be balanced to block holes or excitons from leaking to a side of the cathode 12, so that the life of the third light-emitting device 103 may be improved.

Comparing Embodiments 15 to 18 with Comparative Examples 7 and 8, referring to Table 6, the driving voltages in Embodiments 15 to 18 are relatively low. This is because that compared with Embodiments 15 to 18, the electron transport properties in Comparative Examples 7 and 8 are relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage of the third light-emitting device 103 is relatively low.

It can be seen from the above embodiments and comparative examples that in a case where the material of the electron transport layer 1332 of the third light-emitting device 103 is the first functional material G1 described in the present disclosure, and the material of the hole blocking layer 1333 of the third light-emitting device 103 is the second functional material G2 described in the present disclosure, the efficiency and device life of the third light-emitting device 103 are relatively high, and the driving voltage is relatively low, thereby achieving the electroluminescent performance of high efficiency, low driving voltage and long life of the third light-emitting device 103.

### Fifth Group of Experimental Examples

The embodiments and comparative examples in the following produce the electron transport layer 1332 (i.e., the first functional layer) and the hole blocking layer 1333 (i.e., the second functional layer) in a stacked first light-emitting device 101 using different materials, and perform comparison on a driving voltage, a current efficiency and a device life of the first light-emitting device 101.

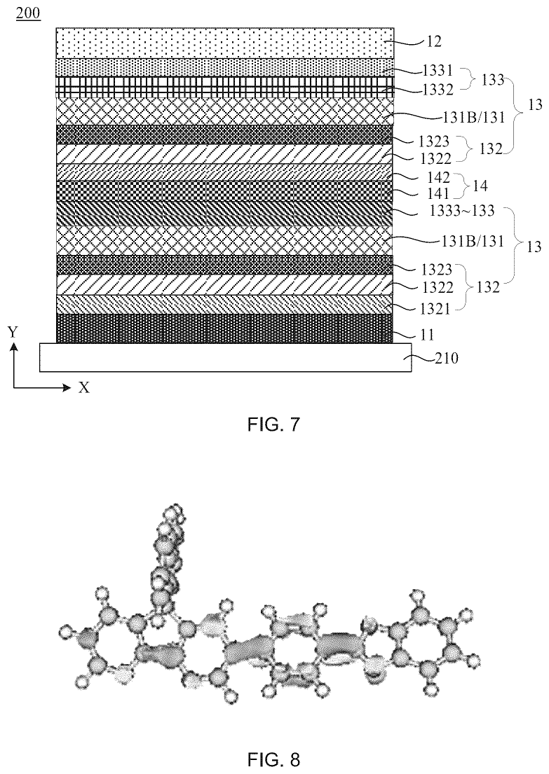

In the following Comparative Example 10 and Embodiments 19 to 25, as shown in FIG. 6, the first light-emitting devices 101 all have the same structure, which is a stacked light-emitting device 100 having two light-emitting units 13. The first light-emitting device 101 includes an anode 11, a hole injection layer 1321, a first hole transport layer 1322, a first electron blocking layer 1323, a first light-emitting layer 131, a first hole blocking layer 1333 (HBL-1), an electron generation layer 141 (N-type charge generation layer, N-CGL), a hole generation layer 142 (P-type charge generation layer, P-CGL), a second hole transport layer 1322, a second electron blocking layer 1323, a second light-emitting layer 131, a second hole blocking layer 1333 (HBL-2), an electron transport layer 1332 (ETL), an electron injection layer 1331 and a cathode 12 that are arranged in sequence in a direction from the anode 11 to the cathode 12. In the following Comparative Example 9, as shown in FIG. 7, the second hole blocking layer 1333 (HBL-2) is not included, and structures of other film layers except the second hole blocking layer 1333 (HBL-2) are the same as those of Comparative Example 10 and Embodiments 19 to 25. In the following Comparative Examples 9 and 10 and Embodiments 19 to 25, the test conditions of the first light-emitting devices 101 are the same.

The manufacture method of the first light-emitting device 101 is as follows: taking a substrate 210 provided with an array layer, a pixel defining layer and an anode 11 as a substrate, cleaning and drying the substrate, placing the substrate into a vacuum evaporation device, and using the material of the hole injection layer 1321, the material of the first hole transport layer 1322, the material of the first electron blocking layer 1323, the material of the first light-emitting layer 131, the material of the first hole blocking layer 1333, the material of the electron generation layer 141, the material of the hole generation layer 142, the material of the second hole transport layer 1322, the material of the second electron blocking layer 1323, the material of the second light-emitting layer 131, the material of the second hole blocking layer 1333, the material of the electron transport layer 1332, the material of the electron injection layer 1331 and the material of the cathode 12 to sequentially form the hole injection layer 1321, the first hole transport layer 1322, the first electron blocking layer 1323, the first light-emitting layer 131, the first hole blocking layer 1333, the electron generation layer 141, the hole generation layer 142, the second hole transport layer 1322, the second electron blocking layer 1323, the second light-emitting layer 131, the second hole blocking layer 1333, the electron transport layer 1332, the electron injection layer 1331 and the cathode 12.

It will be noted that the thicknesses of the hole injection layer 1321, the first hole transport layer 1322, the first electron blocking layer 1323, the first light-emitting layer 131, the first hole blocking layer 1333, the electron generation layer 141, the hole generation layer 142, the second hole transport layer 1322, the second electron blocking layer 1323, the second light-emitting layer 131, the second hole blocking layer 1333, the electron transport layer 1332, the electron injection layer 1331 and the cathode 12 in the embodiments and comparative examples are all the same, which are 10 nm, 20 nm, 5 nm, 20 nm, 10 nm, 18 nm, 12 nm, 20 nm, 5 nm, 20 nm, 5 nm, 30 nm, 1 nm and 130 nm, respectively.

The materials of the anode 11, the hole injection layer 1321, the first hole transport layer 1322, the first electron blocking layer 1323, the first light-emitting layer 131, the electron generation layer 141, the hole generation layer 142, the second hole transport layer 1322, the second electron blocking layer 1323, the second light-emitting layer 131, the electron injection layer 1331 and the cathode 12 in the embodiments and the comparative examples are the same. The material of the anode 11 is indium tin oxide (ITO). The structure of the material of the hole injection layer 1321 is as shown in the above structure (HAT-CN); the structures of the materials of the first hole transport layer 1322 and the second hole transport layer 1322 are each as shown in the above structure (NPB); the structures of the materials of the first electron blocking layer 1323 and the second electron blocking layer 1323 are each as shown in the following structure (TCTA); the structures of the host materials H of the first light-emitting layer 131 and the second light-emitting layer 131 are each as shown in the above structure (H-1), and the structures of the guest materials D of the first light-emitting layer 131 and the second light-emitting layer 131 are each as shown in the above structure (DPAVBi). In addition, in the first light-emitting layer 131 and the second light-emitting layer 131, a mass ratio of the host material H to the guest material D is 95:5. The material of the electron generation layer 141 includes lithium (Li) and a material having a structure as following (N-CGL-1), and a mass ratio of lithium (Li) to the material having the structure as following (N-CGL-1) is 1:99. The material of the hole generation layer 142 includes a material having a structure as above (NPB) and a material having a structure as above (HAT-CN), and a mass ratio of the material having a structure as above (NPB) to the material having a structure as above (HAT-CN) is 5:95. The material of the electron injection layer 1331 is lithium fluoride (LiF); and the material of the cathode 12 is aluminum.

In the following embodiments and comparative examples, the material of the first hole blocking layer 1333 includes a comparative material, and the structure of the comparative material is as shown in the following formula (HB-1).

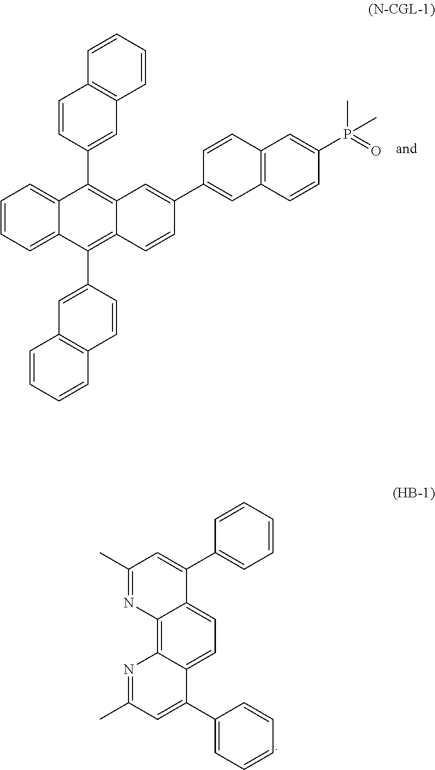

It will be noted that (N-CGL-1) and (HB-1) in the above structural formulas are each a synonym for a respective structural formula and is not a part of the structure of the structural formula.

The materials of the electron transport layers 1332 (ETL, i.e., the first functional layers), the first hole blocking layers 1333 (HBL-1, i.e., second functional layers of the first light-emitting units 13 proximate to the anodes 11), and the second hole blocking layers 1333 (HBL-1, i.e., second functional layers of the second light-emitting units 13 proximate to the cathodes 12) of the first light-emitting devices 101 in the embodiments and comparative examples will be described below.

In Embodiment 19, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (HB-1); and the structural formula of the material of the second hole blocking layer 1333 is shown in (G2-2).

In Embodiment 20, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (HB-1); and the structural formula of the material of the second hole blocking layer 1333 is shown in (G2-18).

In Embodiment 21, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (HB-1); and the structural formula of the material of the second hole blocking layer 1333 is shown in (G2-20).

In Embodiment 22, the material of the electron transport layer 1332 is composed of the first functional material G1 having a structure as shown in (G1-42) and 8-hydroxyquinoline lithium (LiQ), and a mass ratio of the two is 1:1. The structural formula of the material of the first hole blocking layer 1333 is shown in (HB-1); and the structural formula of the material of the second hole blocking layer 1333 is shown in (G2-18).

In Embodiment 23, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (G2-2); and the structural formula of the material of the second hole blocking layer 1333 is shown in (G2-2).

In Embodiment 24, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (G2-18); and the structural formula of the material of the second hole blocking layer 1333 is shown in (G2-2).

In Embodiment 25, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (G2-20); and the structural formula of the material of the second hole blocking layer 1333 is shown in (G2-2).

In Comparative Example 9, the material of the electron transport layer 1332 is composed of the first functional material G1 having a structure as shown in (G1-18) and 8-hydroxyquinoline lithium (LiQ), and a mass ratio of the two is 1:1. The structural formula of the material of the first hole blocking layer 1333 is shown in (HB-1).

In Comparative Example 10, the material of the electron transport layer 1332 is composed of the first functional material G1 having a structure as shown in (G2-2) and 8-hydroxyquinoline lithium (LiQ), and a mass ratio of the two is 1:1. The structural formula of the material of the first hole blocking layer 1333 is shown in (HB-1); and the structural formula of the material of the second hole blocking layer 1333 is shown in (G2-18).

In order to more clearly describe the difference between the materials of the electron transport layers 1332 (ETL, i.e., the first functional layers), the first hole blocking layers 1333 (HBL-1, i.e., second functional layers of the first light-emitting units 13 proximate to the anodes 11), and the second hole blocking layers 1333 (HBL-1, i.e., second functional layers of the second light-emitting units 13 proximate to the cathodes 12) used in the embodiments and comparative examples, the following Table 7 is used to more clearly show the materials of the electron transport layer 1332, the materials of the first hole blocking layer 1333 and the materials of the second hole blocking layers 1333 used in the embodiments and comparative examples.

Based on the above materials, driving voltages (V), current efficiencies (cd/A) and device lives of the first light-emitting devices 101 in Embodiments 19 to 25 and Comparative Examples 9 and 10 are tested. The test results of the driving voltages (V), the current efficiencies (cd/A) and the device lives take Comparative Example 9 as a reference, and the test results are shown in Table 7 below. The device life is characterized by the parameter LT95.

TABLE 7

| | HBL-1 | HBL-2 | ETL | Driving | Current | |
|---|---|---|---|---|---|---|
| | material | material | material | voltage | efficiency | LT95 |
| Embodiment 19 | (HB-1) | (G2-2) | (G1-18):LiQ | 96% | 106% | 103% |
| Embodiment 20 | (HB-1) | (G2-18) | (G1-18):LiQ | 96% | 113% | 108% |
| Embodiment 21 | (HB-1) | (G2-20) | (G1-18):LiQ | 97% | 106% | 103% |
| Embodiment 22 | (HB-1) | (G2-18) | (G1-42):LiQ | 96% | 115% | 109% |
| Embodiment 23 | (G2-2) | (G2-2) | (G1-18):LiQ | 96% | 113% | 110% |
| Embodiment 24 | (G2-18) | (G2-2) | (G1-18):LiQ | 96% | 118% | 113% |
| Embodiment 25 | (G2-20) | (G2-2) | (G1-18):LiQ | 97% | 115% | 109% |
| Comparative | (HB-1) | / | (G1-18):LiQ | 100% | 100% | 100% |
| Example 9 | | | | | | |
| Comparative | (HB-1) | (G1-18) | (G2-2):LiQ | 103% | 96% | 95% |
| Example 10 | | | | | | |

It will be noted that “(A-x)” in Table 7 means that the corresponding structural formula is as shown in the above structural formula (A-x). For example, a content of a sub-grid corresponding to the material of the HBL (i.e., the first hole blocking layer 1333) in Embodiment 19 is “(HB-1)”, which means that in Embodiment 19, the structural formula of the material of the HBL-1 (i.e., the first hole blocking layer 1333) is as shown in the above structural formula (HB-1). The structural formulas represented by (G1-x), (G2-x) (x is a positive integer) and (HB-1) refer to the above contents, and details are not repeated here.

Comparing Embodiments 19 to 25 with Comparative Examples 9 and 10, referring to Table 7, the current efficiencies and the device lives in Embodiments 19 to 25 are relatively high. This is because that the first light-emitting device 101 in Comparative Example 9 is not provided with a second hole blocking layer 1333, and in Comparative Example 10, the material of the electron transport layer 1332 includes the second functional material G2 having a structure as shown in (G2-2), and the material of the second hole blocking layer 1333 is the first functional material G1 having a structure as shown in (G1-18). In this way, compared with Embodiments 19 to 25, the electron transport properties in Comparative Examples 9 and 10 are relatively poor, and the hole and exciton blocking properties are relatively poor. It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, an interface between the first functional layer and the second functional layer may be optimized. In addition, the reasonable position of the first functional material G1 and the second functional material G2 is beneficial to transport of electrons between the first functional layer and the second functional layer, so that the electron transport effect of the first light-emitting device 101 may be improved. As a result, electrons and holes in the light-emitting layer 131 are rather balanced, and the recombination probability of the excitons increases. In this way, firstly, the yield of excitons may increase, so that the efficiency of the first light-emitting device 101 may be improved; secondly, the distribution of the carriers may be balanced to block holes or excitons from leaking to a side of the cathode 12, so that the life of the first light-emitting device 101 may be improved.

Comparing Embodiments 19 to 25 with Comparative Examples 9 and 10, referring to Table 7, the driving voltages in Embodiments 19 to 25 are relatively low. This is because that compared with Embodiments 19 to 25, the electron transport properties in Comparative Examples 9 and 10 are relatively poor (for specific reasons, reference may be made to the above section about the current efficiencies and the device lives). It can be seen that in a case where the material of the electron transport layer 1332 is the first functional material G1 (e.g., the first functional material G1 shown in the general formula (I)) containing a fluorene group, and the material of the hole blocking layer 1333 is the second functional material G2 (e.g., the second functional material G2 shown in the general formula (II)) containing a fluorene group, the electron transport functional layer 133 has a relatively high electron mobility and good electron injection and transport effects, so that the driving voltage is relatively low; moreover, a difference between the LUMO energy level of the material of the electron transport layer 1332 and the LUMO energy level of the hole blocking layer 1333 is relatively small, which may also make a good electron injection effect, so that the driving voltage is relatively low.

Comparing Embodiments 23 to 25 with Embodiments 19 to 22, referring to Table 7, the current efficiency and the device life in Embodiments 23 to 25 are relatively high. This is because that in Embodiments 19 to 22, the material of the second hole blocking layer 1333 is the second functional material G2 having a structure as shown in (HB-1), and in Embodiments 23 to 25, the material of the second hole blocking layer 1333 is the second functional material G2. In this way, compared with Embodiments 19 to 22, the electron transport properties in Embodiments 23 to 25 are relatively good, and the electron transport effect of the first light-emitting device 101 may be improved. As a result, electrons and holes in the light-emitting layer 131 are rather balanced, and the recombination probability of the excitons increases.

Comparing Embodiments 23 to 25 with Embodiments 19 to 22, referring to Table 7, the driving voltages in Embodiments 23 to 25 are relatively low. This is because that in Embodiments 19 to 22, the material of the second hole blocking layer 1333 is the second functional material G2 having a structure as shown in (HB-1), and in Embodiments 23 to 25, the material of the second hole blocking layer 1333 is the second functional material G2. In this way, compared with Embodiments 19 to 22, the electron transport functional layer 133 in Embodiments 23 to 25 has a relatively high electron mobility and good electron injection and transport effects, so that the driving voltage is relatively low; moreover, in Embodiments 23 to 25, a difference between the LUMO energy level of the material of the electron transport layer 1332 and the LUMO energy level of the hole blocking layer 1333 is relatively small, which may also make a good electron injection effect, so that the driving voltage is relatively low.

It can be seen from the above embodiments and comparative examples that, in a case where the material of the electron transport layer 1332 of the stacked first light-emitting device 101 is the first functional material G1 described in the present disclosure, and the material of the hole blocking layer 1333 of the stacked first light-emitting device 101 is the second functional material G2 described in the present disclosure, the efficiency and device life of the first light-emitting device 101 are relatively high, and the driving voltage is relatively low, thereby achieving the electroluminescent performance of high efficiency, low driving voltage and long life of the first light-emitting device 101.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising a cathode and an anode that are opposite, and at least one light-emitting unit located between the cathode and the anode, wherein
the light-emitting unit includes: a light-emitting layer and a first-type functional layer disposed on a side of the light-emitting layer proximate to the cathode; the first-type functional layer includes a first functional layer and a second functional layer; a material of the first functional layer includes a first functional material; and a material of the second functional layer includes a second functional material; and
a structure of the first functional material contains a fluorene group; and a structure of the second functional material contains a fluorene group.

2. The light-emitting device according to claim 1, wherein the first functional layer is closer to the cathode than the second functional layer; and the structure of the first functional material contains an azafluorene group.

3. The light-emitting device according to claim 1, wherein the first functional material is selected from any of structures represented by a general formula (I); 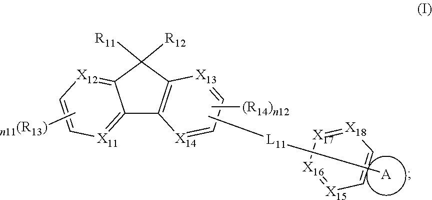
wherein X₁₁, X₁₂, X₁₃, X₁₄, X₁₅, X₁₆, X₁₇ and X₁₈ are each independently selected from any of C(Rₐ) and N; any two of X₁₁, X₁₂, X₁₃, X₁₄, X₁₅, X₁₆, X₁₇ and X₁₈ are same or different; and at least one of X₁₁, X₁₂, X₁₃ or X₁₄ is N;
R₁₁, R₁₂, R₁₃, R₁₄ and Rₐ are same or different; R₁₁, R₁₂, R₁₃, R₁₄ and Rₐ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₁₁, R₁₂, R₁₃, R₁₄ and Rₐ are connected with an adjacent group to form substituted or unsubstituted 3- to 30-membered ring;
L₁₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups;
A is selected from any of substituted or unsubstituted C6 to C12 aryl groups and substituted or unsubstituted 5- to 12-membered heteroaryl groups;
n₁₁ is selected from any of 0, 1 and 2; and
n₁₂ is selected from any of 0 and 1.

4. The light-emitting device according to claim 1, wherein the second functional material is selected from any of structures represented by a general formula (II); 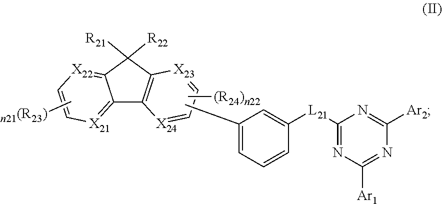
wherein X₂₁, X₂₂, X₂₃ and X₂₄ are each independently selected from any of C(R_{b}) and N; and any two of X₂₁, X₂₂, X₂₃ and X₂₄ are same or different;
R₂₁, R₂₂, R₂₃, R₂₄ and R_{b} are same or different; R₂₁, R₂₂, R₂₃, R₂₄ and R_{b} are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R₂₁, R₂₂, R₂₃, R₂₄ and R_{b} are connected with an adjacent group to form substituted or unsubstituted 3- to 30-membered ring;
L₂₁ is selected from any of a direct bond, substituted or unsubstituted C3 to C30 alkylene groups, substituted or unsubstituted C6 to C30 arylene groups, and substituted or unsubstituted 5- to 30-membered heteroarylene groups;
Ar₁ and Ar₂ are same or different; Ar₁ and Ar₂ are each independently selected from any of substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Ar₁ and Ar₂ are connected with an adjacent group to form substituted or unsubstituted 3- to 30-membered ring;
n₂₁ is selected from any of 0, 1 and 2; and
n₂₂ is selected from any of 0 and 1.

5. The light-emitting device according to claim 3, wherein the first functional material is selected from any of structures represented by a general formula (I-A); 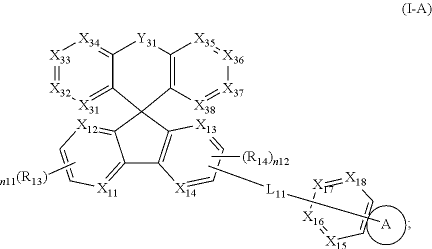
wherein X₃₁, X₃₂, X₃₃, X₃₄, X₃₅, X₃₆, X₃₇ and X₃₈ are each independently selected from any of C(R_{c}) and N; and any two of X₃₁, X₃₂, X₃₃, X₃₄, X₃₅, X₃₆, X₃₇ and X₃₈ are same or different;
Y₃₁ is selected from any of a direct bond, C(R_{d}Rₑ), O, S and Se; and
R_{c}, R_{d} and Rₑ are same or different; R_{c}, R_{d} and Rₑ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{c}, R_{d} and Rₑ are connected with an adjacent group to form substituted or unsubstituted 3- to 30-membered ring.

6. The light-emitting device according to claim 3, wherein Rᵢ is a phenyl group, and R₁₂ is a phenyl group.

7. The light-emitting device according to claim 3, wherein A is selected from any of structures represented by a general formula (A1-1), a general formula (A1-2), a general formula (A1-3) and a general formula (A1-4); 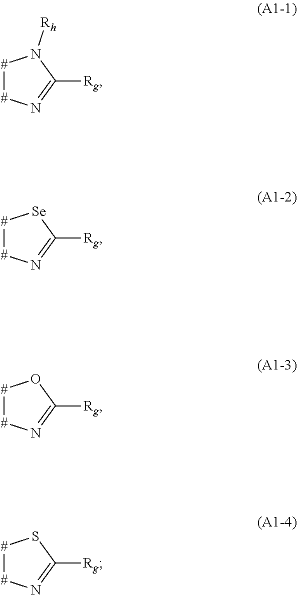
wherein #indicates a fusion site;
R_{g} and Rₕ are same or different; R_{g} and Rₕ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{g} and Rₕ are connected with an adjacent group to form substituted or unsubstituted 3- to 30-membered ring.

8. The light-emitting device according to claim 3, wherein A is selected from any of structures represented by a general formula (A2), a general formula (A3), a general formula (A4) and a general formula (A5); 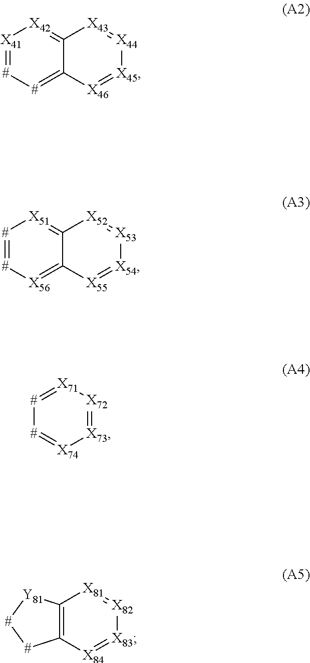
wherein #indicates a fusion site;
X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are each independently selected from any of C(R_{f}) and N; and any two of X₄₁, X₄₂, X₄₃, X₄₄, X₄₅, X₄₆, X₅₁, X₅₂, X₅₃, X₅₄, X₅₅, X₅₆, X₇₁, X₇₂, X₇₃, X₇₄, X₈₁, X₈₂, X₈₃ and X₈₄ are same or different;
Y₈₁ is selected from any of C(RᵢRⱼ), N(Rₖ), O, S and Se;
R_{f}, Rᵢ, Rⱼ and Rₓ are same or different; R_{f}, Rᵢ, Rⱼ and Rₓ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or R_{f}, Rᵢ, Rⱼ and Rₖ are connected with an adjacent group to form substituted or unsubstituted 3- to 30-membered ring.

9. The light-emitting device according to claim 8, wherein A is selected from any of structures represented by the general formula (A2); and A and a six-membered ring containing X₁₅, X₁₆, X₁₇ and X₁₈ form a phenanthroline group; or
A is selected from any of structures represented by the general formula (A4); and A and a six-membered ring containing X₁₅, X₁₆, X₁₇, X₁₈ form a benzodiazine group.

10. (canceled)

11. The light-emitting device according to claim 4, wherein the second functional material is selected from any of structures represented by a general formula (II-A); 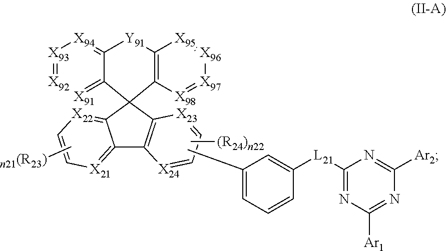
wherein X₉₁, X₉₂, X₉₃, X₉₄, X₉₅, X₉₆, X₉₇ and X₉₈ are each independently selected from any of C(Rₙ) and N; and any two of X₉₁, X₉₂, X₉₃, X₉₄, X₉₅, X₉₆, X₉₇ and X₉₈ are same or different;
Y₉₁ is selected from any of a direct bond, C(RₒRₚ), O, S and Se; and
Rₙ, Rₒ and Rₚ are same or different; Rₙ, Rₒ and Rₚ are each independently selected from any of hydrogen, deuterium, halogen, cyanogroup, nitro group, hydroxyl group, substituted or unsubstituted C1 to C30 alkyl groups, substituted or unsubstituted C2 to C30 alkenyl groups, substituted or unsubstituted C2 to C30 alkynyl groups, substituted or unsubstituted C3 to C30 cycloalkyl groups, substituted or unsubstituted C1 to C30 alkoxy groups, substituted or unsubstituted C6 to C30 aryl groups, substituted or unsubstituted 5- to 30-membered heteroaryl groups, and substituted and unsubstituted 3- to 30-membered heterocyclyl groups, or Rₙ, Rₒ and Rₚ are connected with an adjacent group to form substituted or unsubstituted 3- to 30-membered ring.

12. The light-emitting device according to claim 4, wherein R₂₁ is a phenyl group, and R₂₂ is a phenyl group.

13. The light-emitting device according to claim 4, wherein R₂₁ is a methyl group, and R₂₂ is a methyl group.

14. The light-emitting device according to claim 4, wherein L₂₁ has a structure represented by a general formula (II-A); 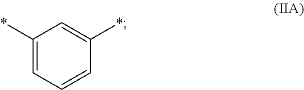
wherein * indicates a connection site.

15. The light-emitting device according to claim 4, wherein X₂₁, X₂₂, X₂₃ and X₂₄ are substituted or unsubstituted carbon.

16. The light-emitting device according to claim 2, wherein the first-type functional layer further includes a third functional layer, and the third functional layer is located on a side of the first functional layer away from the second functional layer; a material of the third functional layer includes a third functional material, and the third functional material is selected from any of ytterbium and lithium fluoride.

17. The light-emitting device according to claim 1, wherein a material of the light-emitting layer includes a host material and a guest material; and the guest material is configured to emit blue light.

18. The light-emitting device according to claim 17, wherein the guest material is selected from any of a fluorescent material, a phosphorescent material and a delayed fluorescent material.

19. The light-emitting device according to claim 4, wherein the light-emitting device comprises at least two light-emitting units, and the at least two light-emitting units are stacked;
the light-emitting device further comprises a charge generation layer located between two adjacent light-emitting units; and
a material of a second functional layer of each of the light-emitting units includes the second functional material.

20. A display panel, comprising a plurality of light-emitting devices each according to claim 1; and
pixel driving circuits, the pixel driving circuits being each used to drive a light-emitting device to emit light.

21. A display apparatus, comprising the display panel according to claim 20; and
a driver chip, the driver chip being used to drive the display panel to display.
